(19) United States
(12) Patent Application Publication
(10) Pub. No.: US 2026/0215088 A1
(43) Pub. Date: Jul. 23, 2026

(54) SEMICONDUCTOR DEVICE AND DISPLAY APPARATUS

(71) Applicant: SEMICONDUCTOR ENERGY LABORATORY CO., LTD., Atsugi-shi, Kanagawa-ken (JP)

(72) Inventors: Susumu KAWASHIMA, Atsugi, Kanagawa (JP); Hideaki SHISHIDO, Atsugi, Kanagawa (JP); Koji KUSUNOKI, Isehara, Kanagawa (JP)

(21) Appl. No.: 19/140,618

(22) PCT Filed: Dec. 21, 2023
(86) PCT No.: PCT/IB2023/063067

§ 371 Date: Jun. 18, 2025

(30) Foreign Application Priority Data
Dec. 28, 2022 (JP) 2022-211919

(51) Int. Cl. H10K 59/121; G09G 3/3233; G09G 3/36; H10K 59/131

(52) U.S. Cl. CPC H10K 59/1213; G09G 3/3233; G09G 3/3648; H10K 59/131; G09G 2310/08; G09G 2330/021

(57) ABSTRACT

A novel semiconductor device is provided. A transmission portion includes a first transistor; the transmission portion has a function of a source follower outputting a first potential to one of a source and a drain of the first transistor in accordance with a potential input to a gate of the first transistor; the generation portion has a function of generating a second potential corresponding to a potential of the first wiring; the input portion has a function of retaining voltage corresponding to threshold voltage of the first transistor and a function of transmitting, to the gate of the first transistor, a potential corresponding to the potential of the first wiring; and the output portion has a function of transmitting the first potential to the second wiring and a function of transmitting the second potential to the second wiring.

### TECHNICAL FIELD

One embodiment of the present invention relates to a semiconductor device, a display apparatus, and the like.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an imaging device, a lighting device, an arithmetic device, a control device, a memory device, an input device, an output device, an input/output device, a signal processing device, an arithmetic processing device, an electronic computer, an electronic device, driving methods thereof, and manufacturing methods thereof.

### BACKGROUND ART

For example, display apparatuses applicable for XR (Extended Reality) such as VR (Virtual Reality) or AR (Augmented Reality) have been required. Specifically, such display apparatuses have been desired to have a high resolution, high color reproducibility, and the like, for example, so as to offer enhanced realistic feeling and an enhanced sense of immersion.

Examples of devices applicable to such display apparatuses include a liquid crystal display apparatus and a light-emitting apparatus including a light-emitting element such as organic EL (Electro Luminescence) element (also referred to as an OLED (Organic Light Emitting Diode)) or a light-emitting diode (LED).

For example, an organic EL element has a structure where a layer including a light-emitting organic compound is held between a pair of electrodes. By voltage application between the electrodes, current is supplied to the layer, whereby light emission can be obtained from the light-emitting organic compound. A display apparatus using such an organic EL element does not need a backlight that is necessary for a liquid crystal display apparatus, for example; thus, a thin, lightweight, high-contrast, and low-power display apparatus can be achieved. Since the response speed of the organic EL element is high, a display apparatus suitable for displaying a fast-moving image can be achieved. Patent Document 1 discloses an example of a display apparatus using an organic EL element.

Patent Document 2 discloses a circuit structure of a pixel circuit for controlling the emission intensity of an organic EL element, in which threshold voltage variation between transistors is corrected in each pixel to increase the display quality of a display apparatus. Patent Document 3 discloses a circuit structure of a peripheral driver circuit of a display apparatus, in which threshold voltage variation between transistors is corrected in each circuit to increase the display quality of the display apparatus.

### REFERENCES

### Patent Documents

[Patent Document 1] Japanese Published Patent Application No. 2002-324673
[Patent Document 2] Japanese Published Patent Application No. 2015-132816
[Patent Document 3] Japanese Published Patent Application No. 2005-266365.

### SUMMARY OF THE INVENTION

### Problems to be Solved by the Invention

One object of one embodiment of the present invention is to provide a high-resolution semiconductor device or display apparatus. Another object of one embodiment of the present invention is to provide a downsized semiconductor device or display apparatus. Another object of one embodiment of the present invention is to provide a semiconductor device or display apparatus with higher display quality. Another object of one embodiment of the present invention is to provide a semiconductor device or display apparatus that has increased operation speed. Another object of one embodiment of the present invention is to provide a semiconductor device or display apparatus with reduced power consumption. Another object of one embodiment of the present invention is to provide a highly reliable semiconductor device or display apparatus. Another object of one embodiment of the present invention is to provide a novel semiconductor device or display apparatus. Another object of one embodiment of the present invention is to provide a method for driving a semiconductor device or a method for driving a display apparatus, which can increase display quality. Another object of one embodiment of the present invention is to provide a method for driving a semiconductor device or a method for driving a display apparatus, which can increase operation speed. Another object of one embodiment of the present invention is to provide a method for driving a semiconductor device or a method for driving a display apparatus, which can reduce power consumption. Another object of one embodiment of the present invention is to provide a method for driving a semiconductor device or a display apparatus, which can increase reliability. Another object of one embodiment of the present invention is to provide a novel method for driving a semiconductor device or a novel method for driving a display apparatus.

Note that the description of the above objects does not preclude the existence of other objects. One embodiment of the present invention does not necessarily achieve all the above objects. Objects other than objects listed above are apparent from the description of the specification, the drawings, the claims, and the like and objects other than objects listed above can be derived from the description of the specification, the drawings, the claims, and the like.

### Means for Solving the Problems

(1)

One embodiment of the present invention is a semiconductor device including a transmission portion, an input portion, an output portion, a generation portion, a first wiring, and a second wiring, in which the transmission portion includes a first transistor; a gate of the first transistor is electrically connected to the first wiring through the input portion; one of a source and a drain of the first transistor is electrically connected to the second wiring through the output portion; the first wiring is electrically connected to the second wiring through the generation portion and the output portion; the transmission portion has a function of a source follower outputting a first potential to the one of the source and the drain of the first transistor in accordance with a potential input to the gate of the first transistor; the generation portion has a function of generating a second potential corresponding to a potential of the first wiring; the input portion has a function of retaining a voltage corresponding to a threshold voltage of the first transistor and a function of transmitting, to the gate of the first transistor, a potential corresponding to the potential of the first wiring; and the output portion has a function of transmitting the first potential to the second wiring and a function of transmitting the second potential to the second wiring.
(2)

One embodiment of the present invention is a semiconductor device including a transmission portion, an input portion, an output portion, a generation portion, a first wiring, a second wiring, a third wiring, a fourth wiring, a fifth wiring, a sixth wiring, a seventh wiring, an eighth wiring, a ninth wiring, a tenth wiring, an eleventh wiring, a twelfth wiring, a thirteenth wiring, and a fourteenth wiring, in which the transmission portion includes a first transistor and a second transistor; the input portion includes a third transistor, a fourth transistor, a fifth transistor, and a first capacitor; the output portion includes a sixth transistor and a seventh transistor; the generation portion includes an eighth transistor and a ninth transistor; a gate of the first transistor is electrically connected to one of a source and a drain of the fifth transistor and one terminal of the first capacitor; one of a source and a drain of the first transistor is electrically connected to one of a source and a drain of the second transistor, one of a source and a drain of the fourth transistor, and one of a source and a drain of the sixth transistor; the other of the source and the drain of the first transistor is electrically connected to the third wiring; a gate of the second transistor is electrically connected to the fourth wiring; the other of the source and the drain of the second transistor is electrically connected to the fifth wiring; a gate of the third transistor is electrically connected to the sixth wiring; one of a source and a drain of the third transistor is electrically connected to the other of the source and the drain of the fourth transistor and the other terminal of the first capacitor; the other of the source and the drain of the third transistor is electrically connected to a gate of the eighth transistor and the first wiring; a gate of the fourth transistor is electrically connected to the seventh wiring; a gate of the fifth transistor is electrically connected to the eighth wiring; the other of the source and the drain of the fifth transistor is electrically connected to the ninth wiring; a gate of the sixth transistor is electrically connected to the tenth wiring; the other of the source and the drain of the sixth transistor is electrically connected to one of a source and a drain of the seventh transistor and the second wiring; a gate of the seventh transistor is electrically connected to the eleventh wiring; the other of the source and the drain of the seventh transistor is electrically connected to one of a source and a drain of the eighth transistor and one of a source and a drain of the ninth transistor; the other of the source and the drain of the eighth transistor is electrically connected to the twelfth wiring; a gate of the ninth transistor is electrically connected to the thirteenth wiring; and the other of the source and the drain of the ninth transistor is electrically connected to the fourteenth wiring.
(3)

In (2) described above, the first capacitor may have a function of retaining a voltage corresponding to a threshold voltage of the first transistor.
(4)

The semiconductor device in (3) described above may have a first state where the fourth transistor, the fifth transistor, and the seventh transistor are each in a conduction state and the third transistor and the sixth transistor are each in a non-conduction state.
(5)

In any one of (1) to (4) described above, the first transistor may include a semiconductor layer, and the semiconductor layer may include an oxide semiconductor.
(6)

In (5) described above, at least part of the semiconductor layer may be provided inside an opening formed in an insulating layer.
(7)

In (6) described above, the transistor included in each of the transmission portion, the input portion, the output portion, and the generation portion may be formed in the same step as the first transistor.
(8)

One embodiment of the present invention is a display apparatus including the semiconductor device of any one of (1) to (4) described above and a pixel. The pixel includes a tenth transistor, and one of a source and a drain of the tenth transistor is electrically connected to the second wiring.
(9)

In (8) described above, the first transistor may include a semiconductor layer, and the semiconductor layer may include an oxide semiconductor.
(10)

In (9) described above, at least part of the semiconductor layer may be provided inside an opening formed in an insulating layer.
(11)

In (10) described above, the transistor included in each of the transmission portion, the input portion, the output portion, the generation portion, and the pixel may be formed in the same step as the first transistor.

### Effect of the Invention

One embodiment of the present invention can provide a high-definition semiconductor device or display apparatus. Another embodiment of the present invention can provide a downsized semiconductor device or display apparatus. Another embodiment of the present invention can provide a semiconductor device or display apparatus with higher display quality. Another embodiment of the present invention can provide a semiconductor device or display apparatus that has increased operation speed. Another embodiment of the present invention can provide a semiconductor device or display apparatus with reduced power consumption. Another embodiment of the present invention can provide a highly reliable semiconductor device or display apparatus. Another embodiment of the present invention can provide a novel semiconductor device or display apparatus. Another embodiment of the present invention can provide a method for driving a semiconductor device or a method for driving a display apparatus, which can increase display quality. Another embodiment of the present invention can provide a method for driving a semiconductor device or a method for driving a display apparatus, which can increase operation speed. Another embodiment of the present invention can provide a method for driving a semiconductor device or a method for driving a display apparatus, which can reduce power consumption. Another embodiment of the present invention can provide a method for driving a semiconductor device or a display apparatus, which can increase reliability. Another embodiment of the present invention can provide a novel method for driving a semiconductor device or a novel method for driving a display apparatus.

Note that the descriptions of the above effects do not preclude the existence of other effects. Note that one embodiment of the present invention does not necessarily achieve all the above effects. Effects other than the effects listed above are apparent from the description of the specification, the drawings, the claims, and the like and effects other than the effects listed above can be derived from the description of the specification, the drawings, the claims, and the like.

### BRIEF DESCRIPTION OF THE DRAWINGS

FIG. 1A to FIG. 1C are circuit diagrams each showing a structure example of a semiconductor device.

FIG. 2A and FIG. 2B are timing charts showing operation examples of a semiconductor device.

FIG. 3 is a circuit diagram showing an operation example of a semiconductor device.

FIG. 4 is a circuit diagram showing an operation example of a semiconductor device.

FIG. 5 is a circuit diagram showing an operation example of a semiconductor device.

FIG. 6 is a circuit diagram showing a structure example of a semiconductor device.

FIG. 7A to FIG. 7F are circuit diagrams showing structure examples of a semiconductor device.

FIG. 8A to FIG. 8E are block diagrams showing structure examples of a display apparatus.

FIG. 9 is a circuit diagram showing a structure example of a semiconductor device.

FIG. 10 is a timing chart showing an operation example of a semiconductor device.

FIG. 11 is a circuit diagram showing a structure example of a semiconductor device.

FIG. 12 is a circuit diagram showing a structure example of a semiconductor device.

FIG. 13 is a circuit diagram showing a structure example of a semiconductor device.

FIG. 14 is a circuit diagram showing a structure example of a semiconductor device.

FIG. 15 is a circuit diagram showing a structure example of a semiconductor device.

FIG. 16 is a circuit diagram showing a structure example of a semiconductor device.

FIG. 17 is a circuit diagram showing a structure example of a semiconductor device.

FIG. 18 is a circuit diagram showing a structure example of a semiconductor device.

FIG. 19A to FIG. 19C and FIG. 19E are circuit diagrams showing structure examples of a semiconductor device. FIG. 19D is a timing chart showing an operation example of a semiconductor device.

FIG. 20A to FIG. 20C and FIG. 20E are circuit diagrams showing structure examples of a semiconductor device. FIG. 20D is a timing chart showing an operation example of a semiconductor device.

FIG. 21A to FIG. 21C are circuit diagrams showing structure examples of a semiconductor device.

FIG. 22 is a circuit diagram showing a structure example of a semiconductor device.

FIG. 23A to FIG. 23C and FIG. 23E are circuit diagrams showing structure examples of a semiconductor device. FIG. 23D is a timing chart showing an operation example of a semiconductor device.

FIG. 24 is a circuit diagram showing a structure example of a semiconductor device.

FIG. 25A to FIG. 25F are circuit diagrams showing structure examples of a semiconductor device.

FIG. 26 is a timing chart showing an operation example of a semiconductor device.

FIG. 27A to FIG. 27C are circuit diagrams showing structure examples of a semiconductor device.

FIG. 28A is a top view showing a structure example of a semiconductor device. FIG. 28B and

FIG. 28C are cross-sectional views showing the structure example of the semiconductor device.

FIG. 29A is a top view showing a structure example of a semiconductor device. FIG. 29B is a cross-sectional view showing the structure example of the semiconductor device.

FIG. 30A is a top view showing a structure example of a semiconductor device. FIG. 30B and

FIG. 30C are cross-sectional views showing the structure example of the semiconductor device.

FIG. 31 is a cross-sectional view showing a structure example of a semiconductor device.

FIG. 32A and FIG. 32B are cross-sectional views showing a structure example of a semiconductor device.

FIG. 33A and FIG. 33B are cross-sectional views showing a structure example of a semiconductor device.

FIG. 34A and FIG. 34B are circuit diagrams showing structure examples of a semiconductor device. FIG. 34C is a top view showing the structure example of the semiconductor device.

FIG. 35 is a cross-sectional view showing a structure example of a semiconductor device.

FIG. 36A and FIG. 36B are circuit diagrams showing structure examples of a semiconductor device. FIG. 36C is a top view showing the structure example of the semiconductor device.

FIG. 37 is a cross-sectional view showing a structure example of a semiconductor device.

FIG. 38A is a perspective view showing a structure example of a display apparatus. FIG. 38B to

FIG. 38F are top views showing examples of pixel arrangement.

FIG. 39A and FIG. 39B are cross-sectional views showing structure examples of a display apparatus.

FIG. 40A and FIG. 40B are cross-sectional views showing structure examples of a display apparatus.

FIG. 41A to FIG. 41D are diagrams showing examples of electronic devices.

FIG. 42A to FIG. 42F are diagrams showing examples of electronic devices.

FIG. 43A to FIG. 43G are diagrams showing examples of electronic devices.

### MODE FOR CARRYING OUT THE INVENTION

In this specification and the like, a semiconductor device refers to a device that utilizes semiconductor characteristics, and means a circuit including a semiconductor element (e.g., a transistor or a diode) or a device including the circuit, for example. The semiconductor device also means any device that can function by utilizing semiconductor characteristics. For example, an integrated circuit including a semiconductor element, a chip provided with an integrated circuit, an electronic component including a packaged chip, and an electronic device provided with an electronic component are examples of a semiconductor device. For example, a display apparatus, a light-emitting apparatus, a power storage device, an optical device, an imaging device, a lighting device, an arithmetic device, a control device, a memory device, an input device, an output device, an input/output device, a signal processing device, an electronic computer, an electronic device, and the like themselves might be semiconductor devices, or might include semiconductor devices.

Embodiments will be described below with reference to the drawings. Note that the embodiments can be implemented in many different modes. Thus, it will be readily understood by those skilled in the art that the modes and details can be changed in various ways without departing from the spirit and scope thereof. Thus, one embodiment of the present invention should not be interpreted as being limited to the description in the embodiments.

In this specification and the like, one embodiment of the present invention can be constituted by appropriately combining a structure described in an embodiment with any of the structures described in the other embodiments. In addition, in the case where a plurality of structures are described in one embodiment, the structures can be combined with each other as appropriate to constitute one embodiment of the present invention.

As for the drawings illustrating the embodiments, in the structures of the invention, the same reference numerals are used in common for the same portions or portions having similar functions in different drawings, and repeated description thereof is omitted in some cases. Furthermore, for example, the same hatching pattern is used for the portions having similar functions throughout the drawings, and the portions are not especially denoted by reference numerals in some cases. Moreover, some components are omitted in a perspective view or a top view (also referred to as a “plan view”), for example, for easy understanding of the drawings in some cases. For example, some hidden lines might also be omitted in the drawings. For example, a hatching pattern or the like might be omitted in the drawings.

In the drawings, the size, the layer thickness, or the region is exaggerated for clarity in some cases. Thus, the drawings are not limited to the drawings with the shown size, aspect ratio, and the like, for example. Note that the drawings schematically show ideal examples, and embodiments of the present invention are not limited to shapes, values, and the like shown in the drawings, for example. For example, in the actual manufacturing process, a layer, a resist mask, or the like might be unintentionally reduced in size by treatment such as etching, which is not shown in the drawings in some cases for easy understanding. For example, in the actual circuit operation, a fluctuation in voltage, current, or the like might be caused by noise, difference in timing, or the like, which is not shown in some cases for easy understanding.

In this specification, the drawings, and the like, components of the present invention are classified on the basis of the functions, and shown as elements independent of one another in some cases. However, such components are sometimes hard to classify functionally, and there are a case where one component is associated with a plurality of functions and a case where a plurality of components are associated with one function. Accordingly, the component is not limited to that described in this specification, the drawings, and the like and can be explained with another term as appropriate depending on the situation.

In this specification, the drawings, and the like, when a plurality of components are denoted by the same reference numerals, and in particular need to be distinguished from each other, an identification sign such as “A”, “b”, “_1”, “[n]”, or “[m, n]” is sometimes added to the reference numerals, for example. When matters common to a plurality of components with identification signs are described or they do not need to be distinguished from each other, no identification sign is added in some cases.

Note that in this specification and the like, a “conduction state” or an “on state” of a transistor refers to a state where a source and a drain of the transistor can be regarded as being electrically short-circuited or a state where current can be made to flow between the source and the drain. For example, the “conduction state” or the “on state” refers to a state where voltage between a gate and a source is higher than threshold voltage in an n-channel transistor, a state where voltage between a gate and a source is lower than threshold voltage in a p-channel transistor, or the like in some cases. A “non-conduction state”, a “cutoff state”, or an “off state” of a transistor refers to a state where a source and a drain of the transistor can be regarded as being electrically disconnected. For example, the “non-conduction state”, the “cutoff state”, or the “off state” refers to a state where voltage between a gate and a source is lower than threshold voltage in an n-channel transistor, a state where voltage between a gate and a source is higher than threshold voltage in a p-channel transistor, or the like in some cases.

In this specification and the like, “gate voltage” refers to voltage between a gate and a source, “drain voltage” refers to voltage between a drain and a source, and “back gate voltage” refers to voltage between a back gate and a source in some cases. In addition, “drain current” refers to current flowing between a drain and a source in some cases. The terms “high gate voltage,” “high drain voltage,” “high back gate voltage,” and the like of an n-channel transistor can be replaced with the terms “low gate voltage,” “low drain voltage,” “low back gate voltage,” and the like of a p-channel transistor, respectively, as appropriate in some cases. The terms “low gate voltage,” “low drain voltage,” “low back gate voltage,” and the like of an n-channel transistor can be replaced with the terms “high gate voltage,” “high drain voltage,” “high back gate voltage,” and the like of a p-channel transistor, respectively, as appropriate in some cases.

In this specification and the like, “off-state current” of a transistor refers to drain current of the transistor in an off state unless otherwise specified. Note that in this specification and the like, off-state current and current flowing between a gate and a source/drain (also referred to as gate leakage current) are sometimes referred to as leakage current.

### Embodiment 1

A semiconductor device of one embodiment of the present invention will be described with reference to drawings. A display apparatus of one embodiment of the present invention will also be described with reference to drawings. The semiconductor device can be used for part of the display apparatus, for example.

### Structure Example of Semiconductor Device

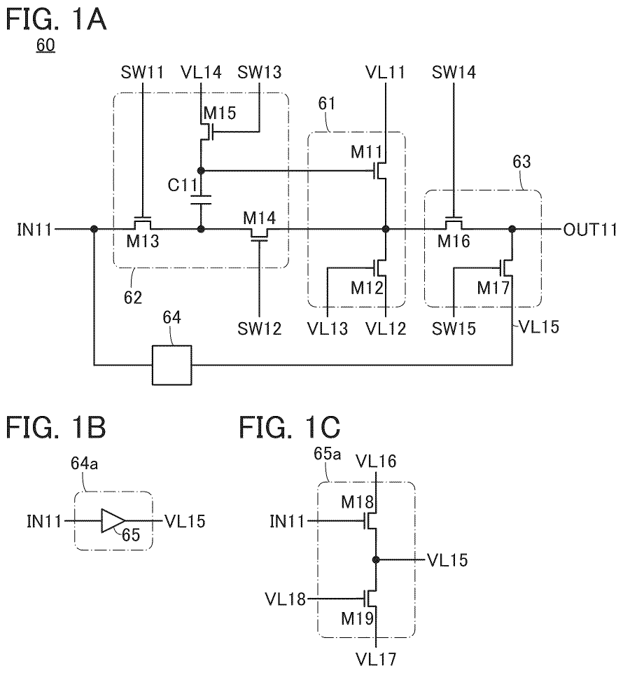

FIG. 1A is a circuit diagram showing a structure example of a semiconductor device of one embodiment of the present invention.

As shown in FIG. 1A, a semiconductor device 60 includes a transmission portion 61, an input portion 62, an output portion 63, and a generation portion 64. The transmission portion 61 is electrically connected to a wiring IN11 through the input portion 62 and is electrically connected to a wiring OUT11 through the output portion 63. The wiring IN11 is electrically connected to a wiring VL15 through the generation portion 64, and the wiring VL15 is electrically connected to the wiring OUT11 through the output portion 63.

The transmission portion 61 has a function of outputting a potential corresponding to an input potential. The input portion 62 has a function of transmitting a potential corresponding to a potential of the wiring IN11 to the transmission portion 61. The input portion 62 also has a function of correcting the potential input to the transmission portion 61. The output portion 63 has a function of transmitting a potential output from the transmission portion 61 to the wiring OUT11. The output portion 63 also has a function of transmitting a potential of the wiring VL15 to the wiring OUT11. The generation portion 64 has a function of generating a potential corresponding to the potential of the wiring IN11 and supplying the potential to the wiring VL15.

The transmission portion 61 includes a transistor M11 and a transistor M12. The input portion 62 includes a transistor M13, a transistor M14, a transistor M15, and a capacitor C11. The output portion 63 includes a transistor M16 and a transistor M17.

One of a source and a drain of the transistor M11 is electrically connected to one of a source and a drain of the transistor M12. The other of the source and the drain of the transistor M11 is electrically connected to a wiring VL11. The other of the source and the drain of the transistor M12 is electrically connected to a wiring VL12. A gate of the transistor M12 is electrically connected to a wiring VL13.

The transistor M11 has a function of outputting, to the one of the source and the drain, a potential corresponding to a potential supplied to its gate. The transistor M12 has a function of a current source that supplies drain current corresponding to a potential supplied to the gate. Thus, the transmission portion 61 has a function of a source follower in which the gate of the transistor M11 serves as an input terminal and the one of the source and the drain of the transistor M11 serves as an output terminal. In this specification and the like, a transistor that functions like the transistor M11 is sometimes referred to as a “driving transistor.” Moreover, a transistor that functions like the transistor M12 is sometimes referred to as a “load transistor.” The transmission portion 61 can also have a function of a source-grounded amplifier circuit. The transistor M12 having a function of a load transistor can be replaced with a resistor, for example.

One of a source and a drain of the transistor M13 is electrically connected to one terminal of the capacitor C11 and one of a source and a drain of the transistor M14. The other of the source and the drain of the transistor M13 is electrically connected to the wiring IN11. A gate of the transistor M13 is electrically connected to a wiring SW11. The transistor M13 has a function of establishing or breaking electrical continuity (a function of a switch) between the one terminal of the capacitor C11 and the wiring IN11 in accordance with a potential of the wiring SW11.

The other of the source and the drain of the transistor M14 is electrically connected to the one of the source and the drain of the transistor M11. A gate of the transistor M14 is electrically connected to a wiring SW12. The transistor M14 has a function of establishing or breaking electrical continuity (a function of a switch) between the one terminal of the capacitor C11 and the one of the source and the drain of the transistor M11 in accordance with a potential of the wiring SW12.

One of a source and a drain of the transistor M15 is electrically connected to the other terminal of the capacitor C11 and the gate of the transistor M11. A gate of the transistor M15 is electrically connected to a wiring SW13. The other of the source and the drain of the transistor M15 is electrically connected to a wiring VL14. The transistor M15 has a function of establishing or breaking electrical continuity (a function of a switch) between the other terminal of the capacitor C11 and the wiring VL14 in accordance with a potential of the wiring SW13.

The capacitor C11 has a function of retaining a potential difference (voltage) between a pair of terminals (between one terminal and the other terminal). That is, the capacitor C11 has a function of changing a potential of the other terminal in accordance with a change in a potential of the one terminal, for example. In other words, for example, the change in the potential of the one terminal (i.e., the one of the source and the drain of the transistor M13) can be transmitted to the other terminal (i.e., the gate of the transistor M11) through the capacitor C11. Furthermore, the capacitor C11 has a function of retaining a potential difference between the gate and the one of the source and the drain of the transistor M11, for example. That is, voltage corresponding to the threshold voltage of the transistor M11, for example, can be retained in the capacitor C11.

One of a source and a drain of the transistor M16 is electrically connected to one of a source and a drain of the transistor M17 and the wiring OUT11. The other of the source and the drain of the transistor M16 is electrically connected to the one of the source and the drain of the transistor M11. A gate of the transistor M16 is electrically connected to a wiring SW14. The transistor M16 has a function of establishing or breaking electrical continuity (a function of a switch) between the wiring OUT11 and the one of the source and the drain of the transistor M11 in accordance with a potential of the wiring SW14.

The other of the source and the drain of the transistor M17 is electrically connected to the wiring VL15. A gate of the transistor M17 is electrically connected to a wiring SW15. The transistor M17 has a function of establishing or breaking electrical continuity (a function of a switch) between the wiring OUT11 and the wiring VL15 in accordance with a potential of the wiring SW15.

FIG. 1B is a circuit diagram showing a structure example of the generation portion 64.

As shown in FIG. 1B, a generation portion 64a includes a buffer portion 65. The buffer portion 65 has a function of generating a potential corresponding to the potential of the wiring IN11 and supplying the potential to the wiring VL15.

FIG. 1C is a circuit diagram showing a structure example of the buffer portion 65.

As shown in FIG. 1C, a buffer portion 65a includes a transistor M18 and a transistor M19.

One of a source and a drain of the transistor M18 is electrically connected to one of a source and a drain of the transistor M19 and the wiring VL15. The other of the source and the drain of the transistor M18 is electrically connected to a wiring VL16. A gate of the transistor M18 is electrically connected to the wiring IN11. The other of the source and the drain of the transistor M19 is electrically connected to a wiring VL17. A gate of the transistor M19 is electrically connected to a wiring VL18.

The transistor M18 has a function of outputting, to the one of the source and the drain, a potential corresponding to a potential supplied to its gate. The transistor M19 has a function of a current source that supplies drain current corresponding to a potential supplied to the gate. Thus, the buffer portion 65a has a function of a source follower in which the gate of the transistor M18 serves as an input terminal and the one of the source and the drain of the transistor M18 serves as an output terminal. In other words, the transistor M18 has a function of a driving transistor, and the transistor M19 has a function of a load transistor. Note that the buffer portion 65a can also have a function of a source-grounded amplifier circuit. Note that the transistor M19 having a function of a load transistor can be replaced with a resistor, for example.

In this embodiment and the like, unless otherwise specified, the transistors (the transistor M11 to the transistor M19) included in the semiconductor device 60 are enhancement (normally-off) n-channel transistors. Thus, their threshold voltages are higher than 0 V.

Note that one embodiment of the present invention is not limited thereto. The semiconductor device 60 can be formed using a variety of transistors.

For example, as some or all of the transistors included in the semiconductor device 60, p-channel transistors may be used.

A transistor including any of a variety of semiconductors can be used as the transistor included in the semiconductor device 60. For example, a transistor including a single crystal semiconductor, a polycrystalline semiconductor, a microcrystalline semiconductor, or an amorphous semiconductor in a channel formation region can be used. Furthermore, as the semiconductor, for example, a compound semiconductor (e.g., silicon germanium or gallium arsenide), an oxide semiconductor, or the like as well as a single element semiconductor whose main component is a single element (e.g., silicon or germanium) can be used.

As the transistor included in the semiconductor device 60, any of a variety of transistors can be used. For example, a MOS field-effect transistor, a junction field-effect transistor, a bipolar transistor, or the like can be used.

Furthermore, as the transistor included in the semiconductor device 60, a transistor having any of a variety of structures can be used. For example, a transistor having any of a variety of structures such as a planar type, a staggered type, a FIN-type, a TRI-GATE type, a top-gate type, a bottom-gate type, and a dual-gate type (a structure in which gates are placed on the opposite sides with a channel formation region therebetween (placed above and below the channel formation region, for example) can be used. As the transistor included in the semiconductor device 60, a vertical transistor (a transistor in which at least part of a semiconductor layer including a channel formation region is provided along the side surface of an insulating layer in an opening formed in the insulating layer) is preferably used.

Note that in a vertical transistor, the source electrode and the drain electrode are positioned at different heights, which causes current flow in the height direction (also referred to as the vertical direction, the depth direction in the top view, or the direction perpendicular to the formation surface) in the channel formation region of the semiconductor layer. In other words, the channel length direction can be regarded as having a component of the height direction.

In a vertical transistor, the source region, the channel formation region, and the drain region can at least partly overlap with one another in the top view, enabling a smaller occupied area (footprint). Such a transistor enables reduced channel length and increased channel width, reducing on-state resistance (increasing on-state current).

Note that as a modification example of the above-described vertical transistor, a structure can be employed in which the source electrode and the drain electrode are positioned at the same height and current flows in the circumferential direction (the lateral direction) in the channel formation region of the semiconductor layer. In other words, the channel width direction can have a component of the height direction (vertical direction). A transistor having such a structure can be referred to as a VLFET (Vertical Lateral Field Effect Transistor) or the like. Since a VLFET can have a long channel length while occupying a small area, a short-channel effect such as drain-induced barrier lowering (DIBL) can be reduced, for example.

In one embodiment of the present invention, vertical transistors are preferably used as some or all of the transistors included in the semiconductor device 60. Vertical transistors are preferably used as the transistors serving as switches (the transistor M13 to the transistor M17), in particular.

Note that as the driving transistors (the transistor M11 and the transistor M18) and the load transistors (the transistor M12 and the transistor M19), transistors having high saturation (a small change in drain current with respect to drain voltage in a saturation region of each of the transistors) are preferably used. For example, a transistor with a long channel length is used. For example, the above-described VLFET may be used.

In one embodiment of the present invention, an OS transistor (a transistor including an oxide semiconductor in a channel formation region) is preferably used as the transistor included in the semiconductor device 60.

An OS transistor features an extremely low off-state current because the band gap of the oxide semiconductor where the channel is formed is greater than or equal to 2 eV. The off-state current value per micrometer of channel width of an OS transistor at room temperature can be less than or equal to 1 aA (1×10⁻¹⁸ A), less than or equal to 1 zA (1×10⁻²¹ A), or less than or equal to 1 yA (1×10⁻²⁴ A). Note that the off-state current value per micrometer of channel width of a Si transistor (a transistor including silicon in a channel formation region) at room temperature is greater than or equal to 1 fA (1×10⁻¹⁵ A) and less than or equal to 1 pA (1×10⁻¹² A). Thus, the off-state current of an OS transistor is lower than that of a Si transistor by approximately ten orders of magnitude.

Thus, for example, when OS transistors are used as the transistor M13 to the transistor M15 serving as switches among the transistors included in the semiconductor device 60, charge accumulated in the capacitor C11 can be retained for a long period. In other words, voltage corresponding to the threshold voltage of the transistor M11 can be retained in the capacitor C11 for a long period, for example. That is, for example, the frequency at which the input portion 62 corrects the potential input to the transmission portion 61 can be decreased. Thus, power consumption of the semiconductor device can be reduced.

For example, when OS transistors are used as the transistor M16 and the transistor M17 serving as switches among the transistors included in the semiconductor device 60, a potential of the wiring OUT11 can be retained for a long period.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125° C. and lower than or equal to 150° C.; thus, an excellent switching operation can be performed. Accordingly, a semiconductor device including an OS transistor achieves stable operation and high reliability even in a high temperature environment. This means that the use of OS transistors as the transistors included in the semiconductor device 60 can improve the reliability of the semiconductor device.

Moreover, the OS transistor has high source-drain breakdown voltage (also referred to as drain breakdown voltage). Accordingly, a semiconductor device including an OS transistor achieves stable operation and high reliability even when being driven with high voltage. That is, in the case where OS transistors are used as the transistor M11 and the transistor M12, for example, among the transistors included in the semiconductor device 60, the operation of the semiconductor device 60 is stable even when a potential difference (voltage) between a potential supplied to the wiring VL11 and a potential supplied to the wiring VL12 is large. Furthermore, in the case where OS transistors are used as the transistor M18 and the transistor M19, the operation of the semiconductor device 60 is stable even when a potential difference (voltage) between a potential supplied to the wiring VL16 and a potential supplied to the wiring VL17 is large. Accordingly, the reliability of the semiconductor device can be increased.

In one embodiment of the present invention, the semiconductor device 60 is not limited to having the structure using OS transistors and may have a structure using a plurality of kinds of transistors including different semiconductor materials may be employed. For example, the semiconductor device 60 may include a transistor including low-temperature polysilicon (LTPS) in its channel formation region (an LTPS transistor) and an OS transistor. The LTPS transistor has high field-effect mobility and favorable frequency characteristics. A structure in which the LTPS transistor and the OS transistor are used in combination is referred to as LTPO in some cases.

For example, the semiconductor device 60 can include OS transistors as the transistors serving as switches (the transistor M13 to the transistor M17), and LTPS transistors as the driving transistors (the transistor M11 and the transistor M18) and the load transistors (the transistor M12 and the transistor M19), among the transistors included in the semiconductor device. When the semiconductor device 60 is formed using both LTPS transistors and OS transistors, the semiconductor device can achieve reduced power consumption and improved driving capability.

In the case where the semiconductor device 60 includes a plurality of kinds of transistors including different semiconductor materials, the transistors may be provided in different layers for each kind of transistor. For example, in the case where the semiconductor device 60 includes a Si transistor and an OS transistor, a layer including the Si transistor and a layer including the OS transistor may be provided to overlap with each other. Such a structure enables the area occupied by the semiconductor device 60 to be small.

In one embodiment of the present invention, the semiconductor device 60 may include vertical OS transistors as the transistors serving as switches (the transistor M13 to the transistor M17), and dual-gate OS transistors as the driving transistors (the transistor M11 and the transistor M18) and the load transistors (the transistor M12 and the transistor M19), among the transistors included in the semiconductor device. Refer to Embodiment 2 described later for a specific structure example of such a semiconductor device including both a vertical transistor and a dual-gate transistor.

### Operation Example of Semiconductor Device

Next, an operation of the semiconductor device 60 is described.

Note that in this specification and the like, a potential difference (voltage) between a gate and a source of a transistor is referred to as “gate voltage” in some cases. This leads to the equation: “the gate voltage of a transistor”=“the gate potential of the transistor—“the source potential of the transistor”. In addition, a potential difference (voltage) between a back gate and a source of a transistor is referred to as “back gate voltage” in some cases. This leads to the equation: “the back gate voltage of a transistor”=“the back gate potential of the transistor”−“the source potential of the transistor”.

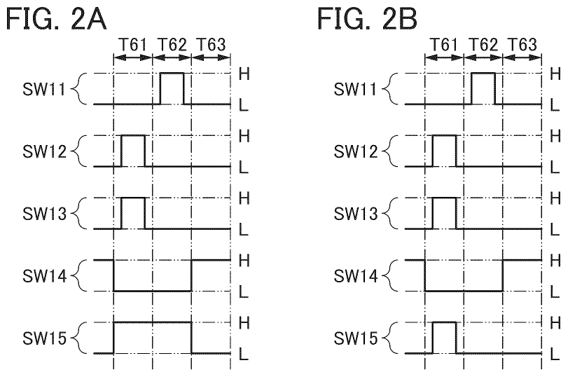

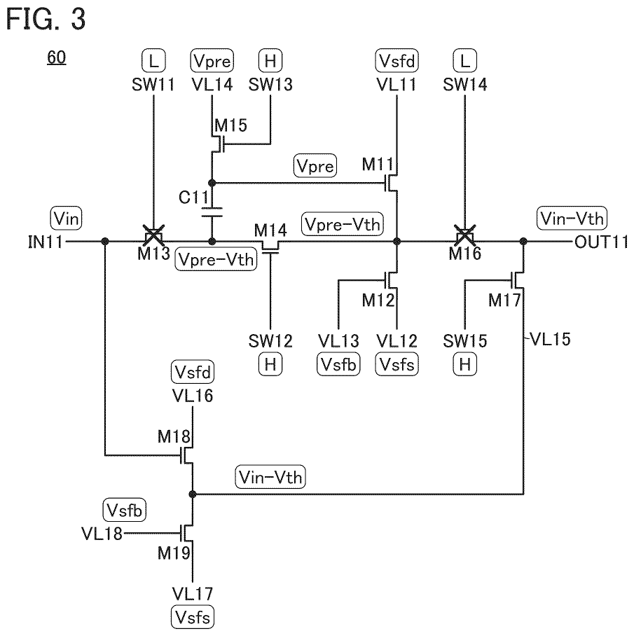

FIG. 2A is a timing chart showing an operation example of the semiconductor device 60. FIG. 3 to FIG. 5 are circuit diagrams showing the operation example of the semiconductor device 60. Note that the semiconductor device 60 shown in FIG. 3 to FIG. 5 has a structure in which the generation portion 64a shown in FIG. 1B and the buffer portion 65a shown in FIG. 1C are used in the semiconductor device 60 shown in FIG. 1A.

In the following description of the operation, a potential Vin is supplied to the wiring IN11. A potential Vsfd is supplied to the wiring VL11 and the wiring VL16, a potential Vsfs is supplied to the wiring VL12 and the wiring VL17, a potential Vsfb is supplied to the wiring VL13 and the wiring VL18, and a potential Vpre is supplied to the wiring VL14. A potential H or a potential L is supplied to each of the wiring SW11, the wiring SW12, the wiring SW13, the wiring SW14, and the wiring SW15.

The potential Vsfs is, for example, a potential lower than the lower limit of the potential range that the potential Vin can have. The potential Vsfd is, for example, a potential higher than the upper limit of the potential range that the potential Vin can have. The potential Vsfb is, for example, a potential higher than the potential Vsfs and lower than the potential Vsfd. The potential Vpre is, for example, a potential higher than the potential Vsfs and lower than the potential Vsfd. Note that the potential Vsfs, the potential Vsfd, and the potential Vsfb are supplied so that the transistor M11, the transistor M12, the transistor M18, and the transistor M19 each operate in the saturation region.

The potential H is a potential higher than the potential L. The difference between the potential H and the potential L is preferably greater than the threshold voltage of a transistor, for example. Here, when the potential H is input to the gate of a transistor included in the semiconductor device 60, the transistor is turned on (brought into a conduction state). When the potential L is input to the gate of a transistor included in the semiconductor device 60, the transistor is turned off (brought into a non-conduction state).

For easy understanding, the transistors included in the semiconductor device 60 have the same threshold voltage (voltage Vth).

Thus, the potential of the wiring VL15 is “potential Vin-voltage Vth”.

The timing chart in FIG. 2A shows the potentials (the potential H and the potential L) supplied to the wiring SW11, the wiring SW12, the wiring SW13, the wiring SW14, and the wiring SW15 in the operation periods (Period T61 to Period T63).

In this specification, drawings, and the like, loads on a wiring (parasitic capacitance and parasitic resistance), for example, sometimes generate a rise time and a fall time at the time of potential change. Such a time is, for example, longer than 0 second and is shorter than 1000 nanoseconds, shorter than 100 nanoseconds, shorter than 10 nanoseconds, or shorter than 1 nanosecond.

Furthermore, for example, two different operations that appear to occur at the same timing do not necessarily occur at exactly the same timing. The operations can be sometimes considered to occur at the same timing even though a signal delay of a wiring or the like causes a slight time lag between the operations, for example. The time lag is, for example, longer than 0 second and is shorter than 1000 nanoseconds, shorter than 100 nanoseconds, shorter than 10 nanoseconds, or shorter than 1 nanosecond. Accordingly, for example, “the same timing” can be replaced with “approximately the same timing,” “substantially the same timing,” “practically the same timing,” or the like as appropriate. This means that “the same timing” sometimes indicates “the same timing or substantially the same timing,” for example.

The plurality of wirings are not necessarily supplied with the same potential H or the same potential L. The potentials supplied to the wirings may be different from each other in consideration of the threshold voltage of the transistor supplied with the potential, for example.

The lengths of the periods in the timing chart may be different from each other through the lengths of the periods appear the same. For example, although the lengths of the periods (Period T61 to Period T63) appear the same in the timing chart in FIG. 2A for easy understanding, the lengths of the periods may be different from each other.

In FIG. 3 to FIG. 5, a symbol showing a potential (also referred to as a potential symbol) such as “H”, “L”, “Vin”, or “Vpre” is sometimes expressed by an enclosed character near a wiring or a node. Furthermore, a symbol “x” sometimes overlaps with an off-state transistor.

In Period T61 shown in FIG. 2, in the input portion 62, an operation where voltage for correcting the threshold voltage of the transistor M11 included in the transmission portion 61 is obtained and the voltage is retained in the capacitor C11 (correction operation) is performed. Furthermore, an operation where a potential corresponding to the potential of the wiring IN11 is generated in the generation portion 64 and supplied to the wiring OUT11 through the output portion 63 (precharge operation) is performed. Next, in Period T62, an operation where the potential of the wiring IN11 is input to the transmission portion 61 through the input portion 62 (input operation) is performed. Subsequently, in Period T63, an operation where a potential output from the transmission portion 61 is supplied to the wiring OUT11 through the output portion 63 (output operation) is performed.

In the transmission portion 61 included in the semiconductor device 60, the potential of the one of the source and the drain of the transistor M11 has a value obtained by subtracting the threshold voltage of the transistor M11 from the potential of the gate of the transistor M11. Thus, for example, in a display apparatus including a plurality of semiconductor devices 60, even when the same potential is supplied to the gates of the transistors M11 included in the semiconductor devices 60, different threshold voltages of the transistors M11 lead to a variation in the potential of the one of the source and the drain of the transistor M11 between the semiconductor devices 60. Accordingly, variations in the threshold voltage between the transistors M11 are a factor in reducing display quality of the display apparatus.

Thus, performing a correction operation described below in the semiconductor device 60 enables the transmission portion 61 to output a potential that does not depend on the threshold voltage. This can improve the display quality of the display apparatus including the semiconductor device 60 can be improved.

Meanwhile, in the output operation where the transistor M16 is turned on in the output portion 63 and the potential output from the transmission portion 61 is supplied to the wiring OUT11, it takes time to stabilize the potential of the wiring OUT11 (this time is also referred to as a settling time). In particular, the settling time is long when the potential of the wiring OUT11 is changed so as to be lowered. This is one factor in reducing the operation speed of the display apparatus including the semiconductor device 60.

Note that as an example of a method for shortening the settling time, a method in which the on-state current of the transistor M11 and the transistor M12 is increased by increasing the channel widths of the transistors can be given. Another example includes a method in which the amount of current flowing through the transistor M12 serving as a current source is increased by increasing the potential supplied to the gate of the transistor M12 (the potential Vsfb supplied to the wiring VL13). However, these methods increase the area occupied by the semiconductor device 60 and the power consumption thereof, for example. Thus, there is a trade-off between an improvement in operation speed of the display apparatus including the semiconductor device 60, and an increase in resolution and a reduction in power consumption.

In view of this, by performing a precharge operation described below in the semiconductor device 60, the potential of the wiring OUT11 can be set to a potential close to the potential of the wiring IN11 before the output operation. Accordingly, the difference between the potential output from the transmission portion 61 and the potential of the wiring OUT11 can be small in the input operation, enabling the settling time to be short in the subsequent output operation. Thus, the operation speed of the display apparatus including the semiconductor device 60 can be increased while increases in the area occupied by the semiconductor device 60 and the power consumption thereof are suppressed.

### Correction Operation and Precharge Operation

Immediately before Period T61, the potential L is supplied to the wiring SW11, the wiring SW12, the wiring SW13, and the wiring SW15, and the potential H is supplied to the wiring SW14. Thus, the transistor M13, the transistor M14, the transistor M15, and the transistor M17 are in the off state, and the transistor M16 is in the on state. That is, an output operation is performed. Note that in the following description of the operation, unless otherwise specified, the potentials of the wirings in the immediately preceding period are maintained.

In Period T61, first, the output operation is stopped, and the precharge operation starts. Specifically, the potential L is supplied to the wiring SW14 and the potential H is supplied to the wiring SW15. Then, the transistor M16 is turned off and the transistor M15 is turned on. Thus, the potential of the wiring OUT11 becomes “potential Vin-voltage Vth”.

Next, the correction operation starts. Specifically, the potential H is supplied to the wiring SW12 and the wiring SW13. Then, the transistor M14 and the transistor M15 are turned on. Thus, the potential of the gate of the transistor M11 becomes “potential Vpre”, and the potential of the one of the source and the drain of the transistor M11 becomes “potential Vpre-voltage Vth”. That is, the potential of the one terminal of the capacitor C11 becomes “potential Vpre-voltage Vth”, and the potential of the other terminal of the capacitor C11 becomes “potential Vpre”. That is, “voltage Vth”, which is the threshold voltage of the transistor M11, is applied between the pair of terminals of the capacitor C11.

That is, the correction operation and the precharge operation are performed in parallel. FIG. 3 shows the state of the semiconductor device 60 at this time.

After that, the correction operation is terminated. Specifically, the potential L is supplied to the wiring SW12 and the wiring SW13. Then, the transistor M14 and the transistor M15 are turned off. Thus, the state where “voltage Vth” is applied between the pair of terminals of the capacitor C11 is maintained. Note that the precharge operation continues.

### Input Operation

In Period T62, the input operation starts. Specifically, the potential H is supplied to the wiring SW11. Then, the transistor M13 is turned on. Thus, a potential of the one of the source and the drain of the transistor M13, that is, the potential of the one terminal of the capacitor C11 becomes “potential Vin”. At this time, the potential of the other terminal of the capacitor C11, that is, the potential of the gate of the transistor M11 becomes “potential Vin+voltage Vth”. Thus, the potential of the one of the source and the drain of the transistor M11 becomes “potential Vin”.

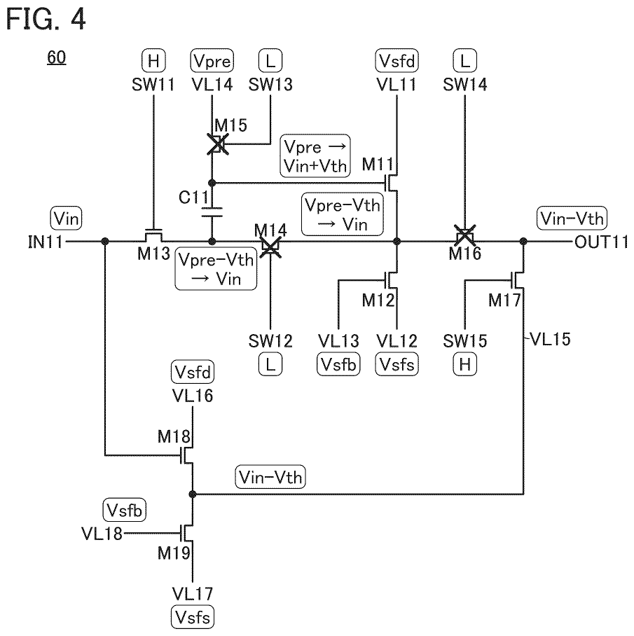

That is, the input operation and the precharge operation are performed in parallel. FIG. 4 shows the state of the semiconductor device 60 at this time.

After that, the input operation is terminated. Specifically, the potential L is supplied to the wiring SW11. Then, the transistor M13 is turned off. Thus, the state where the potential of the gate of the transistor M11 is “potential Vin+voltage Vth” and the potential of the one of the source and the drain of the transistor M11 is “potential Vin” is maintained. Note that the precharge operation continues.

### Output Operation

In Period T63, the precharge operation is stopped, and the output operation starts. Specifically, the potential H is supplied to the wiring SW14, and the potential L is supplied to the wiring SW15. Then, the transistor M16 is turned on and the transistor M15 is turned off. Thus, the potential of the wiring OUT11 becomes “potential Vin”.

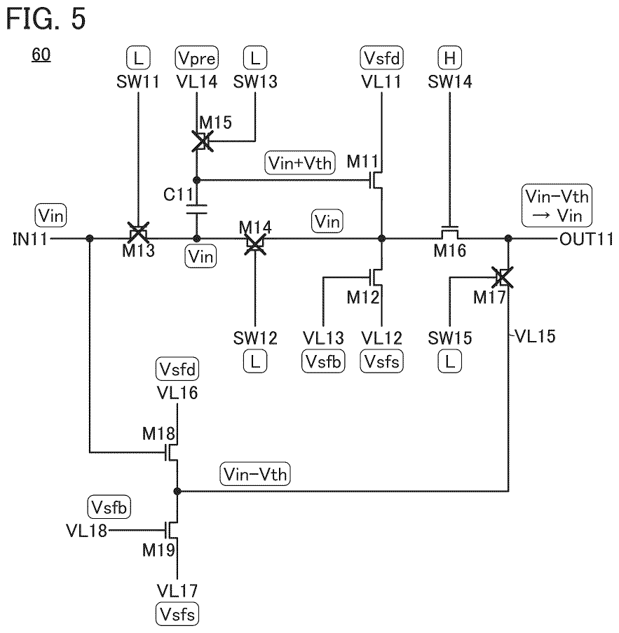

FIG. 5 shows the state of the semiconductor device 60 at this time.

In one embodiment of the present invention, in the semiconductor device 60, the precharge operation is performed before the output operation, and the correction operation and the input operation are performed in a period during which the precharge operation is performed, as described above. This enables the display apparatus including the semiconductor device 60 to achieve both an improvement in display quality and an increase in operation speed.

One embodiment of the present invention is not limited to the above operation example.

FIG. 2B is a timing chart showing another operation example of the semiconductor device 60. The timing chart shown in FIG. 2B is different from the timing chart shown in FIG. 2A in that the potential supplied to the wiring SW15 changes at the same timing as the potentials supplied to the wiring SW12 and the wiring SW13. That is, the timing chart shown in FIG. 2B is an example of the following operations: the correction operation is performed in a period during which the precharge operation is performed, and the input operation is performed in a period from the stop of the precharge operation to the start of the output operation.

### Another Structure Example of Semiconductor Device

One embodiment of the present invention is not limited to the above-described structure example of the semiconductor device.

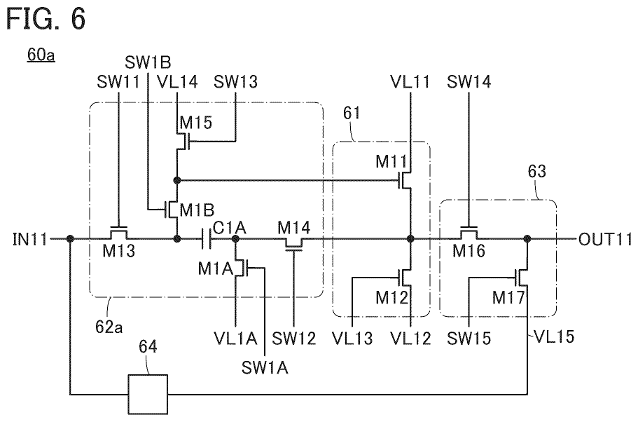

FIG. 6 is a circuit diagram showing a semiconductor device 60a, which is a modification example of the semiconductor device 60. The semiconductor device 60a includes an input portion 62a instead of the input portion 62. The input portion 62a is different from the input portion 62 in not including the capacitor C11 and in including a transistor M1A, a transistor M1B, and a capacitor C1A.

The one of the source and the drain of the transistor M13 is electrically connected to the one of the source and the drain of the transistor M1B and one terminal of the capacitor C1A. The one of the source and the drain of the transistor M14 is electrically connected to one of a source and a drain of the transistor M1A and the other terminal of the capacitor C1A. The one of the source and the drain of the transistor M15 is electrically connected to the other of the source and the drain of the transistor M1B and the gate of the transistor M11. The other of the source and the drain of the transistor M1A is electrically connected to a wiring VL1A. A gate of the transistor M1A is electrically connected to a wiring SW1A. A gate of the transistor M1B is electrically connected to the wiring SW1B.

In the correction operation and the input operation in the semiconductor device 60a, for example, first, the potential H is supplied to the wiring SW11, the wiring SW12, and the wiring SW13, and the potential L is supplied to the wiring SW1A and the wiring SW1B. After that, the potential L is supplied to the wiring SW12 and the wiring SW13, and the potential H is supplied to the wiring SWIB. Next, the potential L is supplied to the wiring SW11, and the potential H is supplied to the wiring SW1A. Note that the precharge operation and the output operation are similar to those in the above-described operation example of the semiconductor device 60.

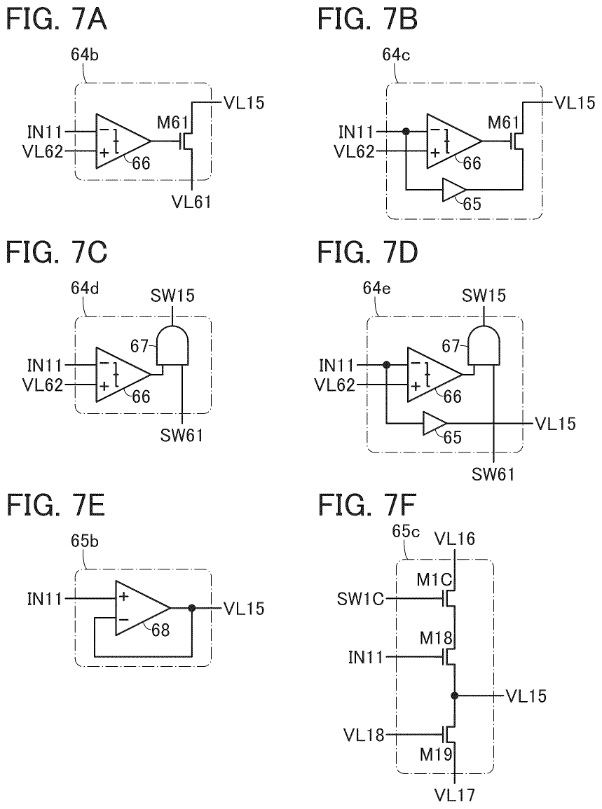

FIG. 7A is a circuit diagram showing a generation portion 64b, which is another structure example of the generation portion 64. The generation portion 64b includes a comparator portion 66 and a transistor M61. An inverting input terminal of the comparator portion 66 is electrically connected to the wiring IN11. A non-inverting input terminal of the comparator portion 66 is electrically connected to a wiring VL62. An output terminal of the comparator portion 66 is electrically connected to a gate of the transistor M61. One of a source and a drain of the transistor M61 is electrically connected to the wiring VL15. The other of the source and the drain of the transistor M61 is electrically connected to a wiring VL61. The generation portion 64b has a function of supplying a potential of the wiring VL61 to the wiring VL15 when the potential of the wiring IN11 is lower than a potential of the wiring VL62. Note that a circuit structure of a common comparator can be used for the comparator portion 66. For example, both an n-channel transistor and a p-channel transistor may be used, or only n-channel transistors or p-channel transistors may be used.

FIG. 7B is a circuit diagram showing a generation portion 64c, which is another structure example of the generation portion 64. The generation portion 64c has a structure in which the generation portion 64a and the generation portion 64b are combined. The generation portion 64c has a function of supplying a potential corresponding to the potential of the wiring IN11 to the wiring VL15 when the potential of the wiring IN11 is lower than the potential of the wiring VL62.

FIG. 7C is a circuit diagram showing a generation portion 64d, which is another structure example of the generation portion 64. The generation portion 64d includes the comparator portion 66 and the AND arithmetic portion 67. The inverting input terminal of the comparator portion 66 is electrically connected to the wiring IN11. The non-inverting input terminal of the comparator portion 66 is electrically connected to the wiring VL62. The output terminal of the comparator portion 66 is electrically connected to one input terminal of the AND arithmetic portion 67. The other input terminal of the AND arithmetic unit 67 is electrically connected to a wiring SW61. An output terminal of the AND arithmetic unit 67 is electrically connected to the wiring SW15. The generation portion 64d has a function of supplying a potential of the wiring SW61 (e.g., the potential H or the potential L) to the wiring SW15 when the potential of the wiring IN11 is lower than the potential of the wiring VL62, or supplying the potential L to the wiring SW15 when the potential of the wiring IN11 is higher than the potential of the wiring VL62, for example. Note that a circuit structure of a common AND gate can be used for the AND arithmetic unit 67. For example, both an n-channel transistor and a p-channel transistor may be used, or only n-channel transistors or p-channel transistors may be used.

FIG. 7D is a circuit diagram showing a generation portion 64e, which is another structure example of the generation portion 64. The generation portion 64e has a structure in which the generation portion 64a and the generation portion 64d are combined. The generation portion 64d has a function of supplying the potential of the wiring SW61 (e.g., the potential H or the potential L) to the wiring SW15 when a potential corresponding to the potential of the wiring IN11 is supplied to the wiring VL15 and the potential of the wiring IN11 is lower than the potential of the wiring VL62, or supplying the potential L to the wiring SW15 when the potential of the wiring IN11 is higher than the potential of the wiring VL62, for example.

FIG. 7E is a circuit diagram showing a buffer portion 65b, which is another structure example of the buffer portion 65. The buffer portion 65b includes an operational amplifier portion 68. A non-inverting input terminal of the operational amplifier portion 68 is electrically connected to the wiring IN11. An output terminal of the operational amplifier portion 68 is electrically connected to an inverting input terminal of the operational amplifier portion 68 and the wiring VL15. Thus, the buffer portion 65b has a function of a voltage follower. Note that a circuit structure of a common operational amplifier can be used for the operational amplifier portion 68. For example, both an n-channel transistor and a p-channel transistor may be used, or only n-channel transistors or p-channel transistors may be used.

FIG. 7F is a circuit diagram showing a buffer portion 65c, which is another structure example of the buffer portion 65. The buffer portion 65c includes a transistor M1C in addition to the buffer portion 65a. One of a source and a drain of the transistor M1C is electrically connected to the other of the source and the drain of the transistor M18. The other of the source and the drain of the transistor M1C is electrically connected to the wiring VL16. A gate of the transistor M1C is electrically connected to a wiring SW1C. The transistor M1C has a function of establishing or breaking electrical continuity (a function of a switch) between the other of the source and the drain of the transistor M18 and the wiring VL16 in accordance with a potential of the wiring SWIC.

Note that although the structure in which the transistor M1C is provided between the other of the source and the drain of the transistor M18 and the wiring VL16 is described here, one embodiment of the present invention is not limited thereto, and a structure in which the transistor M1C is provided between the other of the source and the drain of the transistor M19 and the wiring VL17 may be employed, for example.

The potential supplied to the wiring SW1C is preferably the same as the potential supplied to the wiring SW15, for example. That is, when the transistor M17 is in a conduction state, the transistor M1C is also in a conduction state, and when the transistor M17 is in a non-conduction state, the transistor M1C is also in a non-conduction state. With such a structure, current can be supplied to the transistor M18 and the transistor M19 only in a period during which the potential of the wiring VL15 is transmitted to the wiring OUT11, and the supply of current can be stopped all the time except for the period. Accordingly, power consumption can be reduced.

Note that one embodiment of the present invention is not limited to the structure of the above-described semiconductor device 60. In one embodiment of the present invention, for example, the generation portion 64 may be provided outside the semiconductor device 60.

### Structure Example of Display Apparatus

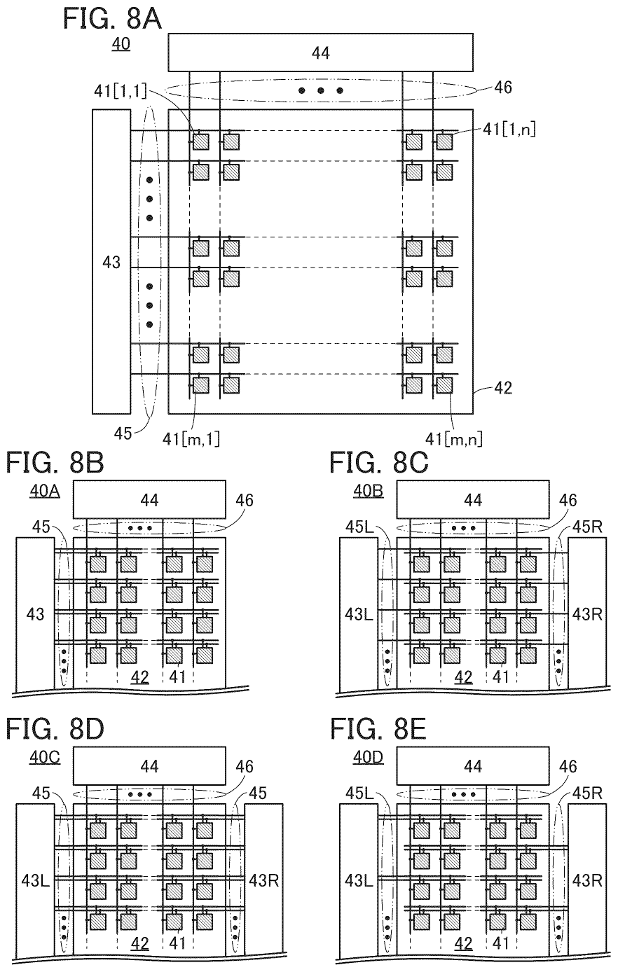

FIG. 8A to FIG. 8E are block diagrams showing a structure example of a display apparatus of one embodiment of the present invention.

As shown in FIG. 8A, a display apparatus 40 includes a display portion 42, a first driver circuit portion 43, and a second driver circuit portion 44. The display portion 42 includes a plurality of pixels 41 arranged in a matrix of m rows and n columns (m and n are each an integer greater than or equal to 2). In FIG. 8A, the pixel 41 placed in the first row and the first column is denoted as a pixel 41[1,n ], the pixel 41 placed in a first row and an n-th column is denoted as a pixel 41[1,n], the pixel 41 placed in an m-th row and a first column is denoted as a pixel 41 [m,1], and the pixel 41 placed in an m-th row and an n-th column is denoted as a pixel 41[m, n]. Note that the pixel 41 placed in a u-th row and a v-th column is denoted as a pixel 41 [u, v] (u is an integer greater than or equal to 1 and less than or equal to m and v is an integer greater than or equal to 1 and less than or equal to n) in some cases.

The display apparatus 40 includes m wirings 45 which are placed in parallel or substantially parallel with each other and whose potentials are controlled by a circuit included in the first driver circuit portion 43. The potential of one wiring 45 is supplied to n pixels 41 arranged in the row direction. Note that a plurality of wirings may form one wiring 45 depending on the structure of the pixel 41. In a display apparatus 40A shown in FIG. 8B, two wirings form one wiring 45.

The display apparatus 40 includes n wirings 46 which are placed in parallel or substantially parallel with each other and whose potentials are controlled by a circuit included in the second driver circuit portion 44. The potential of one wiring 46 is supplied to m pixels 41 arranged in the column direction. Note that a plurality of wirings may form one wiring 46 depending on the structure of the pixel 41.

The pixel 41 has a function of making the light-emitting element emit light with an emission intensity corresponding to the data potential when a data potential is written to a pixel circuit selected by the potential of the wiring 45 through the wiring 46, for example. Specific structure examples of the pixel 41 will be described later.

The circuit included in the first driver circuit portion 43 serves as, for example, a scan line driver circuit (sometimes referred to as a gate line driver circuit, a gate driver, a scan driver, or a row driver).

The circuit included in the second driver circuit portion 44 serves as, for example, a signal line driver circuit (sometimes referred to as a source line driver circuit, a source driver, a data driver, or a column driver). For example, the circuit may have a function of converting data of an image (image data) to be displayed on the display apparatus 40 into the data potential (digital-to-analog conversion).

In each of the pixels 41, current flowing through the light-emitting element can be output to a monitor line, for example. The current output to the monitor line can be output to the outside of the display apparatus 40 after being subjected to conversion into analog voltage (current-to-voltage conversion) or into a digital signal (analog-to-digital conversion) in the second driver circuit portion 44, for example. The analog voltage or the digital signal can be used for image data correction in the outside of the display apparatus (also referred to as external correction), for example.

Note that in this specification and the like, circuits included in the first driver circuit portion 43 and the second driver circuit portion 44 are collectively referred to as a “peripheral driver circuit” in some cases.

The peripheral driver circuit can be formed using various constituent circuits. Examples of the constituent circuits include a shift register circuit, a flip-flop circuit, a latch circuit, a buffer circuit, an inverter circuit, and a level shifter circuit. Other examples include a multiplexer circuit, a demultiplexer circuit, a source follower circuit, a source-grounded amplifier circuit, a sample-and-hold circuit, and a switch circuit (such as a transmission gate or an analog switch). Other examples include a current-to-voltage converter circuit, an analog-to-digital converter circuit, a digital-to-analog converter circuit, an operational amplifier circuit, a comparator circuit, a pass transistor logic circuit, an encoder circuit, a decoder circuit, and a gate circuit (such as an AND circuit, an OR circuit, or a NOT circuit). Other examples include circuits combining these circuits. Note that these constituent circuits can be formed with, for example, a transistor, a capacitor, and the like.

Specific structure examples of the constituent circuits that can be used as the peripheral driver circuits will be described later.

The semiconductor device 60 described above can be used as at least part of the peripheral driver circuit. For example, the semiconductor device 60 can be used as at least part of the second driver circuit portion 44. In that case, for example, the second driver circuit portion 44 includes n semiconductor devices 60, and the wiring OUT11 included in each semiconductor device 60 corresponds to the wiring 46.

In one embodiment of the present invention, various transistors can be used as transistors included in the peripheral driver circuit as in the semiconductor device 60 described above. For example, a vertical transistor can be used as some or all of the transistors included in the peripheral driver circuit.

The use of vertical OS transistors as some or all of the transistors included in the peripheral driver circuit can reduce the area occupied by a buffer circuit included in the gate driver, for example. Accordingly, the display apparatus can have a narrower bezel, for example. Furthermore, for example, the area occupied by a demultiplexer, a source follower, and the like included in the source driver can be reduced. This leads to the higher resolution and definition of the display apparatus.

Note that, for example, Si transistors may be used as some or all of the transistors included in the peripheral driver circuit. Both an OS transistor and a Si transistor may be used, for example. The Si transistor has higher operation speed than the OS transistor. For example, by electrically connecting a gate of an n-channel transistor and a gate of a p-channel transistor, a CMOS circuit (e.g., a circuit that operates complementarily, a CMOS logic gate, a CMOS logic circuit, or the like) can be formed.

In one embodiment of the present invention, any of a variety of structures can be employed for modification examples of the display apparatus 40. For example, as shown in FIG. 8C to FIG. 8E, a first driver circuit portion 43L and a first driver circuit portion 43R can be arranged to face each other with the display portion 42 sandwiched therebetween.

In the structure example shown in FIG. 8C, a display apparatus 40B includes m wirings 45L whose potentials are controlled by a circuit included in the first driver circuit portion 43L and m wirings 45R whose potentials are controlled by a circuit included in the first driver circuit portion 43R. The potentials of one wiring 45L and one wiring 45R are supplied to n pixels 41 arranged in the row direction.

A display apparatus 40C shown in FIG. 8D includes m wirings 45 whose potentials are controlled by both the circuit included in the first driver circuit portion 43L and the circuit included in the first driver circuit portion 43R. The potential of one wiring 45 is supplied to n pixels 41 arranged in the row direction. Such a structure reduces substantial loads on the wiring (parasitic capacitance and parasitic resistance) to a quarter of the load on the wiring of the display apparatus 40A shown in FIG. 8B. Accordingly, the display apparatus can achieve higher speed, resolution, and definition, a narrower bezel, and a larger screen, for example.

In the structure example shown in FIG. 8E, a display apparatus 40D includes m/2 wirings 45L whose potentials are controlled by the circuit included in the first driver circuit portion 43L and m/2 wirings 45R whose potentials are controlled by the circuit included in the first driver circuit portion 43R. The potential of one wiring 45L is supplied to n pixels 41 arranged in odd-numbered rows in the row direction. The potential of one wiring 45R is supplied to n pixels 41 arranged in even-numbered rows in the row direction. Such a structure can halve the number of stages of a shift register, for example. Accordingly, the display apparatus can achieve higher speed, resolution, and definition, a narrower bezel, and a larger screen, for example.

Although not shown, for example, two second driver circuit portions 44 may be arranged to face each other with the display portion 42 sandwiched therebetween.

According to one embodiment of the present invention, for example, the display apparatus 40 can employ not only any of a variety of structures described above but also the structure where a sensor portion is provided to overlap with the display portion 42 in a top view. The sensor portion can serve as, for example, a touch sensor, a near touch sensor, or a fingerprint sensor. Such a sensor can be a capacitive touch sensor or an optical touch sensor, for example.

In the display apparatus 40 provided with the sensor portion, the first driver circuit portion 43 (or the first driver circuit portion 43L and the first driver circuit portion 43R) can include a circuit having a function of driving the sensor portion, for example. The second driver circuit portion 44 can include a circuit having a function of outputting a signal detected by the sensor portion to the outside of the display apparatus, for example.

### Structure Example of Pixel

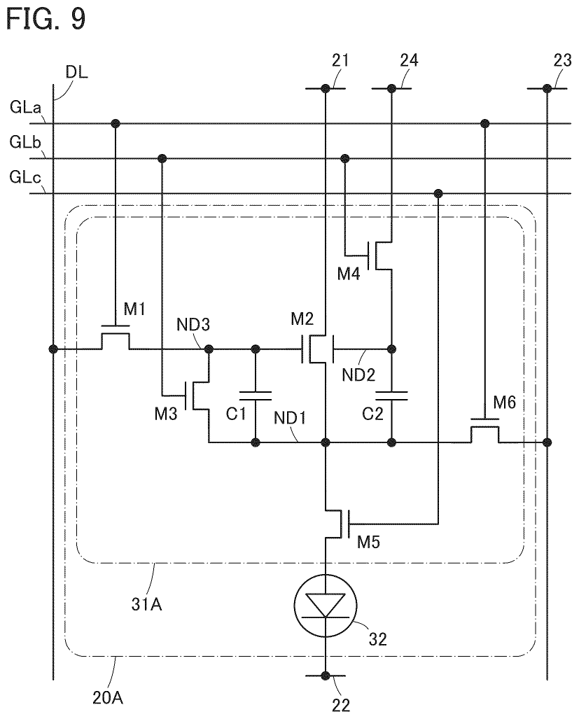

FIG. 9 is a circuit diagram showing a structure example of a semiconductor device that can be used in the pixel 41.

As shown in FIG. 9, a semiconductor device 20A includes a pixel circuit 31A and a light-emitting element 32. Specifically, the pixel circuit 31 A includes a transistor M1, a transistor M2, a transistor M3, a transistor M4, a transistor M5, a transistor M6, a capacitor C1, and a capacitor C2.

A gate of the transistor M1 is electrically connected to a wiring GLa. One of a source and a drain of the transistor M1 is electrically connected to a gate of the transistor M2. The other of the source and the drain of the transistor M1 is electrically connected to a wiring DL. The transistor M1 has a function of establishing or breaking electrical continuity between the gate of the transistor M2 and the wiring DL (a function of a switch).

The gate of the transistor M2 is electrically connected to one terminal of the capacitor C1. One of a source and a drain of the transistor M2 is electrically connected to the other terminal of the capacitor C1. The other of the source and the drain of the transistor M2 is electrically connected to a wiring 21. The transistor M2 has a back gate. The back gate of the transistor M2 is electrically connected to one terminal of the capacitor C2. The other terminal of the capacitor C2 is electrically connected to the one of the source and the drain of the transistor M2.

A gate of the transistor M3 is electrically connected to a wiring GLb. One of a source and a drain of the transistor M3 is electrically connected to the one terminal of the capacitor C1. The other of the source and the drain of the transistor M3 is electrically connected to the other terminal of the capacitor C1. The transistor M3 has a function of establishing or breaking electrical continuity between the gate of the transistor M2 and the one of the source and the drain of the transistor M2 (a function of a switch).

A gate of the transistor M4 is electrically connected to the wiring GLb. One of a source and a drain of the transistor M4 is electrically connected to the one terminal of the capacitor C2. The other of the source and the drain of the transistor M4 is electrically connected to a wiring 24. The transistor M4 has a function of establishing or breaking electrical continuity between the one terminal of the capacitor C2 and the wiring 24 (a function of a switch).

A gate of the transistor M5 is electrically connected to a wiring GLc. One of a source and a drain of the transistor M5 is electrically connected to the one of the source and the drain of the transistor M2. The other of the source and the drain of the transistor M5 is electrically connected to one terminal (e.g., an anode terminal) of the light-emitting element 32. The transistor M5 has a function of establishing or breaking electrical continuity between the one of the source and the drain of the transistor M2 and the one terminal of the light-emitting element 32 (a function of a switch).

A gate of the transistor M6 is electrically connected to the wiring GLa. One of a source and a drain of the transistor M6 is electrically connected to the one of the source and the drain of the transistor M2. The other of the source and the drain of the transistor M6 is electrically connected to a wiring 23. The transistor M6 has a function of establishing or breaking electrical continuity between the one of the source and the drain of the transistor M2 and the wiring 23 (a function of a switch).

The other terminal (e.g., a cathode terminal) of the light-emitting element 32 is electrically connected to a wiring 22.

The light-emitting element 32 emits light with emission intensity corresponding to the amount of current flowing through the light-emitting element 32. As the light-emitting element 32, any of a variety of elements such as an EL (Electro Luminescence) element (an EL element including an organic substance and an inorganic substance, an organic EL element, and an inorganic EL element), a light-emitting diode (LED), a micro LED (e.g., an LED where the area of a light-emitting region is less than or equal to 10000 μm²), an OLED (Organic Light Emitting Diode), a QLED (Quantum-dot Light Emitting Diode), and an electron emitter element can be used, for example.

The transistor M2 can change drain current in accordance with the potential supplied to the gate. Thus, in the pixel circuit 31A, the transistor M2 has a function of controlling the amount of current flowing through the light-emitting element 32. That is, the transistor M2 has a function of controlling the emission intensity of the light-emitting element 32. In this specification and the like, a transistor having a function of the transistor M2 is sometimes referred to as “driving transistor.”

The threshold voltage of the transistor M2 can be changed depending on a potential supplied to the back gate. Thus, the pixel circuit 31A can correct the threshold voltage of the transistor M2 in accordance with the potential supplied to the back gate of the transistor M2 (a node ND2). In other words, in the display apparatus including the pixel circuits 31A, variation in the threshold voltage of the transistor M2 among the pixel circuits 31A can be corrected. In this specification and the like, a pixel circuit that can correct the threshold voltage of a driving transistor (transistor M2) like the pixel circuit 31A is also referred to as a pixel circuit incorporating “internal correction circuit.” Incorporating an internal correction circuit leads to higher display quality of the display apparatus.

A node ND1 sometimes refers to a region where the one of the source and the drain of the transistor M2, the other of the source and the drain of the transistor M3, the one of the source and the drain of the transistor M5, the one of the source and the drain of the transistor M6, the other terminal of the capacitor C1, and the other terminal of the capacitor C2 are electrically connected to one another.

Note that the node ND2 sometimes refers to a region where the back gate of the transistor M2, the one of the source and the drain of the transistor M4, and the one terminal of the capacitor C2 are electrically connected to one another.

A node ND3 sometimes refers to a region where the gate of the transistor M2, the one of the source and the drain of the transistor M1, the one of the source and the drain of the transistor M3, and the one terminal of the capacitor C1 are electrically connected to one another.

The capacitor C1 has, for example, a function of retaining a potential difference (voltage) between the one of the source and the drain of the transistor M2 and the gate of the transistor M2 at the time when the node ND3 is in a floating state.

The capacitor C2 has, for example, a function of retaining a potential difference (voltage) between the one of the source and the drain of the transistor M2 and the back gate of the transistor M2 at the time when the node ND2 is in a floating state.

The wiring GLa, the wiring GLb, and the wiring GLc are referred to as, for example, gate lines, scan lines, or selection lines in some cases. The wiring DL is referred to as, for example, a source line, a data line, or a signal line in some cases.

In this embodiment and the like, unless otherwise specified, the transistors (the transistor M1 to the transistor M6) included in the pixel circuit 31A are enhancement (normally-off) n-channel transistors. Thus, their threshold voltages are higher than 0 V.

Note that one embodiment of the present invention is not limited thereto. The pixel circuit 31A can be formed using a variety of transistors like the above-described semiconductor device 60.

For example, as some or all of the transistors included in the pixel circuit 31A, p-channel transistors may be used.

Furthermore, a vertical transistor may be used as the transistor included in the pixel circuit 31A.

With the use of a vertical transistor in a pixel circuit, for example, the resolution (also referred to as pixel density) of a display apparatus using the pixel circuit can be increased. Furthermore, as pixel arrangement, a PenTile arrangement can be replaced with a stripe arrangement without decreasing the resolution of the display apparatus, for example. In addition, an internal correction circuit can be incorporated without decreasing the resolution of the display apparatus, for example.

In one embodiment of the present invention, vertical transistors are preferably used as some or all of the transistors included in the pixel circuit 31A. Vertical transistors are preferably used as the transistors serving as switches (the transistor M1 and the transistor M3 to the transistor M6), in particular.

Note that as the driving transistor (the transistor M2), a transistor having high saturation is preferably used. For example, a transistor with a long channel length is used. For example, the above-described VLFET may be used.

In one embodiment of the present invention, an OS transistor with extremely low off-state current is preferably used as a transistor included in the pixel circuit 31A.

For example, when OS transistors are used as the transistors serving as switches (the transistor M1 and the transistor M3 to the transistor M6) among the transistors included in the pixel circuit 31A, charge accumulated in the capacitor C1 and the capacitor C2 can be retained for a long period.

Accordingly, in the case of displaying a still image for which rewriting every frame is not required, the display apparatus using the pixel circuit can continue displaying the image even after the operation of a peripheral driver circuit that drives the pixel circuit is stopped, for example. In this specification and the like, such a driving method in which the operation of a peripheral driver circuit is stopped during displaying a still image is also referred to as “idling stop driving”. The power consumption of the display apparatus can be reduced by performing idling stop driving.

In the display apparatus using the pixel circuit, the potential supplied to a back gate of the driving transistor can be retained for a long period, for example. Accordingly, even when the operation of correcting the threshold voltage of the driving transistor is performed not every frame but every few frames or every few seconds, for example, the display quality of the display apparatus can be improved.

In one embodiment of the present invention, the pixel circuit 31A is not limited to having the structure using OS transistors and may have a structure using a plurality of kinds of transistors including different semiconductor materials may be employed. For example, the pixel circuit 31A may include LTPO (i.e., both the LTPS transistor and the OS transistor).

For example, the pixel circuit 31A can include OS transistors as the transistors serving as switches (the transistor M1 and the transistor M3 to the transistor M6), and an LTPS transistor as the driving transistor (the transistor M2), among the transistors included in the pixel circuit. When the pixel circuit 31A includes both LTPS transistors and OS transistors, the display apparatus using the pixel circuit can achieve reduced power consumption and improved drive capability.

Note that in the case where the pixel circuit 31A includes a plurality of kinds of transistors including different semiconductor materials, the transistors may be provided in different layers for each kind of transistor. For example, in the case where the pixel circuit 31A includes a Si transistor and an OS transistor, a layer including the Si transistor and a layer including the OS transistor may be provided to overlap with each other. Such a structure enables the area occupied by the pixel circuit 31A to be small.

In one embodiment of the present invention, the semiconductor device 20A may include vertical OS transistors as the transistors serving as switches (the transistor M1 and the transistor M3 to the transistor M6), and a dual-gate type OS transistor as the driving transistor (the transistor M2), among the transistors included in the pixel circuit 31A. Refer to Embodiment 2 described later for a specific structure example of such a semiconductor device including both a vertical transistor and a dual-gate transistor.

### Operation Example of Pixel

Next, an operation of the semiconductor device 20A is described.

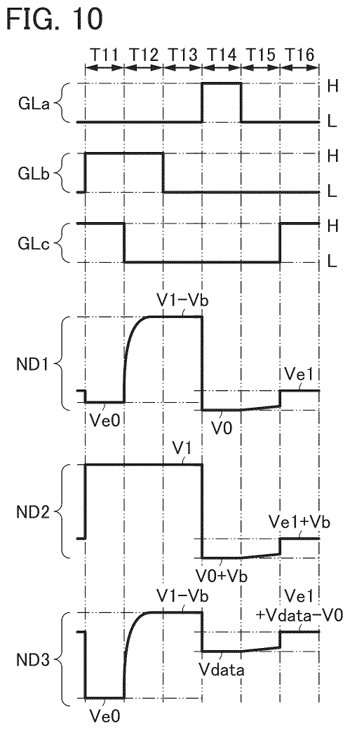

FIG. 10 is a timing chart showing an operation example of the semiconductor device 20A.

In the following description of the operation, a data potential Vdata is supplied to the wiring DL. A potential Va is supplied to the wiring 21, a potential Vc is supplied to the wiring 22, a potential V0 is supplied to the wiring 23, and a potential V1 is supplied to the wiring 24. Either the potential H or the potential L is supplied to each of the wiring GLa, the wiring GLb, and the wiring GLc. The potential H is a potential higher than the potential L. The difference between the potential H and the potential L is preferably greater than the threshold voltage of a transistor, for example. Here, when the potential H is input to a gate of a transistor included in the semiconductor device 20A, the transistor is turned on (brought into a conduction state). When the potential L is input to the gate of the transistor included in the semiconductor device 20A, the transistor is turned off (brought into a non-conduction state).

The potential Va is an anode potential and the potential Vc is a cathode potential. The potential V0 is a potential that can turn off the transistor M2 by being supplied to the gate of the transistor M2. By being supplied to the back gate of the transistor M2, for example, the potential V1 may be a potential that lowers the threshold voltage (also referred to as a potential that shifts the threshold voltage in the negative direction) until the transistor M2 becomes normally on. The potential V0 is, for example, 0 V or the potential L. The potential V1 is, for example, higher than the potential V0 and lower than the potential H.

In the semiconductor device 20A, the emission intensity of the light-emitting element 32 is controlled by the amount of current Ie flowing through the light-emitting element 32. The pixel circuit 31A has a function of controlling the amount of the current Ie in accordance with the data potential Vdata supplied from the wiring DL.

The timing chart in FIG. 10 shows the potentials (the potential H and the potential L) supplied to the wiring GLa, the wiring GLb, and the wiring GLc in the operation periods (Period T11 to Period T16). In addition, changes in the potentials of the node ND1, the node ND2, and the node ND3 are shown.

Although the lengths of periods in a timing chart are sometimes shown to be the same, the lengths of the periods may be different from one another. For example, although the lengths of the periods (Period T11 to Period T16) are shown to be the same in the timing chart in FIG. 10 for easy understanding, the lengths of the periods may be different from one another.

### Correction of Threshold Voltage of Driving Transistor (Threshold Voltage Correction Operation)

In Period T11 to Period T13 shown in FIG. 10, an operation where voltage for correcting the threshold voltage of the transistor M2 is obtained and the voltage is retained in the capacitor C2 is performed.

The current Ie flowing through the light-emitting element 32 is determined mainly by the data potential Vdata and the threshold voltage of the transistor M2. Accordingly, in the display apparatus including a plurality of pixel circuits 31A, even when the data potentials Vdata supplied to the pixel circuits 31A are the same, variation in the threshold voltage between the transistors M2 included in the pixel circuits 31A makes different currents Ie flow through the pixel circuits 31A. Accordingly, variations in the threshold voltage between the transistors M2 are a factor in reducing display quality of the display apparatus.

In view of this, correction is made such that the threshold voltages of the transistors M2 in the pixel circuits 31A are the same, thereby reducing the variation in the current Ie. Here, description is made on a correction method in which the potential supplied to the back gate of the transistor M2 is changed to make the threshold voltage of the transistor M2 become 0 V (or the vicinity of 0 V).

Immediately before Period T11, the potential L is supplied to the wiring GLa and the wiring GLb, and the potential H is supplied to the wiring GLc. Thus, the transistor M1, the transistor M3, the transistor M4, and the transistor M6 are in the off state, and the transistor M5 is in the on state. Note that in the following description of the operation, unless otherwise specified, the potentials of the wirings in the immediately preceding period are maintained.

In Period T11, a reset operation (initialization) is performed. Specifically, the potential H is supplied to the wiring GLb. Then, the transistor M3 and the transistor M4 are turned on.

Thus, the potential of the node ND1 becomes a potential Ve0. The potential of the node ND3 also becomes the potential Ve0 through the transistor M3. Here, the potential Ve0 is higher than the potential Vc by a voltage drop in the light-emitting element 32. The potential V1 is supplied to the node ND2 through the transistor M4. Application of “potential V1-potential Ve0” as the back gate voltage of the transistor M2 brings the transistor M2 into a normally-on state.

In Period T12, the potential L is supplied to the wiring GLc. Then, the transistor M5 is turned off.

Immediately after the transistor M5 is turned off, the transistor M2 is in a normally-on state because “potential V1-potential Ve0” is supplied to the transistor M2 as the back gate voltage. Accordingly, charge is supplied from the wiring 21 to the node ND1 through the transistor M2. This allows the potential of the node ND1 to increase over time. Since the transistor M3 is in an on state, the potential of the node ND3 also increases similarly. As the potential of the node ND1 gradually increases, the back gate voltage of the transistor M2 gradually decreases. In other words, the threshold voltage of the transistor M2 gradually increases (i.e., shifts in the positive direction). Then, when the threshold voltage of the transistor M2 is as close to 0 V as possible, the transistor M2 is turned off to stop the increase in the potential of the node ND1. In this case, the back gate voltage at which the threshold voltage of the transistor M2 is 0 V is referred to as correction voltage Vb. That is, when the increase in the potential of the node ND1 stops, the potential of the node ND1 becomes “potential V1-correction voltage Vb.”

In Period T13, the potential L is supplied to the wiring GLb. Then, the transistor M3 and the transistor M4 are turned off.

Accordingly, the node ND2 and the node ND3 are brought into a floating state; hence, charge supplied to the nodes is retained. That is, the state where the correction voltage Vb obtained in Period T12 is applied to the transistor M2 as the back gate voltage is maintained.

Through the operation in Period T11 to Period T13, correction is performed such that the threshold voltage of the transistor M2 becomes 0 V and the state subjected to correction can be maintained. Note that in this specification and the like, such a correction method is sometimes referred to as “internal correction.”

### Writing of Display Data (Data Writing Operation)

In Period T14 and Period T15 shown in FIG. 10, an operation of writing the data potential Vdata to the pixel circuit 31A is performed.

In Period T14, the potential H is supplied to the wiring GLa. Then, the transistor M1 and the transistor M6 are turned on.

Consequently, the data potential Vdata is supplied to the node ND3, and the potential V0 is supplied to the node ND1. In other words, “data potential Vdata-potential V0” is applied to the transistor M2 as the gate voltage.

Here, the node ND2 is in a floating state, and the node ND1 and the node ND2 are capacitively coupled through the capacitor C2. Thus, when the potential of the node ND1 changes to the potential V0, the potential of the node ND2 similarly changes to “potential V0+correction voltage Vb”. That is, the data potential Vdata can be written while the state where the correction voltage Vb is applied to the transistor M2 as the back gate voltage and the threshold voltage of the transistor M2 is corrected to 0 V is maintained.

In Period T15, the potential L is supplied to the wiring GLa. Then, the transistor M1 and the transistor M6 are turned off.

Accordingly, the node ND3 are brought into a floating state; hence, charge supplied to the node ND3 is retained. Thus, when charge is supplied from the wiring 21 to the node ND1 through the transistor M2, the potential of the node ND1 gradually increases.

Here, the node ND3 is in a floating state, and the node ND1 and the node ND3 are capacitively coupled through the capacitor C1. Accordingly, in accordance with the increase in the potential of the node ND1, the potential of the node ND3 also increases. That is, the state where “data potential Vdata-potential V0” is applied to the transistor M2 as the gate voltage is maintained. Similarly, the node ND2 is in a floating state, and the node ND1 and the node ND2 are capacitively coupled through the capacitor C2. Accordingly, in accordance with the increase in the potential of the node ND1, the potential of the node ND2 also increases. In other words, the state where the correction voltage Vb is applied to the transistor M2 as the back gate voltage is maintained.

### Light Emission of Light-Emitting Element (Light-Emitting Operation)

In Period T16 shown in FIG. 10, an operation of making the light-emitting element 32 emit light is performed.

In Period T16, the potential H is supplied to the wiring GLc. Then, the transistor M5 is turned on.

Consequently, current flows from the wiring 21 to the wiring 22 through the transistor M2, the transistor M5, and the light-emitting element 32. That is, the current Ie flows through the light-emitting element 32, and the light-emitting element 32 emits light with emission intensity corresponding to the current Ie.

When the current Ie flows from the wiring 21 to the wiring 22, a voltage drop occurs in the light-emitting element 32. Accordingly, the potential of the node NDI changes to a potential Ve1. At this time, since the node ND2 and the node ND3 are each in a floating state, as in the description of Period T15, the potentials of the node ND2 and the node ND3 also change in accordance with the change in the potential of the node ND1. That is, the state where “data potential Vdata-potential V0” is applied to the transistor M2 as the gate voltage is maintained. Furthermore, the state where the correction voltage Vb is applied to the transistor M2 as the back gate voltage is maintained.

The operation in Period T16 may be performed at the same timing as the operation in Period T15. In other words, supplying the potential L to the wiring GLa and supplying the potential H to the wiring GLc may be performed at the same timing.

In one embodiment of the present invention, through the threshold voltage correction operation (Period T11 to Period T13) described above, correction can be performed in the semiconductor device 20A such that the threshold voltage of the transistor M2 becomes 0 V. When an OS transistor that features extremely low off-state current is used as the transistor M4, the state in which correction is performed such that the threshold voltage of the transistor M2 becomes 0 V (i.e., the state in which the correction voltage Vb is applied to the transistor M2 as the back gate voltage) can be maintained for a long period.

Here, in the semiconductor device 20A, the amount of current Ie flowing through the light-emitting element 32 is proportional to the square of “gate voltage of the transistor M2 threshold voltage of the transistor M2”. Thus, correction is performed such that the threshold voltage of the transistor M2 becomes 0 V, whereby the amount of current Ie becomes proportional to the square of “data potential Vdata-potential V0”. That is, the amount of current Ie does not depend on the threshold voltage of the transistor M2. Thus, the state where the current Ie whose amount does not depend on the threshold voltage of the transistor M2 flows can be maintained for a long period.

Thus, in one embodiment of the present invention, in the semiconductor device 20A, the frequency of the threshold voltage correction operation (Period T11 to Period T13) described above can be lower than the frequency of the data writing operation and the light-emitting operation (Period T14 to Period T16). For example, in the semiconductor device 20A, even when the data writing operation and light-emitting operation are repeated a plurality of times for each threshold voltage correction operation, the state in which correction is performed such that the threshold voltage of the transistor M2 becomes 0 V can be maintained. Thus, the display apparatus using the semiconductor device can achieve improved display quality and reduced power consumption.

### Other Structure Examples of Pixel

Note that one embodiment of the present invention is not limited to the structure example of the above-described semiconductor device.

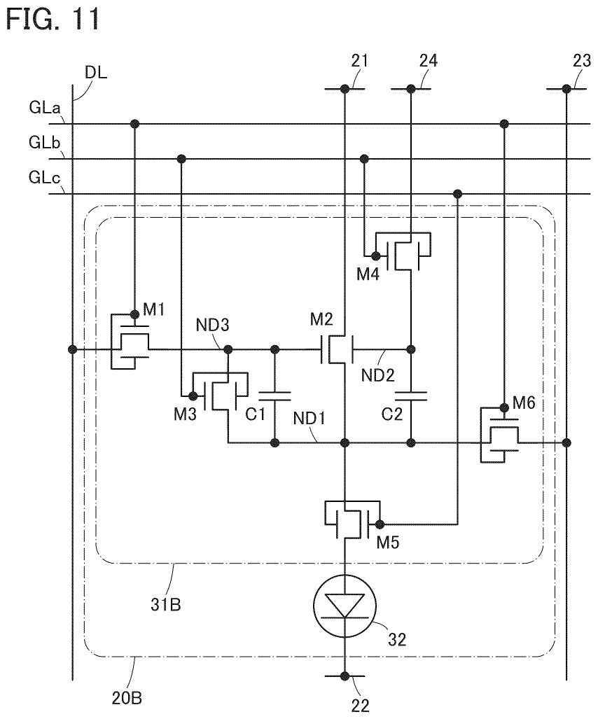

FIG. 11 is a circuit diagram showing a semiconductor device 20B, which is a modification example of the semiconductor device 20A. The semiconductor device 20B includes a pixel circuit 31B instead of the pixel circuit 31A. The pixel circuit 31B is different from the pixel circuit 31A in that the transistor M1 and the transistor M3 to the transistor M6 each have a back gate. The back gate is electrically connected to the gate in each of the transistor M1 and the transistor M3 to the transistor M6 in the semiconductor device 20B. When the gate and the back gate are supplied with the same potential in the transistor having the back gate, the on-state resistance can be reduced.

The potential that can be supplied to the back gate of the transistor having the back gate is not limited to the same potential as the potential of the gate. When the same potential as the potential of the source is supplied to the back gate, for example, an electric field generated outside the transistor is unlikely to affect the channel formation region, and consequently the electrical characteristics of the transistor can be stabilized and the reliability of the transistor can be provided. Furthermore, for example, a given potential is supplied to the back gate, the threshold voltage of the transistor can be changed. Note that the potential supplied to the back gate is not limited to a fixed potential. The same potential may be supplied to the back gates of transistors or the potentials supplied to the back gates may differ between the transistors.

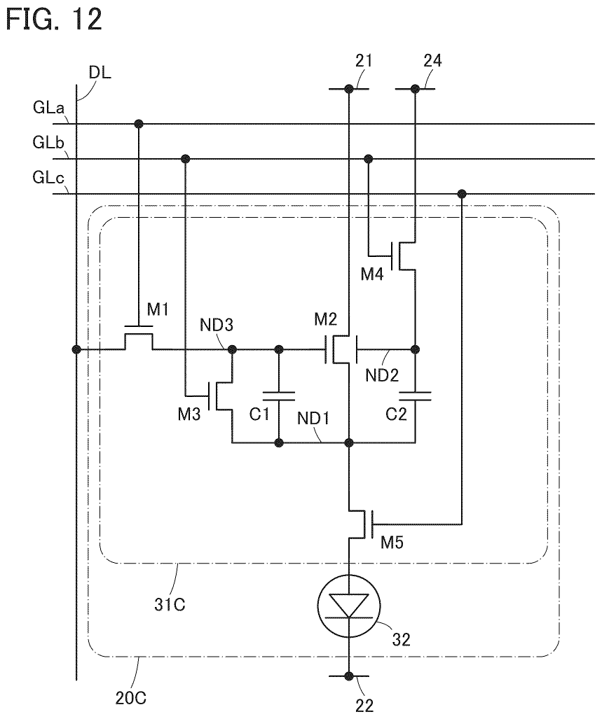

FIG. 12 is a circuit diagram showing a semiconductor device 20C, which is a modification example of the semiconductor device 20A. The semiconductor device 20C includes a pixel circuit 31C instead of the pixel circuit 31A. The pixel circuit 31C is different from the pixel circuit 31A in not including the transistor M6. In the data writing operation of the semiconductor device 20C, for example, the transistor M5 is brought into a conduction state to increase the potential of the node NDI by a voltage drop in the light-emitting element 32. The semiconductor device 20C does not necessarily include the wiring 23. This leads to a reduced area occupied by the pixel circuit 31C.

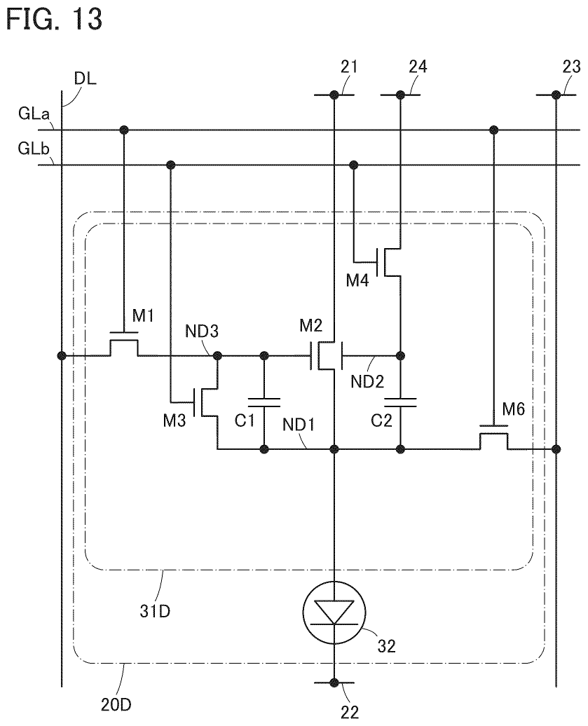

FIG. 13 is a circuit diagram showing a semiconductor device 20D, which is a modification example of the semiconductor device 20A. The semiconductor device 20D includes a pixel circuit 31D instead of the pixel circuit 31A. The pixel circuit 31D is different from the pixel circuit 31A in not including the transistor M5. Accordingly, the one of the source and the drain of the transistor M2 is electrically connected to the one terminal of the light-emitting element 32. In the threshold voltage correction operation of the semiconductor device 20D, the potential Va is supplied to the wiring 22, for example, to prevent current flow through the light-emitting element 32. In addition, the semiconductor device 20D does not necessarily include the wiring GLc. This leads to a reduced area occupied by the pixel circuit 31D.

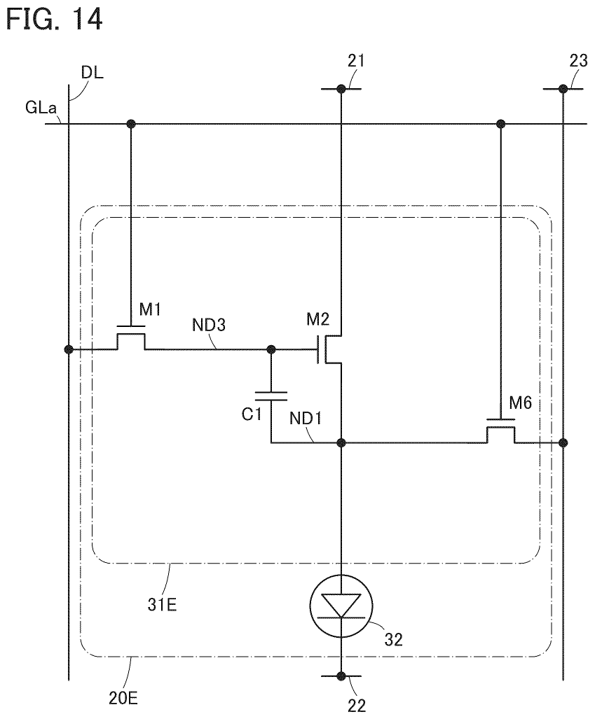

FIG. 14 is a circuit diagram showing a semiconductor device 20E, which is a modification example of the semiconductor device 20D. The semiconductor device 20E includes a pixel circuit 31E instead of the pixel circuit 31D. The pixel circuit 31E is different from the pixel circuit 31D in not including the transistor M3, the transistor M4, and the capacitor C2. In the pixel circuit 31E, the transistor M2 does not necessarily have a back gate. That is, the pixel circuit 31E does not include an internal correction circuit. In addition, the semiconductor device 20E does not necessarily include the wiring GLb and the wiring 24. This leads to a reduced area occupied by the pixel circuit 31E.

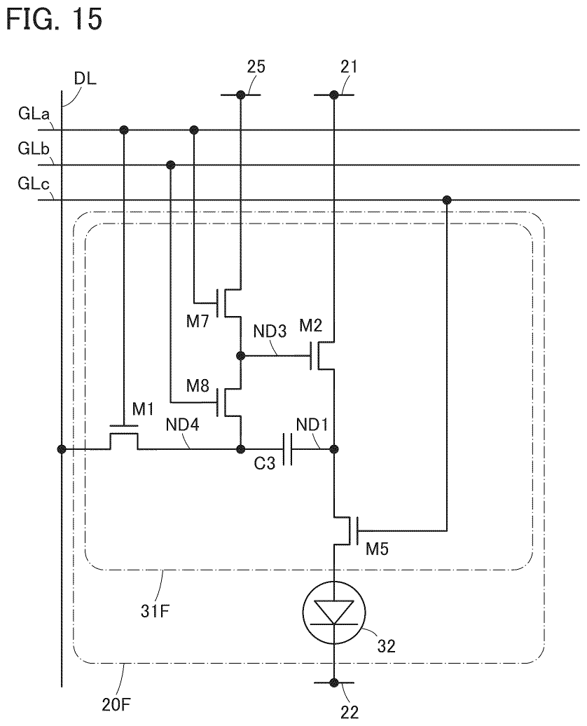

FIG. 15 is a circuit diagram showing a semiconductor device 20F, which is a modification example of the semiconductor device 20A. The semiconductor device 20F includes a pixel circuit 31F instead of the pixel circuit 31A. The pixel circuit 31F is different from the pixel circuit 31A in including a transistor M7, a transistor M8, and a capacitor C3 instead of the transistor M3, the transistor M4, the transistor M6, the capacitor C1, and the capacitor C2. In the pixel circuit 31F, the transistor M2 does not necessarily have a back gate. The pixel circuit 31F include an internal correction circuit different from that of the pixel circuit 31A.

The one of the source and the drain of the transistor M1 is electrically connected to one terminal of the capacitor C3. The gate of the transistor M2 is electrically connected to one of a source and a drain of the transistor M7. The one of the source and the drain of the transistor M2 is electrically connected to the other terminal of the capacitor C3.

A gate of the transistor M7 is electrically connected to the wiring GLa. The other of the source and the drain of the transistor M7 is electrically connected to a wiring 25. The transistor M7 has a function of establishing or breaking electrical continuity between the gate of the transistor M2 and the wiring 25 (a function of a switch).

A gate of the transistor M8 is electrically connected to the wiring GLb. One of a source and a drain of the transistor M8 is electrically connected to the gate of the transistor M2. The other of the source and the drain of the transistor M8 is electrically connected to the one terminal of the capacitor C3. The transistor M8 has a function of establishing or breaking electrical continuity between the gate of the transistor M2 and the one terminal of the capacitor C3 (a function of a switch).

The node ND3 sometimes refers to a region where the gate of the transistor M2, the one of the source and the drain of the transistor M7, and the one of the source and the drain of the transistor M8 are electrically connected to one another.

A node ND4 sometimes refers to a region where the one of the source and the drain of the transistor M1, the other of the source and the drain of the transistor M8, and the one terminal of the capacitor C3 are electrically connected to one another.

The capacitor C3 has, for example, a function of retaining a potential difference (voltage) between the one of the source and the drain of the transistor M2 and the one of the source and the drain of the transistor M1 at the time when the node ND4 is in a floating state.

In the semiconductor device 20F, for example, in the threshold voltage correction operation, the data writing operation, and the light-emitting operation, first, the potential L is supplied to the wiring GLa and the wiring GLb, and the potential H is supplied to the wiring GLc. After that, the potential H is supplied to the wiring GLa. Next, the potential L is supplied to the wiring GLc. After that, the potential L is supplied to the wiring GLa. Next, the potential H is supplied to the wiring GLb and the wiring GLc.

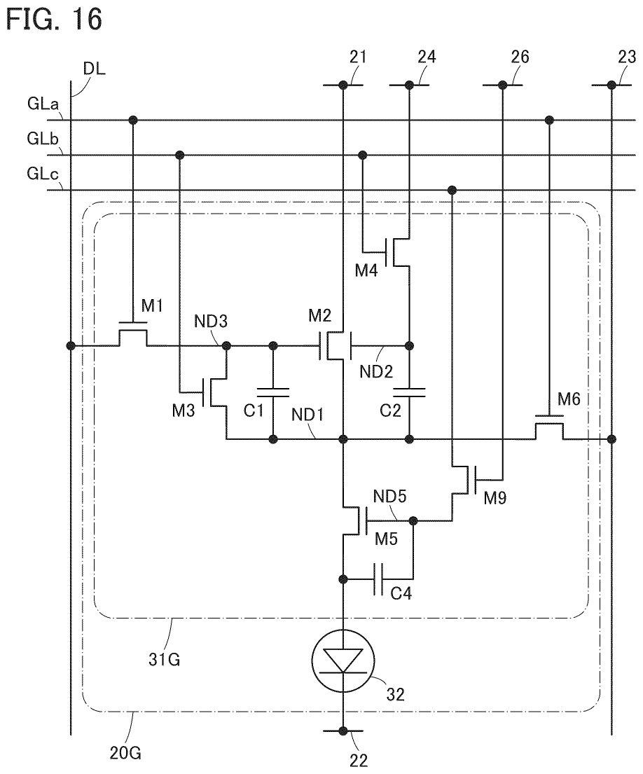

FIG. 16 is a circuit diagram showing a semiconductor device 20G, which is a modification example of the semiconductor device 20A. The semiconductor device 20G includes a pixel circuit 31G instead of the pixel circuit 31A. The pixel circuit 31G includes a transistor M9 and a capacitor C4 in addition to the pixel circuit 31A.

A gate of the transistor M5 is electrically connected to one terminal of the capacitor C4. The other of the source and the drain of the transistor M5 is electrically connected to the other terminal of the capacitor C4.

A gate of the transistor M9 is electrically connected to a wiring 26. One of a source and a drain of the transistor M9 is electrically connected to the gate of the transistor M5. The other of the source and the drain of the transistor M9 is electrically connected to the wiring GLc.

A node ND5 sometimes refers to a region where the gate of the transistor M5, the one of the source and the drain of the transistor M9, and the one terminal of the capacitor C4 are electrically connected to one another.

The capacitor C4 has, for example, a function of retaining a potential difference (voltage) between the other of the source and the drain of the transistor M5 and the gate of the transistor M5 at the time when the node ND5 is in a floating state.

In the semiconductor device 20G, for example, when a potential of the one terminal of the light-emitting element 32 (i.e., the other of the source and the drain of the transistor M5) increases in the light-emitting operation, a potential of the node ND5 (i.e., the gate of the transistor M5) also increases by capacitive coupling through the capacitor C4. Thus, the transistor M5 can be surely turned on during the light-emitting operation. Accordingly, current can be stably supplied to the light-emitting element 32. Note that the capacitor C4 is sometimes referred to as a bootstrap capacitor.

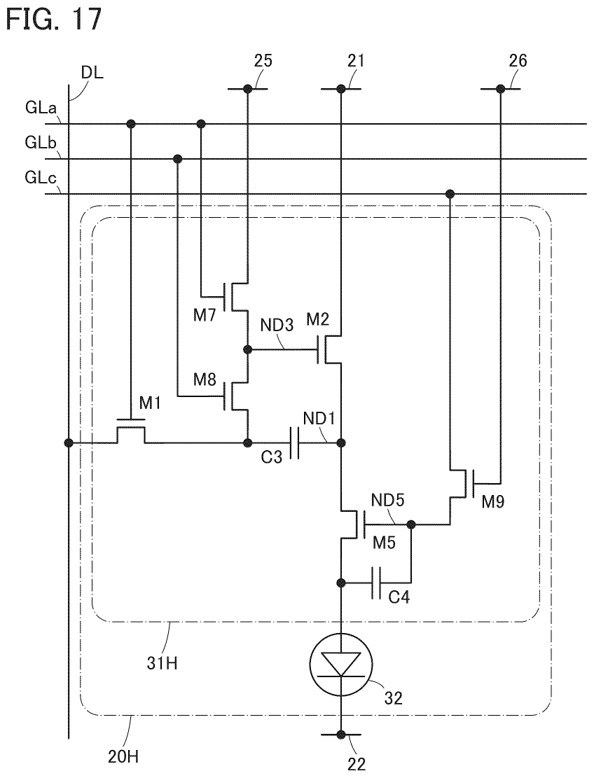

FIG. 17 is a circuit diagram showing a semiconductor device 20H, which is a modification example of the semiconductor device 20F. The semiconductor device 20H includes a pixel circuit 31H instead of the pixel circuit 31F. The pixel circuit 31H includes the transistor M9 and the capacitor C4 in addition to the pixel circuit 31F. That is, the pixel circuit 31H has a structure in which the internal correction circuit of the pixel circuit 31F and the bootstrap capacitor of the pixel circuit 31G are combined.

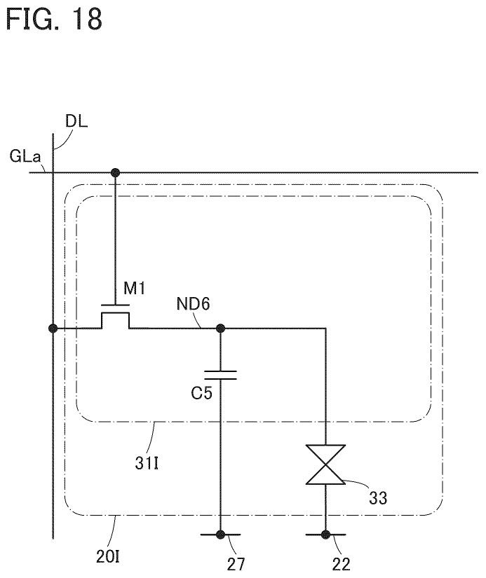

FIG. 18 is a circuit diagram showing a semiconductor device 20I. The semiconductor device 20I includes a pixel circuit 31I and a liquid crystal element 33. The pixel circuit 31I includes the transistor M1 and a capacitor C5. The pixel circuit 31I includes the transistor M1 and the capacitor C5.

The gate of the transistor M1 is electrically connected to the wiring GLa. The one of the source and the drain of the transistor M1 is electrically connected to one terminal of the liquid crystal element 33. The other of the source and the drain of the transistor M1 is electrically connected to the wiring DL. The transistor M1 has a function of establishing or breaking electrical continuity between one terminal of the capacitor C5 and the wiring DL (a function of a switch).

The other terminal of the liquid crystal element 33 is electrically connected to the wiring 22. In the liquid crystal element 33, the transmittance of light changes in accordance with a potential difference (voltage) between a pair of terminals (between one terminal and the other terminal).

The one terminal of the capacitor C5 is electrically connected to the one of the source and the drain of the transistor M1. The other terminal of the capacitor C5 is electrically connected to a wiring 27.

A node ND6 sometimes refer to a region where the one of the source and the drain of the transistor M1, the one terminal of the capacitor C5, and the one terminal of the liquid crystal element 33 are electrically connected to one another.

The capacitor C5 has a function of retaining a potential difference between a pair of terminals of the liquid crystal element 33 when the node ND6 is in a floating state, for example.

### Structure Examples of Peripheral Driver Circuit

Next, structure examples of the constituent circuits that can be used for the peripheral driver circuit included in the display apparatus 40 are described.

### Shift Register

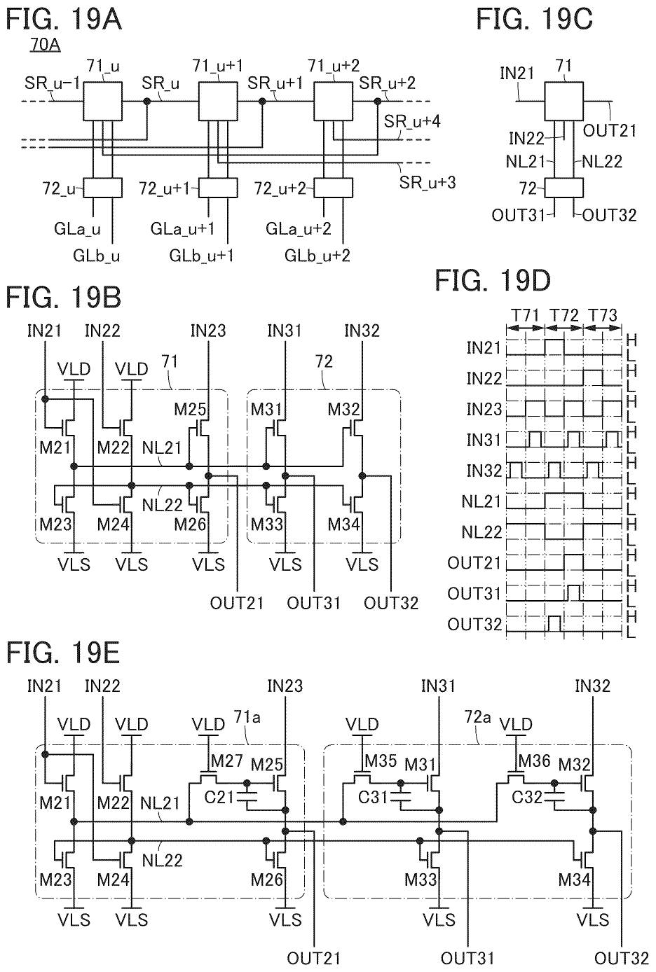

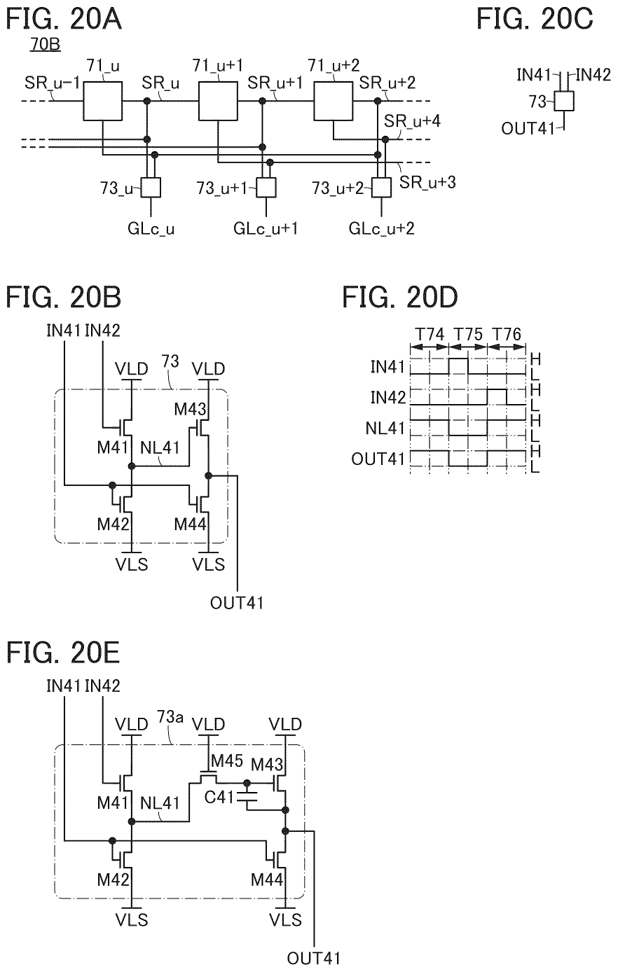

FIG. 19A to FIG. 19E and FIG. 20A to FIG. 20E are circuit diagrams showing structure examples of the semiconductor devices that can be used for the peripheral driver circuit. The semiconductor device can be used as part of a gate driver, for example. For another example, the semiconductor device can be used as part of a shift register.

A semiconductor device 70A shown in FIG. 19A includes m register portions 71 and m buffer portions 72. The semiconductor device 70A is electrically connected to m wirings GLa and m wirings GLb. The m register portions 71 are electrically connected to one another through m wirings SR. In FIG. 19A, a register portion 71_u to a register portion 71_u+2, a buffer portion 72_u to a buffer portion 72_u+2, a wiring SR_u−1 to a wiring SR_u+4, a wiring GLa_u to a wiring GLa_u+2, and a wiring GLb_u to a wiring GLb_u+2 are selectively shown as part of the semiconductor device 70A. Note that m is an integer greater than or equal to 2 and corresponds to the number m of rows of the pixels 41 arranged in a matrix in the display apparatus 40 described above. In addition, u is an integer greater than or equal to 1 and less than or equal to m.

FIG. 19B is a circuit diagram showing a structure example of the register portion 71 and the buffer portion 72. FIG. 19C shows a circuit block corresponding to the register portion 71 and the buffer portion 72. The register portion 71 can be used as each of a register portion 71_1 to a register portion 71_m. The buffer portion 72 can be used as each of a buffer portion 72_1 to a buffer portion 72_m. Thus, for example, in the register portion 71_u, a wiring IN21 is electrically connected to the wiring SR_u−1, a wiring IN22 is electrically connected to the wiring SR_u+2, and a wiring OUT21 is electrically connected to the wiring SR_u. For example, in the buffer portion 72_u, a wiring OUT31 is electrically connected to the wiring GLa_u and a wiring OUT32 is electrically connected to the wiring GLb_u. Note that the wiring IN21, a wiring IN31, a wiring IN32, a wiring VLD, and a wiring VLS are not shown in FIG. 19A and FIG. 19C. The same applies to the register portion 71_1 to the register portion 71_u−1 and the register portion 71_u+1 to the register portion 71_m. The same applies to the buffer portion 72_1 to the buffer portion 72_u−1 and the buffer portion 72_u+1 to the buffer portion 72_m.

That is, in the semiconductor device 70A, the wiring OUT21 in the register portion 71_u−1 is electrically connected to the wiring IN21 in the register portion 71_u through the wiring SR_u−1, and the wiring OUT21 in the register portion 71_u is electrically connected to the wiring IN21 in the register portion 71_u+1 through the wiring SR_u. In such a structure, the register portions 71_1 to 71_m are selected sequentially, and a desired potential can be supplied to each of the wiring GLa_u and the wiring GLb_u in the buffer portion 72_u electrically connected to the register portion 71_u selected. Note that a potential of the wiring VLS is supplied to each of the wiring GLa_u and the wiring GLb_u in the buffer portion 72_u electrically connected to the register portion 71_u that is not selected, in the semiconductor device 70A.

The register portion 71 shown in FIG. 19B includes a transistor M21, a transistor M22, a transistor M23, a transistor M24, a transistor M25, and a transistor M26. The transistor M21 has a function of establishing or breaking electrical continuity between the wiring VLD and a wiring NL21 in accordance with a potential of the wiring IN21. The transistor M22 has a function of establishing or breaking electrical continuity between the wiring VLD and a wiring NL22 in accordance with a potential of the wiring IN22. The transistor M23 has a function of establishing or breaking electrical continuity between the wiring VLS and the wiring NL21 in accordance with the potential of the wiring NL22. The transistor M24 has a function of establishing or breaking electrical continuity between the wiring VLS and the wiring NL22 in accordance with the potential of the wiring IN21. The transistor M25 has a function of establishing or breaking electrical continuity between a wiring IN23 and the wiring OUT21 in accordance with the potential of the wiring NL21. The transistor M26 has a function of establishing or breaking electrical continuity between the wiring VLS and the wiring OUT21 in accordance with the potential of the wiring NL22.

The buffer portion 72 shown in FIG. 19B includes a transistor M31, a transistor M32, a transistor M33, and a transistor M34. The transistor M31 has a function of establishing or breaking electrical continuity between the wiring IN31 and the wiring OUT31 in accordance with the potential of the wiring NL21. The transistor M32 has a function of establishing or breaking electrical continuity between the wiring IN32 and the wiring OUT32 in accordance with the potential of the wiring NL21. The transistor M33 has a function of establishing or breaking electrical continuity between the wiring VLS and the wiring OUT31 in accordance with the potential of the wiring NL22. The transistor M34 has a function of establishing or breaking electrical continuity between the wiring VLS and the wiring OUT32 in accordance with the potential of the wiring NL22.

FIG. 19D is a timing chart showing an operation example of the register portion 71 and the buffer portion 72 shown in FIG. 19B.

In the following description of the operation, the potential H is supplied to the wiring VLD, and the potential L is supplied to the wiring VLS. Either the potential H or the potential L is supplied to each of the wiring IN21, the wiring IN22, the wiring IN23, the wiring IN31, and the wiring IN32.

The timing chart in FIG. 19D shows the potentials (the potential H and the potential L) supplied to the wiring IN21, the wiring IN22, the wiring IN23, the wiring IN31, and the wiring IN32 in the operation periods (Period T71 to Period T73). In addition, changes in the potentials of the wiring NL21, the wiring NL22, the wiring OUT21, the wiring OUT31, and the wiring OUT32 are shown.

In Period T71, the potential L is supplied to the wiring IN21 and the wiring IN22. The potential of the wiring NL22 is the potential H. Accordingly, the potential L is supplied to the wiring NL21. In this case, the transistor M25, the transistor M31, and the transistor M32 are each in an off state (a non-conduction state) and the transistor M26, the transistor M33, and the transistor M34 are each in an on state (a conduction state). Accordingly, the potential L is supplied to each of the wiring OUT21, the wiring OUT31, and the wiring OUT32 regardless of the potentials (the potential H and the potential L) of the wiring IN23, the wiring IN31, and the wiring IN32. Note that in the following description of the operation, unless otherwise specified, the potentials of the wirings supplied in the immediately preceding period are maintained.

In Period T72, the potential H is supplied to the wiring IN21, and accordingly, the potential of the wiring NL22 becomes the potential L and the potential of the wiring NL21 becomes the potential H. Thus, the transistor M25, the transistor M31, and the transistor M32 are each turned on, and the transistor M26, the transistor M33, and the transistor M34 are each turned off. Accordingly, the potentials (the potential H and the potential L) of the wiring IN23, the wiring IN31, and the wiring IN32 are supplied to the wiring OUT21, the wiring OUT31, and the wiring OUT32 through the transistor M25, the transistor M31, and the transistor M32, respectively. After that, even if the potential L is supplied to the wiring IN21, the potentials of the wiring NL22 and the wiring NL21 are maintained.

In Period T73, the potential H is supplied to the wiring IN22, and accordingly, the potential of the wiring NL22 becomes the potential H and the potential of the wiring NL21 becomes the potential L. Thus, the transistor M25, the transistor M31, and the transistor M32 are each turned off, and the transistor M26, the transistor M33, and the transistor M34 are each turned on. Accordingly, the potential L is supplied to each of the wiring OUT21, the wiring OUT31, and the wiring OUT32 regardless of the potentials (the potential H and the potential L) of the wiring IN23, the wiring IN31, and the wiring IN32. After that, even if the potential L is supplied to the wiring IN22, the potentials of the wiring NL22 and the wiring NL21 are maintained.

FIG. 19E is a circuit diagram showing a modification example of the register portion 71 and the buffer portion 72. A register portion 71a and a buffer portion 72a shown in FIG. 19E are different from the register portion 71 and the buffer portion 72 in including bootstrap circuits. That is, the register portion 71a includes a transistor M27 and a capacitor C21 in addition to the register portion 71 while the buffer portion 72a includes a transistor M35, a transistor M36, a capacitor C31, and a capacitor C32 in addition to the buffer portion 72. Note that the capacitor C21, the capacitor C31, and the capacitor C32 are referred to as bootstrap capacitors in some cases.

A gate of the transistor M27 is electrically connected to the wiring VLD. A gate of the transistor M25 is electrically connected to the wiring NL21 through a source and a drain of the transistor M27. The gate of the transistor M25 is also electrically connected to the wiring OUT21 through the capacitor C21.

A gate of the transistor M35 is electrically connected to the wiring VLD. A gate of the transistor M31 is electrically connected to the wiring NL21 through a source and a drain of the transistor M35. The gate of the transistor M31 is also electrically connected to the wiring OUT31 through the capacitor C31.

A gate of the transistor M36 is electrically connected to the wiring VLD. A gate of the transistor M32 is electrically connected to the wiring NL21 through a source and a drain of the transistor M36. The gate of the transistor M32 is also electrically connected to the wiring OUT32 through the capacitor C32.

Here, in the register portion 71, when the potential H is transmitted from the wiring IN23 to the wiring OUT21, a potential decrease depending on the threshold voltage occurs in the transistor M25. Thus, with the use of the bootstrap circuit like the register portion 71a, capacitive coupling between the bootstrap capacitors can maintain the on state in the transistor M25. In this manner, the potential H can be transmitted to the wiring OUT21 without occurrence of the potential decrease depending on the threshold voltage.

In the buffer portion 72, similarly, when the potential H is transmitted from the wiring IN31 to the wiring OUT31, a potential decrease depending on the threshold voltage occurs in the transistor M31, and when the potential H is transmitted from the wiring IN32 to the wiring OUT32, a potential decrease depending on the threshold voltage occurs in the transistor M32. Hence, with the use of the bootstrap circuit like the buffer portion 72a, capacitive coupling between the bootstrap capacitors can maintain the on state in each of the transistor M31 and the transistor M32. In this manner, the potential H can be transmitted to each of the wiring OUT31 and the wiring OUT32 without occurrence of the potential decrease depending on the threshold voltage.

A semiconductor device 70B shown in FIG. 20A includes m register portions 71 and m inverter portions 73. The semiconductor device 70B is electrically connected to m wirings GLc. The m register portions 71 are electrically connected to one another through m wirings SR. In FIG. 20A, the register portion 71_u to the register portion 71_u+2, an inverter portion 73_u to a an inverter portion 73_u+2, the wiring SR_u−1 to the wiring SR_u+4, and a wiring GLc_u to a wiring GLc_u+2 are selectively shown as part of the semiconductor device 70B.

FIG. 20B is a circuit diagram showing a structure example of the inverter portion 73. FIG. 20C is a circuit block corresponding to the inverter portion 73. The inverter portion 73 can be used as each of an inverter portion 73_1 to an inverter portion 73_m. Thus, for example, in the inverter portion 73_u, a wiring IN41 is electrically connected to the wiring SR_u, a wiring IN42 is electrically connected to the wiring SR_u+2, and a wiring OUT41 is electrically connected to the wiring GLc_u. Note that the wiring VLD and the wiring VLS are not shown in FIG. 20A and FIG. 20C. The same applies to the inverter portion 73_1 to the inverter portion 73_u−1 and the inverter portion 73_u+1 to the inverter portion 73_m.

Thus, in the semiconductor device 70B, the register portions 71_1 to 71_m are selected sequentially, and a desired potential can be supplied to the wiring GLc_u in the inverter portion 73_u electrically connected to the register portion 71_u selected, as in the semiconductor device 70A. Note that a potential of the wiring VLD is supplied to the wiring GLc_u in the inverter portion 73_u electrically connected to the register portion 71_u that is not selected, in the semiconductor device 70B.

The inverter portion 73 shown in FIG. 20B includes a transistor M41, a transistor M42, a transistor M43, and a transistor M44. The transistor M41 has a function of establishing or breaking electrical continuity between the wiring VLD and a wiring NL41 in accordance with a potential of the wiring IN42. The transistor M42 has a function of establishing or breaking electrical continuity between the wiring VLS and the wiring NL41 in accordance with a potential of the wiring IN41. The transistor M43 has a function of establishing or breaking electrical continuity between the wiring VLD and the wiring OUT41 in accordance with the potential of the wiring NL41. The transistor M44 has a function of establishing or breaking electrical continuity between the wiring VLS and the wiring OUT41 in accordance with the potential of the wiring IN41.

FIG. 20D is a timing chart showing an operation example of the inverter portion 73 shown in FIG. 20B.

In the following description of the operation, the potential H is supplied to the wiring VLD, and the potential L is supplied to the wiring VLS. Either the potential H or the potential L is supplied to each of the wiring IN41 and the wiring IN42.

The timing chart in FIG. 20D shows the potentials (the potential H and the potential L) supplied to the wiring IN41 and the wiring IN42 in the operation periods (Period T74 to Period T76). In addition, changes in the potentials of the wiring NL41 and the wiring OUT41 are shown.

In Period T74, the potential L is supplied to the wiring IN41 and the wiring IN42. The potential of the wiring NL41 is the potential H. In this case, the transistor M43 is in an on state (a conduction state), and the transistor M44 is in an off state (a non-conduction state). Accordingly, the potential H is supplied to the wiring OUT41. Note that in the following description of the operation, unless otherwise specified, the potentials of the wirings supplied in the immediately preceding period are maintained.

In Period T75, the potential H is supplied to the wiring IN41, and accordingly the potential of the wiring NL41 becomes the potential L. Then, the transistor M43 is turned off and the transistor M44 is turned on. Thus, the potential L is supplied to the wiring OUT41. After that, the potential L is supplied to the wiring IN41 to turn off the transistor M44. At this time, the potentials of the wiring NL41 and the wiring OUT41 are maintained.

In Period T76, the potential H is supplied to the wiring IN42, and accordingly the potential of the wiring NL41 becomes the potential H. Then, the transistor M43 is turned on. Thus, the potential H is supplied to the wiring OUT41. After that, even if the potential L is supplied to the wiring IN42, the potentials of the wiring NL41 and the wiring OUT41 are maintained.

FIG. 20E is a circuit diagram showing a modification example of the inverter portion 73. An inverter portion 73a shown in FIG. 20E is different from the inverter portion 73 in including a bootstrap circuit. That is, the inverter portion 73a includes a transistor M45 and a capacitor C41 in addition to the inverter portion 73. Note that the capacitor C41 is sometimes referred to as a bootstrap capacitor.

A gate of the transistor M45 is electrically connected to the wiring VLD. A gate of the transistor M43 is electrically connected to the wiring NL41 through a source and a drain of the transistor M45. The gate of the transistor M43 is also electrically connected to the wiring OUT41 through the capacitor C41.

Here, in the inverter portion 73, when the potential H is transmitted from the wiring VLD to the wiring OUT41, a potential decrease depending on the threshold voltage occurs in the transistor M43. Thus, with the use of the bootstrap circuit like the inverter portion 73a, capacitive coupling between the bootstrap capacitors can maintain the on state in the transistor M43. In this manner, the potential H can be transmitted to the wiring OUT41 without occurrence of the potential decrease depending on the threshold voltage.

According to one embodiment of the present invention, the semiconductor device 70A and the semiconductor device 70B can be used in the display apparatus 40. For example, the semiconductor device 70A and the semiconductor device 70B can be used as part of the gate driver in the display apparatus 40. In that case, the wiring GLa_1 to the wiring GLa_m correspond to the wirings GLa in the pixels 41 that are arranged in the m rows and each employ the semiconductor device 20A. Similarly, the wiring GLb_1 to the wiring GLb_m correspond to the wirings GLb, and the wiring GLc_1 to the wiring GLc_m correspond to the wirings GLc.

According to one embodiment of the present invention, there is no limitation on the structures of the semiconductor device 70A and the semiconductor device 70B described above, and the structures may be changed as appropriate as long as the display apparatus described above can be obtained.

### Demultiplexer

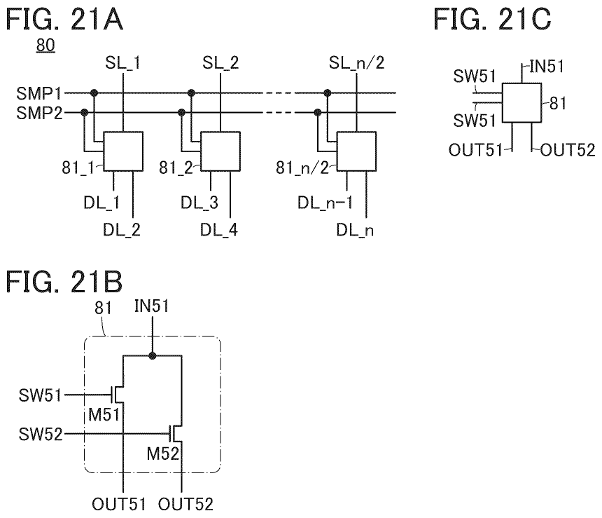

FIG. 21A to FIG. 21C are circuit diagrams showing a structure example of the semiconductor device that can be used for the peripheral driver circuit. The semiconductor device can be used as part of a source driver, for example. For another example, the semiconductor device can be used as part of a demultiplexer.

A semiconductor device 80 shown in FIG. 21A includes n/2 selector portion(s) 81. The semiconductor device 80 is electrically connected to a wiring SMP1, a wiring SMP2, n/2 wiring(s) SL, and n wirings DL. In FIG. 21, a selector portion 81_1, a selector portion 81_2, a selector portion 81_n/2, the wiring SMP1, the wiring SMP2, a wiring SL_1, a wiring SL_2, a wiring SL_n/2, a wiring DL_1 to a wiring DL_4, a wiring DL_n-1, and a wiring DL_n are selectively shown as part of the semiconductor device 80. Note that n is an integer greater than or equal to 2 and corresponds to the number n of columns of the pixels 41 arranged in a matrix in the display apparatus 40 described above.

FIG. 21B and FIG. 21C are a circuit diagram and a block diagram, respectively, showing a structure example of the selector portion 81. The selector portion 81 can be used for each of the selector portion 81_1 to the selector portion 81_n/2. That is, for example, in the selector portion 81_1, a wiring IN51 is electrically connected to the wiring SL_1, a wiring SW51 is electrically connected to the wiring SMP1, a wiring SW52 is electrically connected to the wiring SMP2, a wiring OUT51 is electrically connected to the wiring DL_1, and a wiring OUT52 is electrically connected to the wiring DL 2. For example, in the selector portion 81_n/2, the wiring IN51 is electrically connected to the wiring SL_n/2, the wiring SW51 is electrically connected to the wiring SMP1, the wiring SW52 is electrically connected to the wiring SMP2, the wiring OUT51 is electrically connected to the wiring DL_n-1, and the wiring OUT52 is electrically connected to the wiring DL_n. Note that the same applies to the selector portion 81_2 to the selector portion 81_n/2-1.

The selector portion 81 shown in FIG. 21B includes a transistor M51 and a transistor M52. The transistor M51 has a function of establishing or breaking electrical continuity between the wiring IN51 and the wiring OUT51 in accordance with a potential of the wiring SW51. The transistor M52 has a function of establishing or breaking electrical continuity between the wiring IN51 and the wiring OUT52 in accordance with a potential of the wiring SW52.

Thus, the selector portion 81 has a function of transmitting a potential of the wiring IN51 to any one of the wiring OUT51 and the wiring OUT52 in accordance with the potentials of the wiring SW51 and the wiring SW52. In other words, the selector portion 81 includes one input (the wiring IN51) and two outputs (the wiring OUT51 and the wiring OUT52).

According to one embodiment of the present invention, the semiconductor device 80 can be used in the display apparatus 40. For example, the semiconductor device 80 can be used as part of the source driver in the display apparatus 40. In that case, the wiring DL_1 to the wiring DL_n correspond to the wirings DL in the pixels 41 that are arranged in the n columns and each employ the semiconductor device 20A.

With the use of the semiconductor device 80 in the display apparatus 40, a source driver IC with outputs fewer than the number n of columns of the pixels 41 can be used. For example, the source driver IC with n/2 outputs is used for the semiconductor device 80 described above. This leads to, for example, the reduced size and cost of the display apparatus. It can be said that it is possible to drive a display apparatus in which the number of the columns of the pixels is larger than the number of outputs of the source driver IC. Consequently, for example, the definition of the display apparatus can be increased.

Note that although a structure in which the selector portion 81 included in the semiconductor device 80 includes two outputs is described here, one embodiment of the present inventio is not limited thereto, and three or more outputs may be included. For example, the structure with three outputs enables the use of the source driver IC with n/3 outputs.

### Source Driver

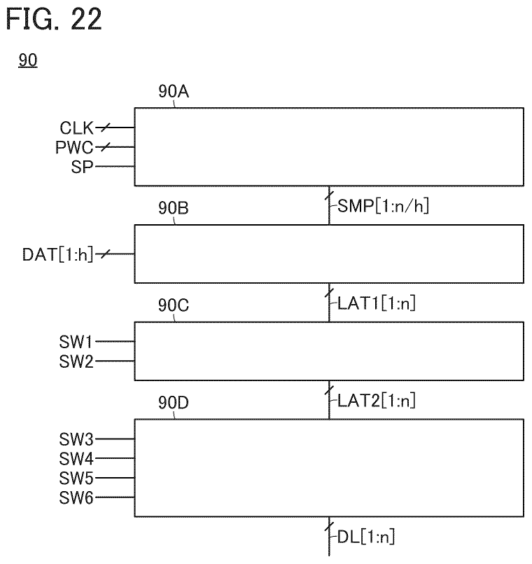

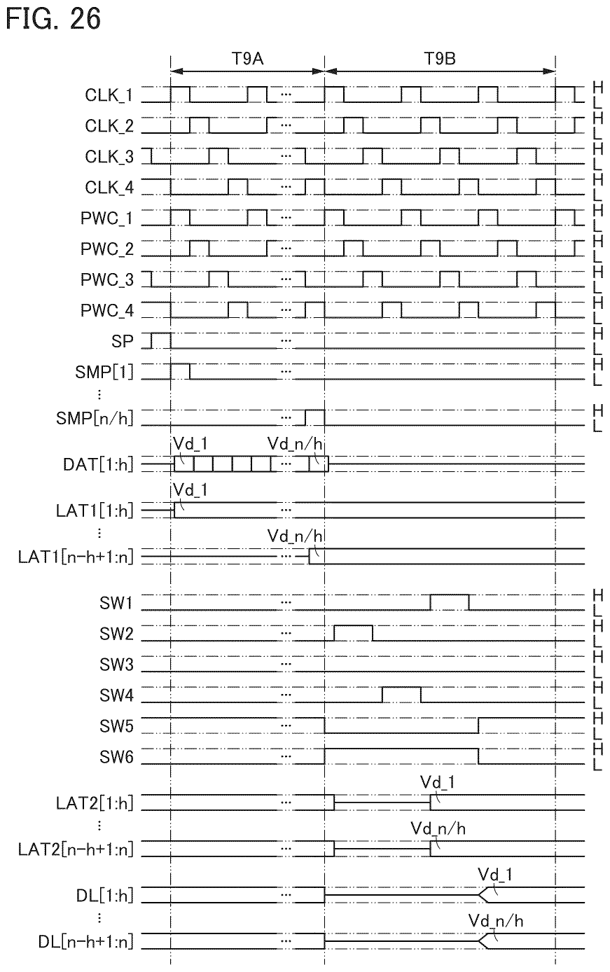

FIG. 22 to FIG. 25F are circuit diagrams showing structure examples of a semiconductor device that can be used for the peripheral driver circuit. FIG. 26 is a timing chart showing an operation example of the semiconductor device. The semiconductor device can be used as part of a source driver, for example.

A semiconductor device 90 shown in FIG. 22 includes a shift register portion 90A, a latch portion 90B, a latch portion 90C, and a source follower portion 90D.

The shift register portion 90A is electrically connected to a plurality of wirings CLK, a plurality of wirings PWC, and a wiring SP. The shift register portion 90A is electrically connected to the latch portion 90B through n/h wirings SMP (sometimes referred to as wirings SMP[1:n/h]). The latch portion 90B is electrically connected to h wirings DAT (sometimes referred to as wirings DAT[1:h]). The latch portion 90B is electrically connected to the latch portion 90C through n wirings LAT1 (sometimes referred to as wirings LAT1[1:n]). The latch portion 90C is electrically connected to a wiring SW1 and a wiring SW2. The latch portion 90C is electrically connected to the source follower portion 90D through n wirings LAT2 (sometimes referred to as wirings LAT2[1:n]). The source follower portion 90D is electrically connected to a wiring SW3, a wiring SW4, a wiring SW5, and a wiring SW6. The source follower portion is electrically connected to the n wirings DL (sometimes referred to as wirings DL[1:n]).

Note that n is an integer greater than or equal to 2 and corresponds to the number n of columns of the pixels 41 arranged in a matrix in the display apparatus 40 described above, for example. Furthermore, h is an integer greater than or equal to 1 and corresponds to the number of data lanes input from the outside of the display apparatus 40 to the second driver circuit portion 44, for example.

The shift register portion 90A has a function of sequentially outputting signals to the wirings SMP[1:n/h] in accordance with signals input through the plurality of wirings CLK, the plurality of wirings PWC, and the wiring SP. The plurality of wirings CLK are wirings to which clock signals whose potentials periodically change in different phases are supplied. The plurality of wirings PWC are wirings to which clock signals whose potentials periodically change in different phases are supplied. The wiring SP is a wiring supplied with a start pulse signal which triggers an operation of sequentially outputting signals.

The latch portion 90B has a function of storing and retaining a potential input through the wirings DAT[1:h] with use of signals sequentially output to the wirings SMP[1:n/h] as triggers and outputting the potential to the wirings LAT1[1:n]. That is, the latch portion 90B has a function of a sample-and-hold circuit. The wirings DAT[1:h] is a wiring to which a data potential corresponding to data of an image displayed on the display apparatus 40 is supplied.

The latch portion 90C has a function of storing and retaining the potential of the wirings LAT1[1:n] with use of a signal input through the wiring SW1 as a trigger and outputting the potential to the wirings LAT2[1:n]. That is, the latch portion 90C has a function of a sample-and-hold circuit. Note that the latch portion 90C may have a function of resetting (initializing) the potential of the wirings LAT2[1:n] in accordance with a signal input through the wiring SW2, for example.

The source follower portion 90D has a function of outputting a potential corresponding to the potential of the wirings LAT2[1:n] to the wirings DL[1:n]. By reducing the output impedance, the source follower portion 90D can shorten the time during which a potential of the wirings DL[1:n] changes in accordance with a change in the potential of the wirings LAT2[1:n] even when the load (parasitic capacitance) of the wirings DL[1:n] is large. That is, the source follower portion 90D has a function of performing impedance conversion. Note that the source follower portion 90D may have a function of controlling the input from the wirings LAT2[1:n] in accordance with signals input through the wiring SW3 and the wiring SW4. For example, the source follower portion 90D may have a function of correcting a potential input from the wirings LAT2[1:n]. Alternatively, the source follower portion 90D may have a function of controlling the output to the wirings DL[1:n] in accordance with signals input through the wiring SW5 and the wiring SW6. For example, the source follower portion 90D may have a function of precharging the wirings DL[1:n] to a given potential.

Next, structure examples of the shift register portion 90A, the latch portion 90B, the latch portion 90C, and the source follower portion 90D are described.

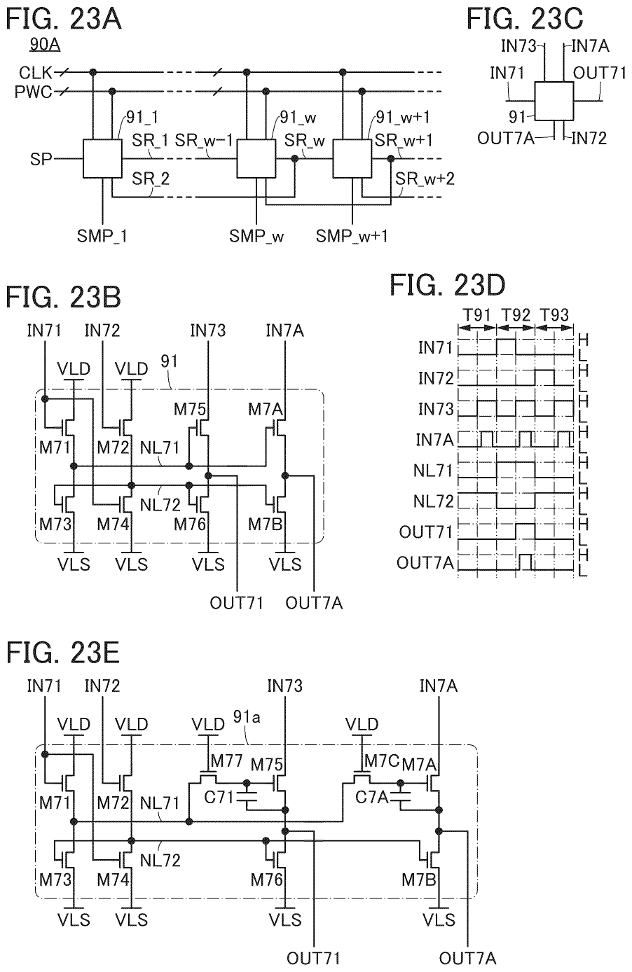

FIG. 23A is a circuit diagram showing a structure example of the shift register portion 90A. The shift register portion 90A includes n/h register portions 91. The shift register portion 90A is electrically connected to the n/h wirings SMP, the plurality of wirings CLK, the plurality of wirings PWC, and the wiring SP. The n/h register portions 91 are electrically connected to one another through n/h wirings SR. In FIG. 23A, a register portion 91_1, a register portion 91_w, a register portion 91_w+1, a wiring SR_1, a wiring SR_2, a wiring SR_w−1 to a wiring SR_w+2, a wiring SMP_1, a wiring SMP_w, and a wiring SMP_w+1 are selectively shown as part of the shift register portion 90A. Note that, w is an integer greater than or equal to 1 and less than or equal to n/h.

FIG. 23B is a circuit diagram showing a structure example of the register portion 91. FIG. 23C is a circuit block corresponding to the register portion 91. The register portion 91 can be used as each of the register portion 91_1 to a register portion 91_n/h. That is, for example, in the register portion 91_w, a wiring IN71 is electrically connected to the wiring SR_w−1, a wiring IN72 is electrically connected to the wiring SR_w+1, a wiring IN73 is electrically connected to any one of the plurality of wirings CLK, and a wiring OUT71 is electrically connected to the wiring SR_w. A wiring IN7A is electrically connected to any one of the plurality of wirings PWC, and a wiring OUTZA is electrically connected to the wiring SMP_w. Note that in the register portion 91_1, the wiring IN71 is electrically connected to the wiring SP. Note that the wiring VLD and the wiring VLS are not shown in FIG. 23A and FIG. 23C. The same applies to the register portion 91_2 to the register portion 91_w−1 and the register portion 91_w+2 to the register portion 91_n/h.

That is, in the shift register portion 90A, the wiring OUT71 in the register portion 91_w−1 is electrically connected to the wiring IN71 in the register portion 91_w through the wiring SR_w−1, and the wiring OUT71 in the register portion 91_w is electrically connected to the wiring IN71 in the register portion 91_w+1 through the wiring SR_w. In such a structure, the register portion 91_1 to the register portion 91_n/h are selected sequentially, and a desired potential can be supplied to the wiring SMP_w electrically connected to the register portion 91_w selected. Note that the potential of the wiring VLS is supplied to the wiring SMP_w electrically connected to the register portion 91_w that is not selected in the shift register portion 90A.

The register portion 91 shown in FIG. 23B includes a transistor M71, a transistor M72, a transistor M73, a transistor M74, a transistor M75, and a transistor M76. The transistor M71 has a function of establishing or breaking electrical continuity between the wiring VLD and a wiring NL71 in accordance with a potential of the wiring IN71. The transistor M72 has a function of establishing or breaking electrical continuity between the wiring VLD and a wiring NL72 in accordance with a potential of the wiring IN72. The transistor M73 has a function of establishing or breaking electrical continuity between the wiring VLS and the wiring NL71 in accordance with a potential of the wiring NL72. The transistor M74 has a function of establishing or breaking electrical continuity between the wiring VLS and the wiring NL72 in accordance with the potential of a wiring IN71. The transistor M75 has a function of establishing or breaking electrical continuity between the wiring IN73 and the wiring OUT71 in accordance with a potential of the wiring NL71. The transistor M76 has a function of establishing or breaking electrical continuity between the wiring VLS and the wiring OUT71 in accordance with the potential of the wiring NL72.

The register portion 91 includes a transistor M7A and a transistor M7B. The transistor M7A has a function of establishing or breaking electrical continuity between the wiring IN7A and the wiring OUT7A in accordance with the potential of the wiring NL71. The transistor M7B has a function of establishing or breaking electrical continuity between the wiring VLS and the wiring OUT7A in accordance with the potential of the wiring NL72.

FIG. 23D is a timing chart showing an operation example of the register portion 91 shown in FIG. 23B.

In the following description of the operation, the potential H is supplied to the wiring VLD, and the potential L is supplied to the wiring VLS. Either the potential H or the potential L is supplied to each of the wiring IN71, the wiring IN72, the wiring IN73, and the wiring IN7A.

The timing chart in FIG. 23D shows the potentials (the potential H and the potential L) supplied to the wiring IN71, the wiring IN72, the wiring IN73, and the wiring IN7A in the operation periods (Period T91 to Period T93). In addition, changes in the potentials of the wiring NL71, the wiring NL72, the wiring OUT71, and the wiring OUT7A are shown.

In Period T91, the potential L is supplied to the wiring IN71 and the wiring IN72. The potential of the wiring NL72 is the potential H. Accordingly, the potential L is supplied to the wiring NL71. In this case, the transistor M75 and the transistor M7A are each in an off state (a non-conduction state), and the transistor M76 and the transistor M7B are each in an on state (a conduction state). Accordingly, the potential L is supplied to each of the wiring OUT71 and the wiring OUT7A regardless of the potentials (the potential H and the potential L) of the wiring IN73 and the wiring IN7A. Note that in the following description of the operation, unless otherwise specified, the potentials of the wirings supplied in the immediately preceding period are maintained.

In Period T92, the potential H is supplied to the wiring IN71, and accordingly, the potential of the wiring NL72 becomes the potential L and the potential of the wiring NL71 becomes the potential H. Thus, the transistor M75 and the transistor M7A are each turned on, and the transistor M76 and the transistor M7B are each turned off. Accordingly, the potentials (the potential H and the potential L) of the wiring IN73 and the wiring IN7A are supplied to the wiring OUT71 and the wiring OUT7A through the transistor M75 and the transistor M7A, respectively. After that, even if the potential L is supplied to the wiring IN71, the potentials of the wiring NL72 and the wiring NL71 are maintained.

In Period T93, the potential H is supplied to the wiring IN72, and accordingly, the potential of the wiring NL72 becomes the potential H and the potential of the wiring NL71 becomes the potential L. Thus, the transistor M75 and the transistor M7A are each turned off, and the transistor M76 and the transistor M7B are each turned on. Accordingly, the potential L is supplied to each of the wiring OUT71 and the wiring OUT7A regardless of the potentials (the potential H and the potential L) of the wiring IN73 and the wiring IN7A. After that, even if the potential L is supplied to the wiring IN72, the potentials of the wiring NL72 and the wiring NL71 are maintained.

FIG. 23E is a circuit diagram showing a modification example of the register portion 91. A register portion 91a shown in FIG. 23E is different from the register portion 91 in including a bootstrap circuit. That is, the register portion 91a includes a transistor M77 and a capacitor C71, and a transistor M7C and a capacitor C7A in addition to the register portion 91. Note that the capacitor C71 and the capacitor C7A are referred to as bootstrap capacitors in some cases.

A gate of the transistor M77 is electrically connected to the wiring VLD. A gate of the transistor M75 is electrically connected to the wiring NL71 through a source and a drain of the transistor M77. The gate of the transistor M75 is also electrically connected to the wiring OUT71 through the capacitor C71.

A gate of the transistor M7C is electrically connected to the wiring VLD. A gate of the transistor M7A is electrically connected to the wiring NL71 through a source and a drain of the transistor M7C. The gate of the transistor M7A is also electrically connected to the wiring OUT7A through the capacitor C7A.

Here, in the register portion 91, when the potential H is transmitted from the wiring IN73 to the wiring OUT71, a potential decrease depending on the threshold voltage occurs in the transistor M75. Thus, with the use of the bootstrap circuit like the register portion 91a, capacitive coupling between the bootstrap capacitors can maintain the on state of the transistor M75. In this manner, the potential H can be transmitted to the wiring OUT71 without occurrence of the potential decrease depending on the threshold voltage.

In the register portion 91, similarly, when the potential H is transmitted from the wiring IN7A to the wiring OUT7A, a potential decrease depending on the threshold voltage occurs in the transistor M7A. Thus, with the use of the bootstrap circuit like the register portion 91a, capacitive coupling between the bootstrap capacitors can maintain the on state in the transistor M7A. In this manner, the potential H can be transmitted to the wiring OUT7A without occurrence of the potential decrease depending on the threshold voltage.

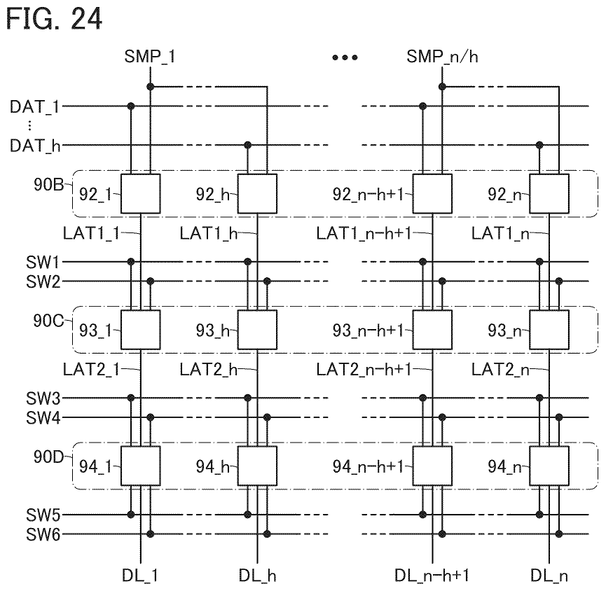

FIG. 24 is a circuit diagram showing a structure example of the latch portion 90B, the latch portion 90C, and the source follower portion 90D. The latch portion 90B includes n latch unit portions 92. The latch portion 90C includes n latch unit portions 93. The source follower portion 90D includes n source follower unit portions 94. In FIG. 24, a latch unit portion 92_1, a latch unit portion 92_h, a latch unit portion 92_n-h+1, and a latch unit portion 92_n are selectively shown as part of the latch portion 90B. A latch unit portion 93_1, a latch unit portion 93_h, a latch unit portion 93_n-h+1, and a latch unit portion 93_n are selectively shown as part of the latch portion 90C. A source follower unit portion 94_1, a source follower unit portion 94_h, a source follower unit portion 94_n-h+1, and a source follower unit portion 94_n are selectively shown as part of the source follower portion 90D. The wiring SMP_1 and the wiring SMP_n/h are selectively shown as part of the wirings SMP[1:n/h]. A wiring DAT_1 and a wiring DAT_h are selectively shown as part of the wirings DAT[1:h]. A wiring LAT1_1, a wiring LAT1_h, a wiring LAT1_n-h+1, and a wiring LAT1_n are selectively shown as part of the wirings LAT1[1:n]. A wiring LAT2_1, a wiring LAT2_h, a wiring LAT2_n-h+1, and a wiring LAT2_n are selectively shown as part of the wirings LAT2[1:n]. The wiring DL_1, a wiring DL_h, a wiring DL_n-h+1, and the wiring DL_n are selectively shown as part of the wirings DL[1:n].

Note that in this specification and the like, for example, in the case of denoting a given one wiring among a plurality of wirings denoted by “[1:n]”, “[1:h]”, or the like, the wiring is sometimes denoted by “_1”, “_n”, “_h”, or the like.

The n latch unit portions 92 are electrically connected to the n wirings LAT1. Furthermore, the h latch unit portions 92 are collectively electrically connected to any one of the n/h wirings SMP. In addition, each of the h latch unit portions 92 is electrically connected to the h wirings DAT. For example, the latch unit portion 92_1 is electrically connected to the wiring LAT1_1; the latch unit portion 92_h is electrically connected to the wiring LAT1_h; the latch unit portion 92_n-h+1 is electrically connected to the wiring LAT1_n-h+1; and the latch unit portion 92_n is electrically connected to the wiring LAT1_n. For example, the latch unit portion 92_1 and the latch unit portion 92_h are electrically connected to the wiring SMP_1, and the latch unit portion 92_n-h+1 and the latch unit portion 92_n are electrically connected to the wiring SMP_n/h. For example, the latch unit portion 92_1 and the latch unit portion 92_n-h+1 are electrically connected to the wiring DAT_1, and the latch unit portion 92_h and the latch unit portion 92_n are electrically connected to the wiring DAT_h.

The n latch unit portions 93 are electrically connected to the n wirings LAT1 and the n wirings LAT2. The n latch unit portions 93 are also electrically connected to the wiring SW1 and the wiring SW2. For example, the latch unit portion 93_1 is electrically connected to the wiring LAT1_1, the wiring LAT2_1, the wiring SW1, and the wiring SW2; the latch unit portion 93_h is electrically connected to the wiring LAT1_h, the wiring LAT2_h, the wiring SW1, and the wiring SW2; the latch unit portion 93_n-h+1 is electrically connected to the wiring LAT1_n-h+1, the wiring LAT2_n-h+1, the wiring SW1, and the wiring SW2; and the latch unit portion 93_n is electrically connected to the wiring LAT1_n, the wiring LAT2_n, the wiring SW1, and the wiring SW2.

The n source follower unit portions 94 are electrically connected to the n wirings LAT2 and the n wirings DL. The n source follower unit portions 94 are also electrically connected to the wiring SW3, the wiring SW4, the wiring SW5, and the wiring SW6. For example, the source follower unit portion 94_1 is electrically connected to the wiring LAT2_1, the wiring DL_1, the wiring SW3, the wiring SW4, the wiring SW5, and the wiring SW6; the source follower unit portion 94_h is electrically connected to the wiring LAT2_h, the wiring DL_h, the wiring SW3, the wiring SW4, the wiring SW5, and the wiring SW6; the source follower unit portion 94_n-h+1 is electrically connected to the wiring LAT2_n-h+1, the wiring DL_n-h+1, the wiring SW3, the wiring SW4, the wiring SW5, and the wiring SW6; and the source follower unit portion 94_n is electrically connected to the wiring LAT2_n, the wiring DL_n, the wiring SW3, the wiring SW4, the wiring SW5, and the wiring SW6.

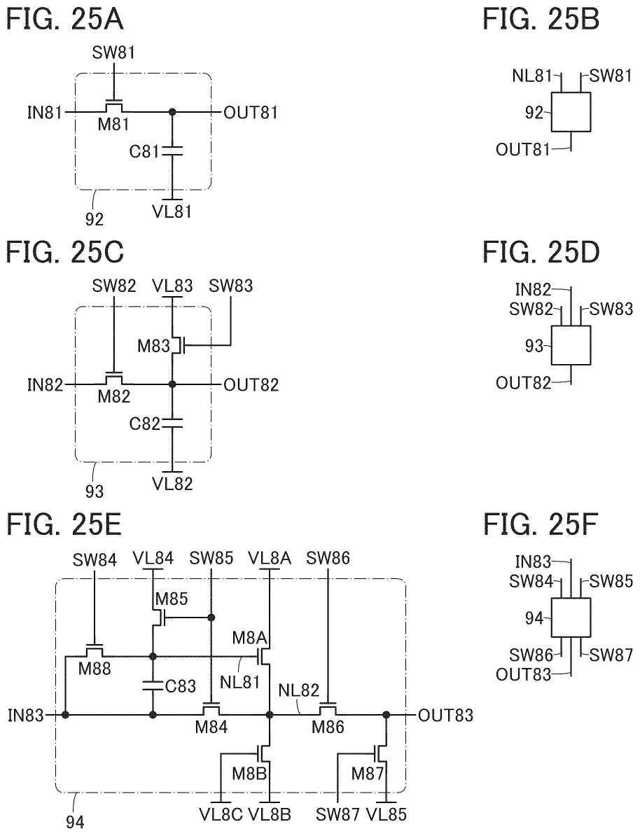

FIG. 25A is a circuit diagram showing a structure example of the latch unit portion 92. FIG. 25B is a circuit block corresponding to the latch unit portion 92. The latch unit portion 92 can be used as each of the latch unit portion 92_1 to the latch unit portion 92_n. That is, for example, in the latch unit portion 92_1, a wiring IN81 is electrically connected to the wiring DAT_1, a wiring SW81 is electrically connected to the wiring SMP_1, and a wiring OUT81 is electrically connected to the wiring LAT1_1. For example, in the latch unit portion 92_n, the wiring IN81 is electrically connected to the wiring DAT_h; the wiring SW81 is electrically connected to the wiring SMP_n/h, and the wiring OUT81 is electrically connected to the wiring LAT1_n. Note that a wiring VL81 is not shown in FIG. 24 and FIG. 25B. Note that the same applies to a latch unit portion 92_2 to a latch unit portion 92_n -1.

The latch unit portion 92 shown in FIG. 25A includes a transistor M81 and a capacitor C81. The transistor M81 has a function of establishing or breaking electrical continuity between the wiring IN81 and the wiring OUT81 in accordance with a potential of the wiring SW81. The capacitor C81 has a function of retaining a potential difference (voltage) between the wiring OUT81 and the wiring VL81 when the wiring OUT81 is in a floating state, for example.

That is, the latch unit portion 92 has a function of storing a potential of the wiring IN81 in the wiring OUT81 and a function of retaining the potential of the wiring OUT81, in accordance with the potential of the wiring SW81. That is, the latch unit portion 92 has a function of a sample-and-hold circuit.

FIG. 25C is a circuit diagram showing a structure example of the latch unit portion 93. FIG. 25D is a circuit block corresponding to the latch unit portion 93. The latch unit portion 93 can be used as each of the latch unit portion 93_1 to the latch unit portion 93_n. That is, for example, in the latch unit portion 93_1, a wiring IN82 is electrically connected to the wiring LAT1_1, a wiring SW82 is electrically connected to the wiring SW1, a wiring SW83 is electrically connected to the wiring SW2, and a wiring OUT82 is electrically connected to the wiring LAT2_1. For example, in the latch unit portion 93_n, the wiring IN82 is electrically connected to the wiring LAT1_n, the wiring SW82 is electrically connected to the wiring SW1, the wiring SW83 is electrically connected to the wiring SW2, and the wiring OUT82 is electrically connected to the wiring LAT2_n. Note that a wiring VL82 and a wiring VL83 are not shown in FIG. 24 and FIG. 25D. Note that the same applies to a latch unit portion 93_2 to a latch unit portion 93_n-1.

The latch unit portion 93 shown in FIG. 25C includes a transistor M82, a transistor M83, and a capacitor C82. The transistor M82 has a function of establishing or breaking electrical continuity between the wiring IN82 and the wiring OUT82 in accordance with a potential of the wiring SW82. The transistor M83 has a function of establishing or breaking electrical continuity between the wiring VL83 and the wiring OUT82 in accordance with a potential of the wiring SW83. The capacitor C82 has a function of retaining a potential difference (voltage) between the wiring OUT82 and the wiring VL82 when the wiring OUT82 is in a floating state, for example.

That is, the latch unit portion 93 has a function of storing a potential of the wiring IN82 in the wiring OUT82 in accordance with the potential of the wiring SW82 and a function of retaining the potential of the wiring OUT82. That is, the latch unit portion 93 has a function of a sample-and-hold circuit.

FIG. 25E is a circuit diagram showing a structure example of the source follower unit portion 94. FIG. 25F is a circuit block corresponding to the source follower unit portion 94. The source follower unit portion 94 can be used as each of the source follower unit portion 94_1 to the source follower unit portion 94_n. That is, for example, in the source follower unit portion 94_1, a wiring IN83 is electrically connected to the wiring LAT2_1; a wiring SW84 is electrically connected to the wiring SW3; a wiring SW85 is electrically connected to the wiring SW4; a wiring SW86 is electrically connected to the wiring SW5; a wiring SW87 is electrically connected to the wiring SW6; and a wiring OUT83 is electrically connected to the wiring DL_1. For example, in the source follower unit portion 94_n, the wiring IN83 is electrically connected to the wiring LAT2_n ; the wiring SW84 is electrically connected to the wiring SW3; the wiring SW85 is electrically connected to the wiring SW4; the wiring SW86 is electrically connected to the wiring SW5; the wiring SW87 is electrically connected to the wiring SW6; and the wiring OUT83 is electrically connected to the wiring DL_n. Note that in FIG. 24 and FIG. 25F, a wiring VL8A, a wiring VL8B, a wiring VL8C, a wiring VL84, and a wiring VL85 are not shown. Note that the same applies to a source follower unit portion 94_2 to a source follower unit portion 94_n-1.

The source follower unit portion 94 shown in FIG. 25E includes a transistor M8A, a transistor M8B, a transistor M84, a transistor M85, a transistor M86, a transistor M87, a transistor M88, and a capacitor C83.

A gate of the transistor M8A is electrically connected to a wiring NL81. One of a source and a drain of the transistor M8A is electrically connected to one of a source and a drain of the transistor M8B and a wiring NL82, and the other of the source and the drain of the transistor M8A is electrically connected to the wiring VL8A. The other of the source and the drain of the transistor M8B is electrically connected to the wiring VL8B. A gate of the transistor M8B is electrically connected to the wiring VL8C. The structure of the transistor M8A and the transistor M8B has a function of a source follower in which the gate of the transistor M8A serves as an input terminal and the one of the source and the drain of the transistor M8A serves as an output terminal. That is, the transistor M8A has a function of a driving transistor, and the transistor M8B has a function of a load transistor. Note that the structure of the transistor M8A and the transistor M8B can also have a function of a source-grounded amplifier circuit. The transistor M8B having the function of a load transistor can be replaced with a resistor, for example.

The transistor M84 has a function of establishing or breaking electrical continuity between the wiring NL82 and the wiring IN83 in accordance with the potential of the wiring SW85. The transistor M85 has a function of establishing or breaking electrical continuity between the wiring VL84 and the wiring NL81 in accordance with the potential of the wiring SW85. The transistor M88 has a function of establishing or breaking electrical continuity between the wiring IN83 and the wiring NL81 in accordance with a potential of the wiring SW84. The capacitor C83 has a function of retaining a potential difference (voltage) between the wiring NL81 and the wiring IN83 when the wiring NL81 is in a floating state, for example.

The transistor M86 has a function of establishing or breaking electrical continuity between the wiring NL82 and the wiring OUT83 in accordance with a potential of the wiring SW86. The transistor M87 has a function of establishing or breaking electrical continuity between the wiring VL85 and the wiring OUT83 in accordance with a potential of the wiring SW87.

Note that the structure of the latch unit portion 93 and the source follower unit portion 94 can correspond to the above-described semiconductor device 60 (the structure shown in FIG. 1A to FIG. 1C). In this case, the transistor M82 corresponds to the transistor M13; the transistor M8A corresponds to the transistor M11; the transistor M8B corresponds to the transistor M12; the transistor M84 corresponds to the transistor M14; the transistor M85 corresponds to the transistor M15; the transistor M86 corresponds to the transistor M16; the transistor M87 corresponds to the transistor M17; and the capacitor C83 corresponds to the capacitor C11. The wiring IN82 corresponds to the wiring IN11, and the wiring OUT83 corresponds to the wiring OUT11.

The generation portion 64 included in the semiconductor device 60 may be used for the structure of the latch unit portion 93 and the source follower unit portion 94. That is, the generation portion 64 may be provided between the wiring IN82 and the wiring VL85 so that a potential corresponding to the potential of the wiring IN82 is generated and supplied to the wiring VL85. In this case, the wiring VL85 corresponds to the wiring VL15.

FIG. 26 is a timing chart showing an operation example of the semiconductor device 90.

In the following description of the operation, the plurality of wirings CLK are set to four wirings of a wiring CLK_1, a wiring CLK_2, a wiring CLK_3, and a wiring CLK_4 (i.e., the plurality of wirings CLK are supplied with four-phase clock signals), and the plurality of wirings PWC are set to four wirings of a wiring PWC_1, a wiring PWC_2, a wiring PWC_3, and a wiring PWC_4 (i.e., the plurality of wirings PWC are supplied with four-phase clock signals). Either the potential H or the potential L is supplied to each of the wiring CLK_1 to the wiring CLK_4, each of the wiring PWC_1 to the wiring PWC_4, and the wiring SP. Furthermore, either the potential H or the potential L is supplied to each of the wiring SW1, the wiring SW2, the wiring SW3, the wiring SW4, the wiring SW5, and the wiring SW6. The potential H is supplied to the wiring VLD, and the potential L is supplied to the wiring VLS. A constant potential (e.g., a potential between the potential H and the potential L) is supplied to each of the wiring VL81, the wiring VL82, the wiring VL83, the wiring VL84, and the wiring VL85. A constant potential (a potential for making the source follower unit portion 94 function as a source follower) is supplied to each of the wiring VL8A, the wiring VL8B, and the wiring VL8C.

Note that the operation example of the register portion 91 (see FIG. 23D) and the operation example of the semiconductor device 60 corresponding to the structure of the latch unit portion 93 and the source follower unit portion 94 (see FIG. 2A) can be referred to as appropriate.

The timing chart in FIG. 26 shows the potentials (the potential H and the potential L) supplied to the wiring CLK_1 to the wiring CLK_4, the wiring PWC_1 to the wiring PWC_4, and the wiring SP in each operation period (Period T9A and Period T9B). In addition, changes in the potentials of the wiring SMP[1] and a wiring SMP[n/h] are shown. A data potential Vd supplied to the wirings DAT[1:h] is shown. Changes in potentials of wirings LAT1[1:h] and wirings LAT1[n-h+1:n] are shown. The potentials (the potential H and the potential L) supplied to the wiring SW1, the wiring SW2, the wiring SW3, the wiring SW4, the wiring SW5, and the wiring SW6 are shown. Changes in potentials of wirings LAT2[1:h], wirings LAT2[n-h+1:n], wirings DL[1:h], and wirings DL[n-h+1:n] are shown.

Note that in this specification and the like, for example, in the case of denoting any h wirings among n wirings denoted by “[1:n]”, the wirings are sometimes denoted by “[1:h]”, “[n-h+1:n]”, or the like. That is, for example, “[1:h]” denotes h wirings from the first to h-th wirings, and “[n-h+1:n]” denotes h wirings from the n-h+1-th to n-th wirings. In other words, for example, the description of “[1:h]” corresponds to the description of “_1” to “h” , and the description “[n-h+1:n]” corresponds to the description of “_n-h+1:n” to “_n”. As another example, in the case of denoting a given one wiring among n/h wirings denoted by “[1:n/h]”, the wiring is sometimes denoted by “[1]”, “[n/h]”, or the like. That is, for example, “[1]” denotes a first wiring and “[n/h]” denotes an n/h-th wiring. In other words, for example, the description of “[1]” corresponds to the description of “1” , and the description of “[n/h]” corresponds to the description of “_n/h”.

In Period T9A, signals are sequentially output to the wiring SMP[1] to the wiring SMP[n/h] by the shift register portion 90A. With the signals sequentially output to the wiring SMP[1] to the wiring SMP[n/h] used as triggers, a potential input through the wirings DAT[1:h] is stored and retained, and then is output to the wirings LAT1[1:n] by the latch portion 90B.

FIG. 26 shows a state where the data potential Vd_1 that is input through the wirings DAT[1:h] is stored and retained with the signal output to the wiring SMP[1] used as the trigger and then is output to the wirings LAT1[1:h] and a state where the data potential Vd_n/h that is input through the wirings DAT[1:h] is stored and retained with the signal output to the wiring SMP[n/h] used as the trigger and then is output to the wirings LAT1[n-h+1:n], in Period T9A.

Note that in Period T9A, the potential L is supplied to the wiring SW1, the wiring SW2, the wiring SW3, the wiring SW4, and the wiring SW6, and the potential H is supplied to the wiring SW5.

In Period T9B, first, the potential L is supplied to the wiring SW5 and the potential H is supplied to the wiring SW6. Then, the wirings DL[1:n] is precharged to a potential of the wiring VL85 (corresponding to the precharge operation of the semiconductor device 60) by the source follower portion 90D.

Next, the wiring SW2 is supplied with the potential H, and then is supplied with the potential L after a certain period. In this period, the potential of the wirings LAT2[1:n] is reset (initialized) to a potential of the wiring VL83 by the latch portion 90C.

Subsequently, the wiring SW4 is supplied with the potential H, and then is supplied with the potential L after a certain period. In this period, in the source follower portion 90D, an operation of correcting a potential input from the wirings LAT2[1:n] is performed (corresponding to the correction operation of the semiconductor device 60).

Next, the wiring SW1 is supplied with the potential H, and then is supplied with the potential L after a certain period. In this period, the potentials of the wiring LAT1_1 to the wiring LAT1 n are stored and retained and then are output to the wiring LAT2_1 to the wiring LAT2_n by the latch portion 90C (corresponding to the input operation of the semiconductor device 60).

Subsequently, the wiring SW5 is supplied with the potential H, and the wiring SW6 is supplied with the potential L. In this period, potentials corresponding to potentials of the wiring LAT2_1 to the wiring LAT2_n are output to the wiring DL_1 to the wiring DL_n by the source follower portion 90D (corresponding to the output operation of the semiconductor device 60).

Note that in Period T9B shown in FIG. 26, the operation may be performed such that the potential L is supplied to the wiring SW4 and the potential H is supplied to the wiring SW3. In this case, the correction operation is not performed in the source follower unit portion 94, and a potential of the wiring IN83 is supplied to the wiring NL81. Thus, the operation speed of the semiconductor device 90 can be improved.

According to one embodiment of the present invention, the semiconductor device 90 can be used in the display apparatus 40. For example, the semiconductor device 90 can be used as part of the source driver in the display apparatus 40. In that case, the wiring DL_1 to the wiring DL_n correspond to the wirings DL in the pixels 41 that are arranged in the n columns and each employ the semiconductor device 20A.

With the use of the semiconductor device 90 in the display apparatus 40, the number of data lanes input from the outside of the display apparatus 40 can be smaller than the number n of columns of the pixels 41. This leads to, for example, the reduced size and cost of the display apparatus.

According to one embodiment of the present invention, there is no limitation on the structure of the semiconductor device 90 described above, and the structures may be changed as appropriate as long as the display apparatus described above can be obtained.

### Series Connection of Transistors

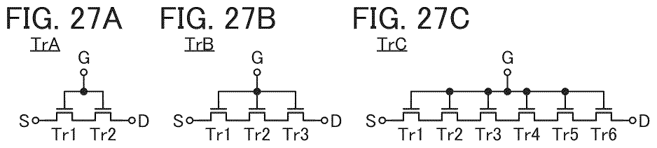

FIG. 27A to FIG. 27C are circuit diagrams showing series connection of transistors.

In one embodiment of the present invention, the transistors included in the pixel circuit and the peripheral driver circuit may each be a single-gate transistor having one gate between a source and a drain, or a double-gate transistor. FIG. 27A shows a circuit symbol example of a double-gate transistor TrA.

The transistor TrA has a structure in which a transistor Tr1 and a transistor Tr2 are connected in series. In the transistor TrA shown in FIG. 27A, one of a source and a drain of the transistor Tr1 is electrically connected to a terminal S. The other of the source and the drain of the transistor Tr1 is electrically connected to one of a source and a drain of the transistor Tr2. The other of the source and the drain of the transistor Tr2 is electrically connected to a terminal D. In the transistor TrA shown in FIG. 27A, gates of the transistor Tr1 and the transistor Tr2 are electrically connected to each other and electrically connected to a terminal G.

The transistor TrA shown in FIG. 27A has a function of switching electrical continuity and discontinuity between the terminal S and the terminal D by changing a potential of the terminal G. Thus, the transistor TrA that is a double-gate transistor serves as one transistor including the transistor Tr1 and the transistor Tr2. That is, it can be said that in FIG. 27A, one of a source and a drain of the transistor TrA is electrically connected to the terminal S, the other of the source and the drain of the transistor TrA is electrically connected to the terminal D, and a gate of the transistor TrA is electrically connected to the terminal G.

The transistors included in the pixel circuit and the peripheral driver circuit may each be a triple-gate transistor. FIG. 27B shows a circuit symbol example of a triple-gate transistor TrB.

The transistor TrB has a structure in which the transistor Tr1, the transistor Tr2, and a transistor Tr3 are connected in series. In the transistor TrB shown in FIG. 27B, the one of the source and the drain of the transistor Tr1 is electrically connected to the terminal S. The other of the source and the drain of the transistor Tr1 is electrically connected to the one of the source and the drain of the transistor Tr2. The other of the source and the drain of the transistor Tr2 is electrically connected to one of a source and a drain of the transistor Tr3. The other of the source and the drain of the transistor Tr3 is electrically connected to the terminal D. In the transistor TrB shown in FIG. 27B, the gates of the transistor Tr1, the transistor Tr2, and the transistor Tr3 are electrically connected to one another and electrically connected to the terminal G.

The transistor TrB shown in FIG. 27B has a function of switching electrical continuity and discontinuity between the terminal S and the terminal D by changing the potential of the terminal G. Thus, the transistor TrB that is a triple-gate transistor serves as one transistor including the transistor Tr1, the transistor Tr2, and the transistor Tr3. That is, it can be said that in FIG. 27B, one of a source and a drain of the transistor TrB is electrically connected to the terminal S, the other of the source and the drain of the transistor TrB is electrically connected to the terminal D, and a gate of the transistor TrB is electrically connected to the terminal G.

The transistors included in the pixel circuit and the peripheral driver circuit may each have a structure in which four or more transistors are connected in series. A transistor TrC shown in FIG. 27C has a structure in which six transistors (the transistor Tr1 to a transistor Tr6) are connected in series. In the transistor TrC shown in FIG. 27C, the gates of the six transistors are electrically connected to one another and are electrically connected to the terminal G.

The transistor TrC shown in FIG. 27C has a function of switching electrical continuity and discontinuity between the terminal S and the terminal D by changing the potential of the terminal G. Thus, the transistor TrC serves as one transistor including the transistor Tr1 to the transistor Tr6. That is, it can be said that in FIG. 27C, one of a source and a drain of the transistor TrC is electrically connected to the terminal S, the other of the source and the drain of the transistor TrC is electrically connected to the terminal D, and a gate of the transistor TrC is electrically connected to the terminal G.

Like the transistor TrA, the transistor TrB, and the transistor TrC, a transistor having a plurality of gates electrically connected to one another is referred to as a “multi-gate type transistor” or a “multi-gate transistor” in some cases.

According to one embodiment of the present invention, the use of any of the multi-gate transistors achieves a transistor having a substantially long channel length. This leads to lower off-state current and higher drain breakdown voltage (i.e., higher reliability). In addition, high saturation characteristics can be obtained. The use of such a transistor having favorable saturation can offer, for example, an ideal current source circuit, an active load having an extremely high resistance, or the like. Accordingly, a differential circuit or a current mirror circuit having excellent properties can be obtained, for example.

In one embodiment of the present invention, a vertical OS transistor can be used as the transistor included in any of various constituent circuits described above. The use of vertical OS transistors as some or all of the transistors included in the constituent circuits can reduce the area occupied by the circuits. This leads to the narrower bezel, higher resolution, and higher definition of the display apparatus, for example.

The semiconductor device and the display apparatus according to one embodiment of the present invention are not limited to those described in this embodiment. At least part of the structure examples, the operation examples, the drawings corresponding thereto, and the like described in this embodiment as an example can be combined with the other structure examples, the other operation examples, the other drawings, and the other embodiments described in this specification and the like as appropriate.

### Embodiment 2

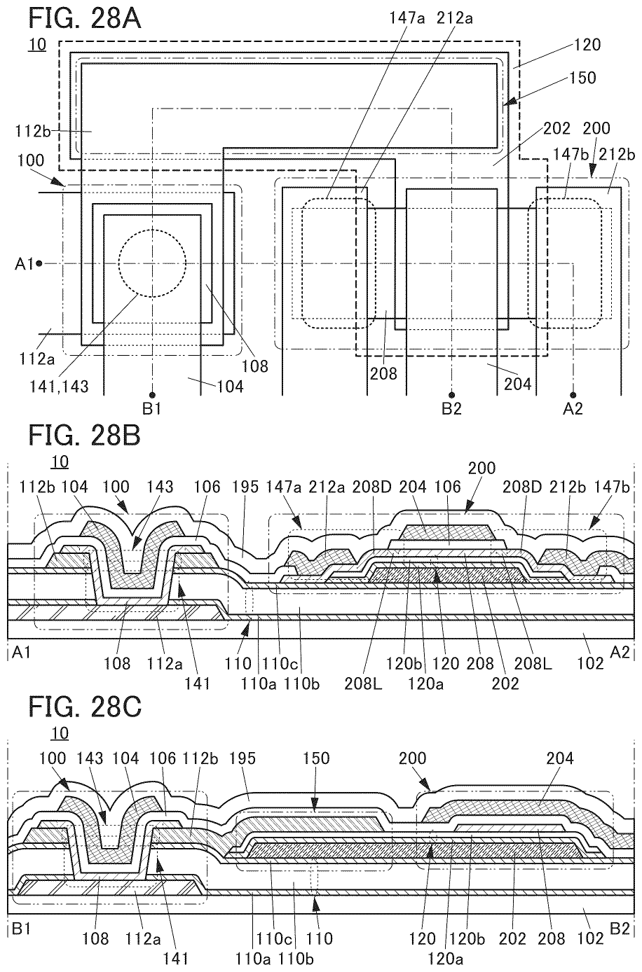

In this embodiment, a semiconductor device of one embodiment of the present invention is described with reference to FIG. 28 to FIG. 37.

One embodiment of the present invention is a semiconductor device including a transistor and a first insulating layer.

The transistor includes a first conductive layer, a second conductive layer including a region overlapping with the first conductive layer with the first insulating layer therebetween, a semiconductor layer, a gate insulating layer, and a gate electrode. The second conductive layer includes a first opening in a region overlapping with the first conductive layer. The first insulating layer include a second opening reaching the first conductive layer in a region overlapping with the first opening. In the first opening and the second opening, the semiconductor layer is in contact with the top surface of the first conductive layer, the side surface of the first insulating layer, and the side surface of the second conductive layer. The gate insulating layer is provided over the semiconductor layer and the gate electrode is provided over the gate insulating layer. In this transistor, the first conductive layer serves as one of a source electrode and a drain electrode and the second conductive layer serves as the other of them. In the transistor, the source electrode, the semiconductor layer including a channel formation region, and the drain electrode can overlap with one another and the occupied area can be reduced accordingly. The region of the semiconductor layer that is in contact with the first insulating layer serves as the channel formation region. Consequently, the channel length of the transistor can be shorter than the resolution limit of a light-exposure apparatus and the on-state current of the transistor can be high.

The semiconductor layer preferably includes a metal oxide. For the first insulating layer, a material releasing oxygen is preferably used. Thus, oxygen can be supplied from the first insulating layer to the semiconductor layer (channel formation region, in particular) to reduce oxygen vacancies (V_{O}) in the semiconductor layer.

In a transistor with a short channel length, the amount of oxygen supplied from the first insulating layer to the semiconductor layer is preferably as large as possible. In addition, the diffusion coefficient of oxygen in the first insulating layer is preferably high. Specifically, the diffusion coefficient of oxygen in the first insulating layer is preferably higher than or equal to 5×10⁻¹² cm²/sec at 350° C. Under such conditions, oxygen diffuses into the first insulating layer at high speed and can be effectively supplied to the semiconductor layer. This allows even a transistor with a short channel length to achieve both excellent electrical characteristics and high reliability.

### Structure Example 1

The semiconductor device of one embodiment of the present invention will be described. FIG. 28A is a top view (also referred to as a plan view) of a semiconductor device 10. FIG. 28B is a cross-sectional view of a cut plane along the dashed-dotted line A1-A2 in FIG. 28A, and FIG. 28C is a cross-sectional view of a cut plane along the dashed-dotted line B1-B2. Note that in FIG. 28A, some components (e.g., an insulating layer) of the semiconductor device 10 are not shown. Some components are not shown in top views of semiconductor devices in the following diagrams, as in FIG. 28A.

The semiconductor device 10 includes a transistor 100, a transistor 200, a capacitor 150, and an insulating layer 110. The transistor 100, the transistor 200, and the capacitor 150 are provided over a substrate 102. The transistor 100 has a structure different from the structure of the transistor 200. Some of the formation steps can be the same between the transistor 100, the transistor 200, and the capacitor 150.

The transistor 100 includes a conductive layer 104, an insulating layer 106, a semiconductor layer 108, a conductive layer 112a, and a conductive layer 112b. In the transistor 100, the conductive layer 104 serves as a gate electrode (also referred to as a first gate electrode), and part of the insulating layer 106 serves as a gate insulating layer (also referred to as a first gate insulating layer). The conductive layer 112a serves as one of a source electrode and a drain electrode, and the conductive layer 112b serves as the other of the source electrode and the drain electrode. The layers forming the transistor 100 may each have a single-layer structure or a stacked-layer structure.

The conductive layer 112a is provided over the substrate 102, and the insulating layer 110 is provided over the conductive layer 112a. The insulating layer 110 is provided to cover the top surface and the side surface of the conductive layer 112a. The insulating layer 110 has an opening 141 reaching the conductive layer 112a in a region overlapping with the conductive layer 112a. It can be said that the conductive layer 112a is exposed in the opening 141.

The conductive layer 112b is provided over the insulating layer 110. The conductive layer 112b includes a region overlapping with the conductive layer 112a with the insulating layer 110 therebetween. The conductive layer 112b has an opening 143 in a region overlapping with the conductive layer 112a. The opening 143 is provided in a region overlapping with the opening 141.

The opening 141 and the opening 143 each have a pillar shape with a circular or substantially circular top surface. With such a structure, for example, miniaturization, high integration, high density, and a reduction in size of the semiconductor device can be achieved. Note that the side surfaces of the opening 141 and the opening 143 are preferably perpendicular to the top surface of the conductive layer 112a.

At least part of the semiconductor layer 108 is provided to cover the opening 141 and the opening 143. The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a. The semiconductor layer 108 includes a region overlapping with the conductive layer 112a with the insulating layer 110 therebetween. It can be said that the insulating layer 110 includes a region sandwiched between the conductive layer 112a and the semiconductor layer 108. In other words, it can be said that part of the semiconductor layer 108 is provided in the opening 141 and the opening 143.

In the semiconductor layer 108, a region in contact with the conductive layer 112a serves as one of a source region and a drain region, and the region in contact with the conductive layer 112b serves as the other of the source region and the drain region. In the semiconductor layer 108, the channel formation region is provided between the source region and the drain region.

At least part of the insulating layer 106 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface and the side surface of the semiconductor layer 108, the top surface and the side surface of the conductive layer 112b, and the top surface of the insulating layer 110.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106. Note that the conductive layer 104 may be provided to fill the opening 141 and the opening 143.

The transistor 100 is what is called a top-gate transistor including the gate electrode above the semiconductor layer 108. Furthermore, since the bottom surface of the semiconductor layer 108 is in contact with the conductive layer 112a and the conductive layer 112b that serve as the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and drain current flows in the vertical direction (also referred to as the height direction, the depth direction in the top view, or the direction perpendicular to the formation surface (the surface of the substrate 102)). In other words, the channel length direction of the transistor 100 can be regarded as having a component of the height direction. Accordingly, a transistor like the transistor 100 of one embodiment of the present invention can be referred to as a vertical transistor, a vertical-channel transistor, a VFET (vertical field-effect transistor), or the like.

The channel length of the transistor 100 can be controlled by the thickness of the insulating layer 110 (specifically, an insulating layer 110b) provided between the conductive layer 112a and the conductive layer 112b. Accordingly, a transistor with a channel length smaller than the resolution limit of a light-exposure apparatus used for manufacturing the transistor can be manufactured with high accuracy. Furthermore, variations in characteristics among the transistors 100 are also reduced. Accordingly, the operation of the semiconductor device including the transistor 100 can be stabilized and the reliability thereof can be improved. The reduced variations in characteristics increases the circuit design flexibility of the semiconductor device, thereby reducing the operation voltage. Thus, the power consumption of the semiconductor device can be reduced.

In the transistor 100, the source electrode, the semiconductor layer including the channel formation region, and the drain electrode can be provided to overlap with one another; thus, the area occupied by the transistor can be significantly smaller than the area occupied by what is called a planar transistor in which a semiconductor layer including a channel formation region is provided in a planar shape.

The conductive layer 112a, the conductive layer 112b, and the conductive layer 104 can serve as wirings, and the transistor 100 can be provided in the region where these wirings overlap with one another. That is, the areas occupied by the transistor 100 and the wirings can be reduced in the circuit including the transistor 100 and the wirings. Accordingly, the area occupied by the circuit can be reduced, which makes it possible to provide a small semiconductor device.

The transistor 200 includes a conductive layer 204, a conductive layer 212a, a conductive layer 212b, the insulating layer 106, a semiconductor layer 208, an insulating layer 120, and a conductive layer 202. In the transistor 200, the conductive layer 204 serves as a gate electrode (also referred to as a first gate electrode), and part of the insulating layer 106 serves as a gate insulating layer (also referred to as a first gate insulating layer). The conductive layer 202 serves as a back gate electrode (also referred to as a second gate electrode), and part of the insulating layer 120 serves as a back gate insulating layer (also referred to as a second gate insulating layer). The conductive layer 212a serves as one of the source electrode and the drain electrode, and the conductive layer 212b serves as the other. The layers constituting the transistor 200 may each have a single-layer structure or a stacked-layer structure. Note that the transistor 200 does not necessarily include the conductive layer 202.

In the semiconductor layer 208 between the source electrode and the drain electrode, the whole region overlapping with the gate electrode with the gate insulating layer therebetween serves as a channel formation region. The semiconductor layer 208 includes a pair of regions 208L between which a channel formation region is sandwiched and a pair of regions 208D outside the pair of regions 208L.

The regions 208L and the regions 208D each include the impurity element. Examples of the impurity element include one or more of hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use one or more of boron, phosphorus, aluminum, magnesium, and silicon as the impurity element.

An impurity element is supplied (or added or implanted) to the semiconductor layer 208 using the conductive layer 204, the conductive layer 212a, and the conductive layer 212b as masks. Thus, the regions 208D are formed in regions of the semiconductor layer 208 that overlaps with none of the conductive layer 204, the conductive layer 212a, the conductive layer 212b, and the insulating layer 106, and the regions 208L are formed in regions of the semiconductor layer 208 that overlaps with none of the conductive layer 204, the conductive layer 212a, and the conductive layer 212b and overlaps with the insulating layer 106.

In the semiconductor layer 208, a region in contact with the conductive layer 212a and the region 208D adjacent to the region serve as one of a source region and a drain region. In the semiconductor layer 208, a region in contact with the conductive layer 212b and the region 208D adjacent to the region serve as the other of the source region and the drain region.

The conductive layer 202 is provided over the insulating layer 110, and the insulating layer 120 is provided over the conductive layer 202. The insulating layer 120 is provided so as to cover the top surface and the side surface of the conductive layer 202. The insulating layer 120 includes a portion protruding beyond an end portion of the conductive layer 202. An end portion of the insulating layer 120 is in contact with the top surface of the insulating layer 110.

The semiconductor layer 208 is provided over the insulating layer 120. The semiconductor layer 208 includes a region overlapping with the conductive layer 202 with the insulating layer 120 therebetween. The semiconductor layer 208 can be formed using the same material as the semiconductor layer 108. The semiconductor layer 208 can be formed in the same step as the semiconductor layer 108. For example, a film to be the semiconductor layer 108 and the semiconductor layer 208 is formed and then processed, whereby the semiconductor layer 108 and the semiconductor layer 208 can be formed.

The insulating layer 106 is provided over the semiconductor layer 208. Part of the insulating layer 106 serves as the gate insulating layer of the transistor 100 and another part of the insulating layer 106 serves as the gate insulating layer of the transistor 200. The insulating layer 106 includes an opening 147a and an opening 147b in regions overlapping with the semiconductor layer 208.

The conductive layer 204, the conductive layer 212a, and the conductive layer 212b are provided over the insulating layer 106. The conductive layer 204 includes a region overlapping with the semiconductor layer 208 with the insulating layer 106 therebetween. The conductive layer 204 includes a region overlapping with the conductive layer 202 with the semiconductor layer 208 therebetween. The conductive layer 212a and the conductive layer 212b are provided to cover the opening 147a and the opening 147b, respectively. The conductive layer 212a is electrically connected to the semiconductor layer 208 through the opening 147a, and the conductive layer 212b is electrically connected to the semiconductor layer 208 through the opening 147b. The conductive layer 204, the conductive layer 212a, and the conductive layer 212b can include the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and then processed, whereby the conductive layer 104, the conductive layer 204, the conductive layer 212a, and the conductive layer 212b can be formed.

The transistor 200 is a planar transistor in which the semiconductor layer 208 is provided in a planar shape. The transistor 200 is what is called a top-gate transistor including the gate electrode above the semiconductor layer 208. For example, when an impurity element is added to the semiconductor layer 208 with the conductive layer 204, which serves as the gate electrode, used as a mask, the regions 208D serving as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 has a value larger than or equal to that of the resolution limit of a light-exposure apparatus used for manufacturing the transistor. That is, the channel length of the transistor 200 can be longer than that of the transistor 100. The transistor with a long channel length can have favorable saturation.

The transistor 100 with a short channel length and the transistor 200 with a long channel length can be formed over the same substrate by the formation steps some of which are shared. For example, the transistor 100 is used as the transistor required to have high on-state current and the transistor 200 is used as the transistor required to have favorable saturation, thereby providing a high-performance semiconductor device.

When the semiconductor device of one embodiment of the present invention is used for a pixel circuit of a display apparatus, for example, the area occupied by the pixel circuit can be reduced and a high-resolution display apparatus can be obtained. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel, for example.

The capacitor 150 includes the conductive layer 112b and the conductive layer 202 serving as a pair of electrodes and the insulating layer 120. The conductive layer 112b serves as the other of the source electrode and the drain electrode of the transistor 100 and also serves as one of the pair of electrodes of the capacitor 150. The conductive layer 202 serves as the back gate electrode of the transistor 200 and as the other of the pair of electrodes of the capacitor 150. In the insulating layer 120, a region sandwiched between the conductive layer 112b and the conductive layer 202 serves as a dielectric of the capacitor 150. When the conductive layer 112b and the conductive layer 202 are formed by different steps, the capacitor 150 having the conductive layer 112b and the conductive layer 202 as the pair of electrodes can be formed. Forming the conductive layer 112b and the conductive layer 202 by different steps enables employing different materials, whereby the range of choices for materials can be widened.

Although a structure in which the capacitor 150 includes the conductive layer 112b, the conductive layer 202, and the insulating layer 120 is described as an example in FIG. 28A and the like, there is no limitation on the structure of the capacitor 150. For example, a structure of the capacitor 150 that includes the conductive layer 212a (or the conductive layer 212b), the conductive layer 112b, and the insulating layer 106 can be given as another example. For another example, a structure including the conductive layer 202, the conductive layer 112a, and the insulating layer 110 can be given. Furthermore, the capacitor 150 is not necessarily included in the semiconductor device 10. In the case where the capacitor 150 including the conductive layer 112b, the conductive layer 202, and the insulating layer 120 is not provided, the conductive layer 112b and the conductive layer 202 may be formed in the same step.

Although the other of the source electrode and the drain electrode of the transistor 100 is electrically connected to the one of the pair of electrodes of the capacitor 150 and the one of the source electrode and the drain electrode of the transistor 200 is electrically connected to the other of the pair of electrodes of the capacitor 150 in FIG. 28A and the like, there is no limitation on the electrical connection relation between the transistor 100, the transistor 200, and the capacitor 150.

An insulating layer 195 is provided to cover the transistor 100, the transistor 200, and the capacitor 150. The insulating layer 195 serves as a protective layer of the transistor 100, the transistor 200, and the capacitor 150.

A semiconductor material used for the semiconductor layer 108 and the semiconductor layer 208 is not particularly limited. For example, a single-element semiconductor or a compound semiconductor can be used. Examples of a single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may include an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). The transistor including amorphous silicon in the channel formation region can be formed over a large glass substrate, and can be manufactured at low cost. A transistor including polycrystalline silicon in the channel formation region has high field-effect mobility and enables high-speed operation. A transistor including microcrystalline silicon in the channel formation region has higher field-effect mobility and enables higher speed operation than the transistor including amorphous silicon.

Each of the semiconductor layer 108 and the semiconductor layer 208 preferably includes a metal oxide exhibiting semiconductor characteristics (also referred to as an oxide semiconductor).

The band gap of the metal oxide used for the semiconductor layer 108 and the band gap of the metal oxide used for the semiconductor layer 208 are each preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has extremely low off-state current, and charge accumulated in a capacitor that is connected in series to the transistor can be retained for a long period. Furthermore, a semiconductor device can have lower power consumption by including the OS transistor.

### Transistor 100

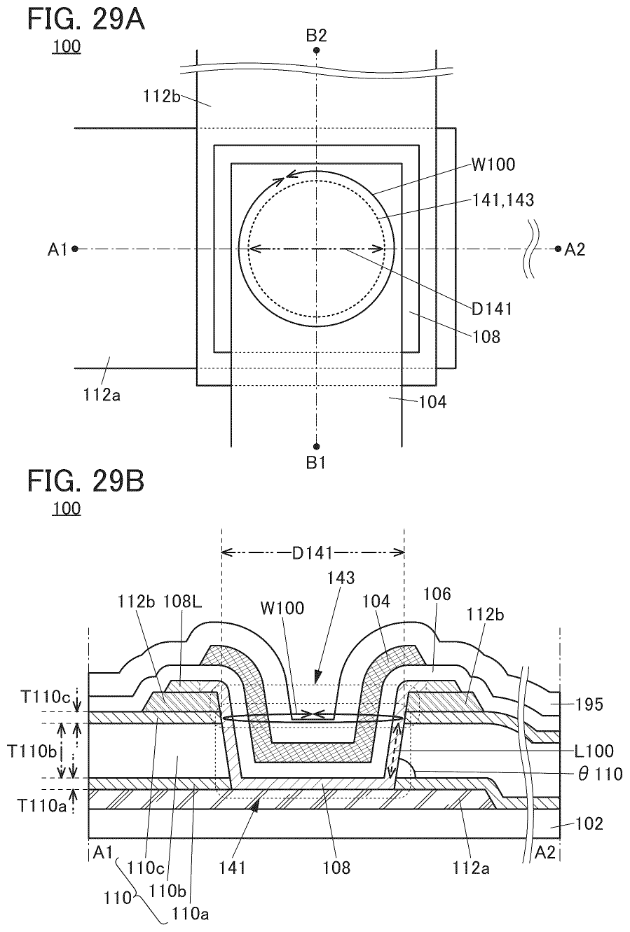

A detailed structure of the transistor 100 is described with reference to FIG. 28A to FIG. 28C, FIG. 29A, and FIG. 29B. FIG. 29A and FIG. 29B are enlarged views of the transistor 100 shown in FIG. 28A and FIG. 28B.

The insulating layer 110 preferably include one or more of an inorganic insulating film. Examples of a material usable for the inorganic insulating film include an oxide, a nitride, an oxynitride, and a nitride oxide. Examples of the oxide include a silicon oxide, an aluminum oxide, a magnesium oxide, a gallium oxide, a germanium oxide, a yttrium oxide, a zirconium oxide, a lanthanum oxide, a neodymium oxide, a hafnium oxide, a tantalum oxide, a cerium oxide, a gallium zinc oxide, and hafnium aluminate. Examples of the nitride include a silicon nitride and an aluminum nitride. Examples of the oxynitride include a silicon oxynitride, an aluminum oxynitride, a gallium oxynitride, a yttrium oxynitride, and a hafnium oxynitride. Examples of the nitride oxide include a silicon nitride oxide and an aluminum nitride oxide.

In this specification and the like, an oxynitride refers to a material that includes more oxygen than nitrogen in its composition. A nitride oxide refers to a material that includes more nitrogen than oxygen in its composition.

In the transistor 100, the insulating layer 110 includes a region in contact with the semiconductor layer 108. In the case where the semiconductor layer 108 is formed using a metal oxide, at least part of the region of the insulating layer 110 that is in contact with the semiconductor layer 108 preferably includes oxygen to improve the characteristics of the interface between the semiconductor layer 108 and the insulating layer 110. Specifically, the region of the insulating layer 110 that is in contact with a channel formation region of the semiconductor layer 108 preferably includes oxygen. One or more of an oxide and an oxynitride can be used for the region of the insulating layer 110 that is in contact with the channel formation region of the semiconductor layer 108.

The insulating layer 110 preferably has a stacked-layer structure. FIG. 28B and the like show an example in which the insulating layer 110 has a stacked-layer structure of an insulating layer 110a, the insulating layer 110b over the insulating layer 110a, and an insulating layer 110c over the insulating layer 110b.

A region of the semiconductor layer 108 that is in contact with the insulating layer 110b serves as a channel formation region. The insulating layer 110b preferably includes oxygen and is preferably formed using any one or more of the oxide and oxynitride described above. Specifically, the insulating layer 110b can be formed using one or both of a silicon oxide and a silicon oxynitride.

It is further preferable that a film from which oxygen is released by heating be used as the insulating layer 110b. When the insulating layer 110b releases oxygen by being heated during the manufacturing process of the transistor 100, the oxygen can be supplied to the semiconductor layer 108. Supplying oxygen from the insulating layer 110b to the semiconductor layer 108, particularly to the channel formation region of the semiconductor layer 108, can repair oxygen vacancies (V_{O}), whereby the amount of oxygen vacancies (V_{O}) can be reduced. Consequently, a transistor with favorable electrical characteristics and high reliability can be obtained.

For example, the insulating layer 110b can be supplied with oxygen when heat treatment in an atmosphere including oxygen or plasma treatment in an atmosphere including oxygen is performed. Alternatively, an oxide film may be formed by a sputtering method in an atmosphere including oxygen to supply oxygen to the top surface of the insulating layer 110b. After that, the oxide film may be removed.

Hydrogen in the semiconductor layer 108, particularly in the channel formation region, is preferably reduced as much as possible. Since hydrogen in the semiconductor layer 108 is bonded to an oxygen vacancy to form V_{O}H (a defect in which hydrogen has entered an oxygen vacancy), transistor characteristics (e.g., I_{d}-V_{g} characteristics of the transistor in the initial state or I_{d}-V_{g} characteristics in a long-term reliability test) might be degraded. Hence, a material that releases little hydrogen is preferably used as a material surrounding the semiconductor layer 108, such as a material of the insulating layer (e.g., the insulating layer 110a, the insulating layer 110b, the insulating layer 110c, or the insulating layer 106) that is in contact with the semiconductor layer 108.

The insulating layer 110b is preferably formed by a film formation method such as a sputtering method or a plasma-enhanced chemical vapor deposition (PECVD) method. In particular, a film is formed by a sputtering method as a film formation method that does not use a hydrogen gas for a film formation gas, so that a film with an extremely low hydrogen content can be formed. In that case, supply of hydrogen to the channel formation region is inhibited and the electrical characteristics of the transistor 100 can be stabilized.

Preferably, a substance easily diffuses into the insulating layer 110b. It can be said that the diffusion coefficient of a substance in the insulating layer 110b is preferably high. In particular, it is preferable that oxygen easily diffuse into the insulating layer 110b. That is, the diffusion coefficient of oxygen in the insulating layer 110b is preferably high. Oxygen included in the insulating layer 110b diffuses into the insulating layer 110b and is supplied to the semiconductor layer 108 through the interface between the insulating layer 110b and the semiconductor layer 108. The insulating layer 110b into which oxygen easily diffuses contributes to the efficient supply of oxygen included in the insulating layer 110b to the semiconductor layer 108 (channel formation region, in particular).

The diffusion coefficient of oxygen in the insulating layer 110 b at 350° C. is preferably higher than or equal to 5×10⁻¹² cm²/sec, further preferably higher than or equal to 1×10⁻¹¹ cm²/sec, further preferably higher than or equal to 5×10⁻¹¹ cm²/sec, still further preferably higher than or equal to 1×10 ⁻¹⁰ cm²/sec. Accordingly, oxygen included in the insulating layer 110 b can be efficiently supplied to the semiconductor layer 108. Since the diffusion coefficient is preferably as high as possible, the upper limit thereof is not set. The diffusion coefficient can be calculated by thermal desorption spectroscopy (TDS), for example. Secondary ion mass spectrometry (SIMS) may also be used.

The use of a material having high electrical conductivity for the semiconductor layer 108 enables the transistor to have high on-state current. However, the use of a material having high electrical conductivity facilitates the formation of oxygen vacancies (Vₒ); the increased oxygen vacancies (V_{O}) in the channel formation region shift the threshold voltage of the transistor, which might increase the drain current flowing at a gate voltage of 0 V (hereinafter, also referred to as cut-off current). For example, a shift of the threshold voltage in the negative direction might increase the cut-off current in the case of an n-channel transistor. Providing the insulating layer 110b enables oxygen supply to at least the region of the semiconductor layer 108 that is in contact with the insulating layer 110b, i.e., the channel formation region, whereby the oxygen vacancies (V_{O}) in the channel formation region can be reduced. This prevents the threshold voltage shift and allows the transistor to have both low cut-off current and high on-state current. Consequently, the semiconductor device can have both low power consumption and high performance.

In the semiconductor layer 108, the region in contact with the conductive layer 112a serves as the one of the source region and the drain region of the transistor 100, and the region in contact with the conductive layer 112b serves as the other of the source region and the drain region. The source region and the drain region have lower electric resistance than the channel formation region. In other words, the source region and the drain region have a higher carrier concentration or a higher oxygen vacancy density than the channel formation region.

The insulating layer 110a is provided between the insulating layer 110b and the conductive layer 112a. The insulating layer 110c is provided between the insulating layer 110b and the conductive layer 112b. It is preferable that the insulating layer 110a and the insulating layer 110c release a small amount of impurity (e.g., hydrogen and water) and be not easily transmits impurities. Thus, the impurities included in the insulating layer 110a and the insulating layer 110c can be prevented from diffusing into the channel formation region. Consequently, a transistor with favorable electrical characteristics and high reliability can be obtained.

For each of the insulating layer 110a and the insulating layer 110c, a film which hardly transmits oxygen is preferably used. Accordingly, oxygen included in the insulating layer 110b can be prevented from diffusing into the conductive layer 112a through the insulating layer 110a. Similarly, oxygen included in the insulating layer 110b can be prevented from diffusing into the conductive layer 112b through the insulating layer 110c. As a result, an increase in the electric resistance of the conductive layer 112a and the conductive layer 112b can be prevented. At the same time, oxygen included in the insulating layer 110b can be prevented from diffusing into the insulating layer 110a side and the insulating layer 110c side. These increase the amount of oxygen supplied to the channel formation region from the insulating layer 110b, reducing oxygen vacancies and V_{O}H in the channel formation region.

When a film that does not easily allow diffusion of oxygen is used for each of the insulating layer 110a and the insulating layer 110c, oxygen can be effectively supplied from the insulating layer 110b to the channel formation region. Note that one or both of the insulating layer 110a and the insulating layer 110c are not necessarily provided.

It is preferable that the insulating layer 110a and the insulating layer 110c each include nitrogen and be each formed using any one or more of the nitride and nitride oxide described above. For example, silicon nitride or silicon nitride oxide can be used for each of the insulating layer 110a and the insulating layer 110c. Alternatively, any one or more of oxide and oxynitride may be used for one or both of the insulating layer 110a and the insulating layer 110c. The insulating layer 110a and the insulating layer 110c can each be formed using, for example, an aluminum oxide. Note that the insulating layer 110a and the insulating layer 110c may be formed using the same material or different materials.

Note that in this specification and the like, different materials mean materials in which some or all of constituent elements are different or materials having the same constituent elements and different compositions.

For example, a thickness T110a of the insulating layer 110a can be greater than or equal to 3 nm, greater than or equal to 5 nm, greater than or equal to 10 nm, greater than or equal to 20 nm, greater than or equal to 50 nm, or greater than or equal to 70 nm and can be less than 1 μm or less than or equal to 500 nm, less than or equal to 400 nm, less than or equal to 300 nm, less than or equal to 200 nm, less than or equal to 150 nm, or less than or equal to 120 nm. The thickness T110a can be the shortest distance between the formation surface of the insulating layer 110a (the top surface of the conductive layer 112a here) and the bottom surface of the insulating layer 110b in a cross-sectional view, as shown in FIG. 29B.

If the thickness T110a of the insulating layer 110a is large, more impurities might be released from the insulating layer 110a, resulting in an increase in impurities diffusing into the channel formation region. Meanwhile, if the thickness T110a is small, oxygen included in the insulating layer 110b might diffuse into the conductive layer 112a side through the insulating layer 110a, resulting in a reduction in oxygen supplied to the channel formation region. As long as thickness T110a is set within the above-described range, the oxygen vacancies (V_{O}) and V_{O}H in the channel formation region can be reduced. Furthermore, the conductive layer 112a can be prevented from being oxidized by oxygen included in the insulating layer 110b and from having higher electric resistance.

For example, a thickness T110c of the insulating layer 110c can be greater than or equal to 3 nm, greater than or equal to 5 nm, greater than or equal to 10 nm, greater than or equal to 15 nm, or greater than or equal to 20 nm and can be less than or equal to 1 μm, less than or equal to 500 nm, less than or equal to 300 nm, less than or equal to 200 nm, less than or equal to 150 nm, less than or equal to 120 nm, or less than or equal to 100 nm. The thickness T110 c can be the shortest distance between the formation surface of the insulating layer 110c (the top surface of the insulating layer 110b here) and the bottom surface of the conductive layer 112b in a cross-sectional view, as shown in FIG. 29B.

If the thickness T110c of the insulating layer 110c is large, more impurities might be released from the insulating layer 110c, resulting in an increase in impurities diffusing into the channel formation region. Meanwhile, if the thickness T110c is small, oxygen included in the insulating layer 110b might diffuse into the conductive layer 112b side through the insulating layer 110c, resulting in a reduction in oxygen supplied to the channel formation region. As long as thickness T110c is set within the above-described range, the oxygen vacancies (V_{O}) and V_{O}H in the channel formation region can be reduced. Furthermore, the conductive layer 112b can be prevented from being oxidized by oxygen included in the insulating layer 110b and from having higher electric resistance.

In the semiconductor layer 108, at least one of the region in contact with the insulating layer 110a and the region in contact with the insulating layer 110c may be a region having lower resistance than the channel formation region (hereinafter, also referred to as a low-resistance region). In other words, the region has a higher carrier concentration or a higher oxygen vacancy density than the channel formation region. When a material that releases an impurity (e.g., water and hydrogen) is used for the insulating layer 110a, the region of the semiconductor layer 108 that is in contact with the insulating layer 110a can be a low-resistance region. In the semiconductor layer 108, the low-resistance region can be formed between the channel formation region and the region in contact with the conductive layer 112a (one of a source region and a drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be formed between the channel formation region and the region in contact with the conductive layer 112b (the other of the source region and the drain region). The low-resistance region can serve as a buffer region for relieving a drain electric field. These low-resistance regions may serve as the source region or the drain region.

The low-resistance region between the drain region and the channel formation region inhibits generation of a high electric field in the vicinity of the drain region, so that generation of hot carriers is inhibited to prevent the degradation of the transistor. For example, in the case where the conductive layer 112a serves as a drain electrode, the conductive layer 112b serves as a source electrode, and the region of the semiconductor layer 108 that is in contact with the insulating layer 110a serves as the low-resistance region, a high electric field is not easily generated in the vicinity of the drain region, and generation of hot carriers and degradation of the transistor can be inhibited. In I the case where the conductive layer 112a serves as the source electrode, the conductive layer 112b serves as the drain electrode, and the region of the semiconductor layer 108 that is in contact with the insulating layer 110c serves as the low-resistance region, a high electric field is not easily generated in the vicinity of the drain region, and generation of hot carriers and degradation of the transistor can be inhibited.

As described above, an excessive amount of impurities released from the insulating layer 110a and the insulating layer 110c might diffuse into the channel formation region. Even when a material that releases impurities is used for the insulating layer 110a and the insulating layer 110c, the amount of released impurities is preferably small.

Note that the insulating layer 110 preferably includes at least the insulating layer 110b. For example, one or both of the insulating layer 110a and the insulating layer 110c are not necessarily provided. The insulating layer 110 may have a single-layer structure or a stacked-layer structure of two, four or more layers.

There is no limitation on the top surface shapes of the opening 141 and the opening 143, and the shapes can be polygons such as a circle, an ellipse, a triangle, a tetragon (including a rectangle, a rhombus, and a square), and a pentagon; and polygons with rounded corners, for example. Note that the polygon may be a concave polygon (a polygon at least one of the interior angles of which is greater than 180°) or a convex polygon (a polygon all the interior angles of which are less than or equal to 180°). The top surface shapes of the opening 141 and the opening 143 are preferably circles as shown in FIG. 28A and the like. When the top surface shapes of the openings are circles, processing accuracy in forming the openings can be high, whereby the openings can be formed to have minute sizes. In this specification and the like, a circular shape is not necessarily a perfect circular shape.

When the opening 141 and the opening 143 are formed to have circular or substantially circular top surface shapes, the semiconductor layer 108, the insulating layer 106, and the conductive layer 104 are provided concentrically. This makes the distance between the conductive layer 104 and the semiconductor layer 108 uniform or substantially uniform, so that a gate electric field can be uniformly or substantially uniformly applied to the semiconductor layer 108.

In this specification and the like, the top surface shape of the opening 141 refers to the shape of the end portion of the top surface of the insulating layer 110 on the opening 141 side. The top surface shape of the opening 143 refers to the shape of the end portion of the bottom surface of the conductive layer 112b on the opening 143 side.

As shown in FIG. 28A and the like, the opening 141 and the opening 143 can have the same or substantially the same top surface shapes. In that case, it is preferable that the end portion of the bottom surface of the conductive layer 112b on the opening 143 side be aligned with or substantially aligned with the end portion of the top surface of the insulating layer 110 on the opening 141 side as shown in FIG. 28B, FIG. 28C, and the like. The bottom surface of the conductive layer 112b refers to the surface thereof on the insulating layer 110 side. The top surface of the insulating layer 110 refers to the surface thereof on the conductive layer 112b side.

Note that the opening 141 and the opening 143 do not necessarily have the same top surface shapes. In the case where the top surface shapes of the opening 141 and the opening 143 are circular, the opening 141 and the opening 143 may be concentrically arranged, but not necessarily concentrically arranged.

The channel length, channel width, and the like of the transistor 100 are described with reference to FIG. 29A and FIG. 29B. FIG. 29A and FIG. 29B are enlarged views of the transistor 100 shown in FIG. 28A and FIG. 28B.

In FIG. 29B, a channel length L100 of the transistor 100 is indicated by a dashed double-headed arrow. The channel length L100 of the transistor 100 corresponds to the length of the side surface of the insulating layer 110b on the opening 141 side in a cross-sectional view. In other words, the channel length L100 depends on a thickness T110b of the insulating layer 110b and an angle θ110 formed by the side surface of the insulating layer 110 b on the opening 141 side and the formation surface of the insulating layer 110b (which is the top surface of the insulating layer 110a here). Thus, the channel length L100 can be a value smaller than that of the resolution limit of a light-exposure apparatus, which enables a transistor having a minute size. Specifically, it is possible to obtain a transistor with an extremely short channel length that is difficult to obtain with the use of a conventional light-exposure apparatus for mass production of flat panel displays (the minimum line width: approximately 2 μm or approximately 1.5 μm, for example). Moreover, it is also possible to obtain a transistor with a channel length shorter than 10 nm without using an extremely expensive light-exposure apparatus used in the latest LSI technology.

The channel length L100 can be, for example, greater than or equal to 1 nm, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 60 nm, less than or equal to 50 nm, less than or equal to 40 nm, less than or equal to 30 nm, less than or equal to 20 nm, or less than or equal to 10 nm. For example, the channel length L100 can be greater than or equal to 100 nm and less than or equal to 1 μm.

When the channel length L100 is small, the transistor 100 can have high on-state current. With the use of the transistor 100, a circuit capable of high-speed operation can be manufactured. Furthermore, the area occupied by the circuit can be reduced. Thus, a semiconductor device with a small size can be obtained. The application of the semiconductor device of one embodiment of the present invention to a large display apparatus or a high-resolution display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110 b of the insulating layer 110 b and the angle θ110, the channel length L100 can be controlled. Note that in FIG. 29B, the thickness T110b of the insulating layer 110b is indicated by the dashed-dotted double-headed arrow.

The thickness T110b of the insulating layer 110b can be, for example, greater than or equal to 1 nm, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 60 nm, less than or equal to 50 nm, less than or equal to 40 nm, less than or equal to 30 nm, less than or equal to 20 nm, or less than or equal to 10 nm.

The side surface of the insulating layer 110 on the opening 141 side preferably has a vertical shape or a tapered shape. The angle θ110 is preferably less than or equal to 90°. By reducing the angle θ110, the coverage with a layer (e.g., the semiconductor layer 108) formed over the insulating layer 110 can be improved. The smaller the angle θ110 is, the larger the channel length L100 is. The larger the angle θ110 is, the smaller the channel length L100 is.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than or equal to 90°, less than or equal to 85°, or less than or equal to 80°. The angle θ110 may be less than or equal to 75°, less than or equal to 70°, less than or equal to 65°, or less than or equal to 60°.

Although FIG. 29B and the like show the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110b and the channel length L100 is difficult to control in some cases. Accordingly, it is preferable that the top surface shape of the opening 143 be the same as the top surface shape of the opening 141, or the opening 143 cover the opening 141 completely in the top view.

In FIG. 29A and FIG. 29B, a width D141 of the opening 141 is indicated by the dashed-two dotted double-headed arrow. FIG. 29A shows an example where the top surface shape of the opening 141 is a circle. In this case, the width D141 corresponds to the diameter of the circle and a channel width W100 of the transistor 100 is the length of the circumference of the circle. That is, the channel width W100 is π×D141. Accordingly, in the case where the opening 141 has a circular top surface shape, the channel width W100 of the transistor can be smaller than in the case where the opening 141 has any other shape.

Note that in the case where the opening 141 has a top surface shape other than a circular shape (e.g., a substantially circular shape or a quadrangular shape with rounded corners), the maximum width of the top surface shape is set to the width D141, for example.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels. For another example, any of the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels can be used as the diameter of the opening 141.

In the case where the opening 141 is formed by a photolithography method, the width D141 of the opening 141 is larger than or equal to the resolution limit of a light-exposure apparatus. In the case of using a conventional light-exposure apparatus for mass production of a flat panel display, the width D141 can be, for example, greater than or equal to 200 nm, greater than or equal to 300 nm, greater than or equal to 400 nm, or greater than or equal to 500 nm and less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm. Alternatively, in the case of using an extremely expensive light-exposure apparatus used in the latest LSI technology, the width D141 can be greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm, for example.

The channel length L100 of the transistor 100 is preferably shorter than at least the channel width W100 of the transistor 100. The channel length L100 of the transistor 100 is greater than or equal to 0.1 times and less than or equal to 0.99 times, preferably greater than or equal to 0.5 times and less than or equal to 0.8 times the channel width W100 of the transistor 100. This structure enables a transistor with favorable electrical characteristics and high reliability.

In the case where the channel length L100 of the transistor 100 is made short, materials for the insulating layer 110a and the insulating layer 110c are each preferably selected such that the amount of hydrogen released from the insulating layer 110a and the insulating layer 110c can be as small as possible. In the case where the materials used for the insulating layer 110a and the insulating layer 110c release even a small amount of hydrogen, their thicknesses are preferably small. For example, when the channel length L100 is less than or equal to 100 nm, the thickness T110a of the insulating layer 110a and the thickness T110c of the insulating layer 110c are each preferably greater than or equal to 1 nm, greater than or equal to 3 nm, or greater than or equal to 5 nm and less than or equal to 50 nm, less than or equal to 40 nm, less than or equal to 30 nm, less than or equal to 20 nm, less than or equal to 15 nm, or less than or equal to 10 nm. Accordingly, the amount of impurities diffusing into the channel formation region can be reduced, and the transistor can have favorable electrical characteristics and high reliability even with the short channel length L100.

Although the structure in which the region of the semiconductor layer 108 that is in contact with the insulating layer 110b serves as the channel formation region is described as an example, one embodiment of the present invention is not limited thereto. The region of the semiconductor layer 108 that is in contact with the insulating layer 110a may also serve as a channel formation region. Similarly, the region that is in contact with the insulating layer 110c may serve as the channel formation region.

Although FIG. 28B and the like show an example in which the semiconductor layer 108, the insulating layer 106, and the conductive layer 104 cover the opening 141 and the opening 143 in the transistor 100, one embodiment of the present invention is not limited thereto. A step may be formed between the insulating layer 110 and the conductive layer 112a, and the semiconductor layer 108, the insulating layer 106, and the conductive layer 104 may be provided along the step.

### Transistor 200

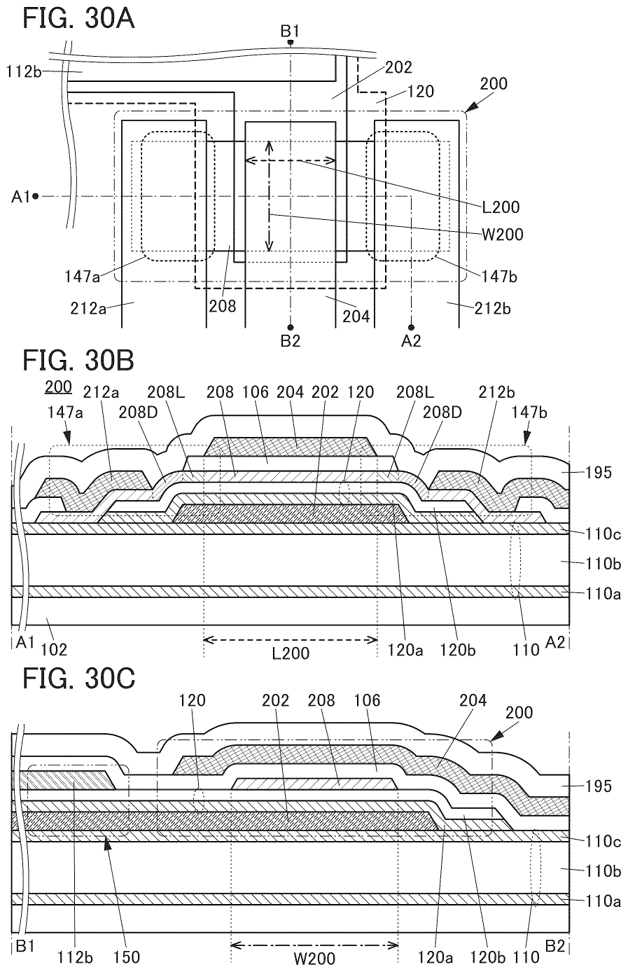

Next, the structure of the transistor 200 is described in detail with reference to FIG. 30A to FIG. 30C. FIG. 30A to FIG. 30C are enlarged views of the transistor 200 shown in FIG. 28A to FIG. 28C.

The channel length of the transistor 200 is the length of the region between the pair of regions 208D where the semiconductor layer 208 and the conductive layer 204 overlap with each other. In FIG. 30A and FIG. 30B, a channel length L200 of the transistor 200 is indicated by a dashed double-headed arrow. The channel length L200 of the transistor 200 depends on the length of the conductive layer 204 and has a value larger than or equal to that of the resolution limit of the light-exposure apparatus used for manufacturing the transistor. For example, the channel length L200 can be greater than or equal to 1.5 μm. The transistor with a long channel length can have favorable saturation.

The conductive layer 202 serving as the back gate electrode of the transistor 200 preferably extends beyond the end portion of the channel formation region. Specifically, the conductive layer 202 preferably has a portion that protrudes beyond the end portion of the conductive layer 204 in the channel length direction.

Note that for easy explanation, in this specification and the like, the portion of the semiconductor layer 208 overlapping with the conductive layer 204 is sometimes described as a channel formation region; however, a channel can be actually formed in a portion not overlapping with the conductive layer 204 and overlapping with the conductive layer 202.

The channel width of the transistor 200 is the width of the region where the semiconductor layer 208 and the conductive layer 204 overlap with each other in the direction orthogonal to the channel length direction. In FIG. 30A and FIG. 30C, a channel width W200 of the transistor 200 is indicated by a dashed-dotted double-headed arrow.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, the transistor 100 is used as the transistor required to have high on-state current and the transistor 200 is used as the transistor required to have favorable saturation, whereby the high-performance semiconductor device 10 utilizing the advantages of the transistors can be provided. Furthermore, some of the formation steps of the transistor 100 can be the same as some of the formation steps of the transistor 200. Specifically, the semiconductor layer 108 and the semiconductor layer 208 can be formed in the same step. Part of the insulating layer 106 serves as the gate insulating layer of the transistor 100 and another part of the insulating layer 106 serves as the gate insulating layer of the transistor 200. The conductive layer 104, the conductive layer 204, the conductive layer 212a, and the conductive layer 212b can be formed in the same process. This allows higher productivity and lower manufacturing cost of the semiconductor device 10.

As shown in FIG. 30A and FIG. 30C, the conductive layer 204 and the conductive layer 202 preferably extend outward from the end portion of the semiconductor layer 208 in the channel width direction of the transistor 200. In that case, as shown in FIG. 30C, the whole of the semiconductor layer 208 in the channel width direction is covered with the conductive layer 204 with the insulating layer 106 therebetween and also covered with the conductive layer 202 with the insulating layer 120 therebetween. In such a structure, the semiconductor layer 208 can be electrically surrounded by electric fields generated by a pair of gate electrodes.

In the example in FIG. 30A and FIG. 30C, there is no electrical connection between the conductive layer 204 (i.e., gate electrode) and the conductive layer 202 (i.e., back gate electrode). A constant potential may be supplied to one of the gate electrode and the back gate electrode, and a signal for driving the transistor 200 may be supplied to the other. In that case, when the transistor 200 is driven with the signal supplied to the other of the gate electrode and the back gate electrode, the potential supplied to the one of the gate electrode and the back gate electrode enables control of the threshold voltage.

The conductive layer 204 may be electrically connected to the conductive layer 202. When the same potential is supplied to the gate electrode and the back gate electrode, electric fields for inducing a channel can be effectively applied to the semiconductor layer 208, whereby the on-state current of the transistor 200 can be increased. Thus, the transistor 200 can also be miniaturized. For example, an opening reaching the conductive layer 202 is provided in the insulating layer 106 and the insulating layer 120, and the conductive layer 204 can be formed to cover the opening.

The conductive layer 202 may be electrically connected to the conductive layer 212a or the conductive layer 212b (i.e., the source electrode or the drain electrode). For example, an opening reaching the conductive layer 202 is provided in the insulating layer 120 and the conductive layer 212a or the conductive layer 212b can be formed to cover the opening.

Any of the materials usable for the insulating layer 110 can be used for the insulating layer 120 that is provided in contact with the top surface and the side surface of the conductive layer 202.

The insulating layer 120 preferably has a stacked-layer structure. FIG. 30B and the like show a structure in which the insulating layer 120 has a stacked-layer structure of an insulating layer 120a and an insulating layer 120b over the insulating layer 120a. For each of the insulating layer 120a and the insulating layer 120b, a material usable for the insulating layer 110 can be used.

For the insulating layer 120b in contact with the channel formation region of the semiconductor layer 208, a film from which oxygen is released by heating is preferably used. When the insulating layer 120b releases oxygen by being heated during the manufacturing process of the transistor 200, the oxygen can be supplied to the semiconductor layer 208, particularly to the channel formation region of the semiconductor layer 208. Oxygen included in the insulating layer 120b diffuses into the insulating layer 120b and is supplied to the semiconductor layer 208 through the interface between the insulating layer 120b and the semiconductor layer 208. Supplying oxygen from the insulating layer 120b to the semiconductor layer 208, particularly to the channel formation region, can repair oxygen vacancies (V_{O}), whereby the amount of oxygen vacancies (V_{O}) can be reduced. Consequently, a transistor with favorable electrical characteristics and high reliability can be obtained.

The diffusion coefficient of oxygen in the insulating layer 120 b at 350° C. is preferably higher than or equal to 1×10⁻¹² cm²/sec, further preferably higher than or equal to 5×10⁻¹² cm²/sec.

For the insulating layer 120b, a material usable for the insulating layer 110b can be used. The insulating layer 120b preferably includes oxygen and is preferably formed using any one or more of an oxide and an oxynitride. Specifically, for example, silicon oxide or silicon oxynitride can be used for the insulating layer 120b.

The electrical characteristics of the transistor 200 with a longer channel length are less affected by the oxygen vacancies (V^{O}) and V_{O}H in the channel formation region than those of the transistor 100 with a shorter channel length. Accordingly, the amount of oxygen supplied from the insulating layer 120b to the semiconductor layer 208 may be smaller than that of oxygen supplied from the insulating layer 110b to the semiconductor layer 108. The amount of oxygen released from the insulating layer 120b may be smaller than that of oxygen released from the insulating layer 110b.

The diffusion coefficient of a substance in the insulating layer 110b is preferably higher than that in the insulating layer 120b. In particular, the diffusion coefficient of oxygen in the insulating layer 110b is preferably higher than that in the insulating layer 120b. This allows the transistor 100 having a short channel length to have favorable electrical characteristics and high reliability.

For the insulating layer 120a in contact with the conductive layer 202, a material that does not easily allow diffusion of a metal element included in the conductive layer 202 is preferably used. This inhibits the metal element included in the conductive layer 202 from diffusing into the channel formation region of the semiconductor layer 208 through the insulating layer 120.

For the insulating layer 120a, a material usable for the insulating layer 110a and the insulating layer 110c can be used. The insulating layer 120a preferably includes nitrogen and is preferably formed using any one or more of a nitride and a nitride oxide. Specifically, for the insulating layer 120a, a silicon nitride can be suitably used, for example. Alternatively, any one or more of an oxide and an oxynitride may be used for the insulating layer 120a. For example, an aluminum oxide can be used for the insulating layer 120a. For the insulating layer 120a, the insulating layer 110a, and the insulating layer 110c, the same material or different materials may be used.

The amount of impurities (e.g., water and hydrogen) released from the insulating layer 120a itself is preferably small. In that case, an impurity included in the insulating layer 120a can be inhibited from diffusing into the channel formation region of the semiconductor layer 208 through the insulating layer 120b, whereby the transistor can have excellent electrical characteristics and high reliability.

Although the insulating layer 120 has a two-layer structure here, one embodiment of the present invention is not limited thereto. The insulating layer 120 may have a stacked-layer structure of three or more layers or a single-layer structure.

Preferably, the insulating layer 120 is provided in a region in contact with at least the channel formation region in the semiconductor layer 208 to cover the top surface and the side surface of the conductive layer 202. FIG. 30B and the like show the semiconductor layer 208 that includes a portion protruding beyond the end portion of the insulating layer 120. The semiconductor layer 208 includes a region in contact with the side surface of the insulating layer 120. Part of the end portion of the semiconductor layer 208 is in contact with the top surface of the insulating layer 120 and another part of the end portion is in contact with the top surface of the insulating layer 110. It can be said that part of the bottom surface of the semiconductor layer 208 is in contact with the top surface of the insulating layer 120 and another part of the bottom surface is in contact with the top surface of the insulating layer 110. Alternatively, the insulating layer 120 may be provided in a region where the semiconductor layer 208 is provided such that the bottom surface of the semiconductor layer 208 is entirely in contact with the top surface of the insulating layer 120.

Although the thickness of the semiconductor layer 208 is uniform without varying from place to place in the example shown in FIG. 30B or the like, one embodiment of the present invention is not limited to this example. The thickness of the semiconductor layer 208 in the region overlapping with the insulating layer 106 may be different from the thickness of the semiconductor layer 208 in the region not overlapping with the insulating layer 106. For example, when the opening 147a and the opening 147b are formed, the semiconductor layer 208 is partly removed, so that the semiconductor layer 208 in the region not overlapping with the insulating layer 106 sometimes has a smaller thickness than the semiconductor layer 208 in the region overlapping with the insulating layer 106. Alternatively, the semiconductor layer 208 in the region overlapping with any of the insulating layer 106, the conductive layer 212a, and the conductive layer 212b may differ in thickness from the semiconductor layer 208 in the region not overlapping with any of them. For example, when the conductive layer 212a and the conductive layer 212b are formed, the semiconductor layer 208 is partly removed, so that the semiconductor layer 208 in the region not overlapping with any of the insulating layer 106, the conductive layer 212a, and the conductive layer 212b sometimes has a smaller thickness than the semiconductor layer 208 in the region overlapping with any of them. Alternatively, there may be a difference in the thickness of the semiconductor layer 208 among the region overlapping with the insulating layer 106, the region overlapping with any of the insulating layer 106, the conductive layer 212a, and the conductive layer 212b, and the region not overlapping with any of them.

In the semiconductor layer 208, the region 208D has lower electric resistance than the channel formation region. It can be said that the region 208D has a higher carrier concentration, a higher oxygen vacancy density, or a higher impurity concentration than the channel formation region.

The region 208L is a region whose electric resistance is substantially equal to or higher than that of the channel formation region. The region 208L can be referred to as a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. The region 208L is a region whose electric resistance is substantially equal to or higher than that of the region 208D. The region 208L can be referred to as a region whose carrier concentration is substantially equal to or lower than the carrier concentration of the region 208D, a region whose oxygen vacancy density is substantially equal to or lower than the oxygen vacancy density of the region 208D, or a region whose impurity concentration is substantially equal to or lower than the impurity concentration of the region 208D.

The region 208L serves as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can serve as an LDD (Lightly Doped Drain) region. The region 208L serving as the LDD region is provided between the channel formation region and the region 208D, whereby the transistor 200 can have high drain breakdown voltage.

The carrier concentration in the semiconductor layer 208 preferably has a distribution such that the concentration is lowest in the channel formation region and increases in the order of the region 208L and the region 208D. Providing the region 208L between the channel formation region and the region 208D can keep the carrier concentration of the channel formation region extremely low even when an impurity such as hydrogen diffuses from the region 208D during the manufacturing process, for example.

Note that the carrier concentration in the region 208L is not necessarily uniform and sometimes has a gradient such that the carrier concentration decreases from the region 208D side toward the channel formation region. For example, one or both of the hydrogen concentration and the oxygen vacancy (V_{O}) concentration in the region 208L may have a gradient such that the concentration decreases from the region 208D side to the channel formation region side.

When the region 208L and the region 208D are formed by adding an impurity element to the semiconductor layer 208, the impurity element may be supplied to the semiconductor layer 108 through the insulating layer 106 with use of the conductive layer 104 as a mask. In that case, a region 108L is formed in the region of the semiconductor layer 108 that does not overlap with the conductive layer 104. Note that in the transistor 100, the region of the semiconductor layer 108 that is in contact with the conductive layer 112b serves as a source region or a drain region. The region 108L is formed in part of the source region or the drain region. Note that the concentration of the impurity element in the region 108L may be different from that in the region 208L. The region 108L is not necessarily formed. For example, in the case where the conductive layer 104 extends to cover the end portion of the semiconductor layer 108, the conductive layer 104 masks the whole semiconductor layer 108 to preclude the supply of the impurity element to the semiconductor layer 108, and the region 108L is not formed.

As shown in FIG. 30A and FIG. 30B, part of the end portions of the conductive layer 212a and the conductive layer 212b are preferably positioned in the opening 147a and the opening 147b, respectively. In other words, part of the end portions of the conductive layer 212a and the conductive layer 212b are preferably in contact with the semiconductor layer 208 in the opening 147a and the opening 147b, respectively. Accordingly, the region in contact with the conductive layer 212a can be adjacent to one of the pair of regions 208D and the region in contact with the conductive layer 212b can be adjacent to the other of the pair of regions 208D.

There is no limitation on the top surface shapes of the opening 147a and the opening 147b. The top surface shapes of the opening 147a and the opening 147b can be any of the shapes that can be used for the opening 141 and the opening 143. The top surface shapes of the opening 147a and the opening 147b are different from the top surface shapes of the opening 141 and the opening 143 and are quadrangles with rounded corners in the structure shown in FIG. 30A and the like; however, one embodiment of the present invention is not limited thereto. The top surface shapes of the opening 147a and the opening 147b may be the same as those of the opening 141 and the opening 143.

Although the conductive layer 212a and the conductive layer 212b are formed in the same process as the conductive layer 204 here, one embodiment of the present invention is not limited thereto. The conductive layer 212a and the conductive layer 212b may be formed in a step different from that for the conductive layer 204. For example, the conductive layer 104 and the conductive layer 204 are formed over the insulating layer 106 and an impurity element is supplied to the semiconductor layer 208 with the use of the conductive layer 204 as a mask, whereby the source region and the drain region are formed. The insulating layer 195 is formed over the conductive layer 104 and the conductive layer 204, an opening reaching the source region and an opening reaching the drain region are formed in the insulating layer 106 and the insulating layer 195, and the conductive layer 212a and the conductive layer 212b can be formed to cover the openings.

### Semiconductor Layer 108 and Semiconductor Layer 208

Metal oxides usable for the semiconductor layer 108 and the semiconductor layer 208 are specifically described. Examples of the metal oxide include an indium oxide, a gallium oxide, and a zinc oxide. The metal oxide preferably includes at least indium or zinc. The metal oxide preferably includes two or three kinds selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more kinds of the above elements, further preferably one or more kinds selected from aluminum, gallium, tin, and yttrium, and still further preferably one or more kinds of gallium and tin. In this specification and the like, a metal element and a metalloid element may be collectively referred to as a “metal element”, and a “metal element” in this specification and the like may refer to a metalloid element.

For example, for each of the semiconductor layer 108 and the semiconductor layer 208, an indium oxide (In oxide), an indium zinc oxide (In—Zn oxide), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (In—Ga—Sn oxide), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, an indium tin oxide including silicon (also referred to as ITSO), a gallium tin oxide (Ga—Sn oxide), an aluminum tin oxide (Al—Sn oxide), or the like can be used. Note that a material that does not include Zn, typified by an indium oxide or the like, has high compatibility with a Si process, and thus is suitable. Meanwhile, a material including Zn can increase the crystallinity, and thus is suitable.

When the proportion of the number of indium atoms in the total number of atoms of all the metal elements included in the metal oxide is increased, the field-effect mobility of the transistor can be increased. In addition, the transistor can have high on-state current.

Note that the metal oxide may include, instead of indium or in addition to indium, one or more kinds of metal elements with larger period numbers. The larger the overlap between orbits of metal elements is, the more likely it is that the metal oxide will have high carrier conductivity. Thus, a transistor including a metal element with a large period number in the periodic table can have high field-effect mobility in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds selected from nonmetallic elements. By including a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the element M atoms in the total number of atoms of all the metal elements included in the metal oxide, oxygen vacancies (V_{O}) can be inhibited from being formed in the metal oxide. Thus, generation of carriers due to oxygen vacancies (V_{O}) is inhibited, which makes the off-state current of the transistor low. Furthermore, a change in electrical characteristics of the transistor can be inhibited, and the reliability of the transistor can be improved.

The compositions of the metal oxides used for the semiconductor layer 108 and the semiconductor layer 208 affect the electrical characteristics and reliability of the transistors. Thus, by changing the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements in such an In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the vicinity thereof. Note that a composition in the neighborhood includes the range of ±30 % of an intended atomic ratio. By increasing the proportion of the number of indium atoms in the metal oxide, the transistor can have increased on-state current, improved field-effect mobility, or the like.

The atomic ratio of In may be less than the atomic ratio of the element M in the In-M-Zn oxide. Examples of the atomic ratio of the metal elements of such an In-M-Zn oxide include In:M:Zn=1:3:2, In:M:Zn=1:3:3, and In:M:Zn=1:3:4 and a composition in the vicinity thereof. By increasing the proportion of the number of M atoms in the metal oxide, generation of oxygen vacancies (V_{O}) can be suppressed.

In the case where a plurality of metal elements are included as the element M, the sum of the proportions of the numbers of atoms of these metal elements can be used as the proportion of the number of element M atoms.

In this specification and the like, the proportion of the number of indium atoms in the total number of atoms of all the metal elements included is sometimes referred to as indium content percentage. The same applies to other metal elements.

The use of a material with a high content percentage of indium for the semiconductor layer 108 and the semiconductor layer 208 enables an increase in the on-state current or field-effect mobility of the transistors and the like. Furthermore, the element M included in the semiconductor layer can inhibit generation of oxygen vacancies (V_{O}). The content percentage of the element M (the proportion of the number of atoms of the element M in the total number of atoms of all the metal elements included) is preferably higher than or equal to 0.1 % and lower than or equal to 3 %, further preferably higher than or equal to 0.1 % and lower than or equal to 2 %. Accordingly, a transistor with favorable electrical characteristics can be provided. For example, a metal oxide with In:M:Zn of 40:1:10 or the vicinity thereof is preferably used. The element M is preferably one or more kinds of the above elements, and further preferably one or more kinds selected from aluminum, gallium, tin, and yttrium. Specifically, a metal oxide with In:Sn:Zn of 40:1:10 or the vicinity thereof can be used. Alternatively, a metal oxide with In:Al:Zn of 40:1:10 or the vicinity thereof can be used.

Here, in the case where a metal oxide having a polycrystalline structure is used for the semiconductor layer 108 and the semiconductor layer 208, the grain boundary becomes a recombination center and captures carriers and thus might reduce the on-state current of the transistor. In the case where a metal oxide with a composition that tends to form a polycrystalline structure is used, the metal oxide preferably includes an element that hinders crystallization. For example, indium tin oxide including silicon (ITSO) is less likely to form a polycrystalline structure than indium tin oxide (ITO) and can be used for the semiconductor layer 108 and the semiconductor layer 208. In the case where ITSO is used, the content percentage of silicon (the proportion of the number of silicon atoms in the total number of atoms of all the metal elements included) is preferably higher than or equal to 1 % and lower than or equal to 20 %, further preferably higher than or equal to 3 % and lower than or equal to 20 %, further preferably higher than or equal to 3 % and lower than or equal to 15 %, still further preferably higher than or equal to 5 % and lower than or equal to 15 %. Specifically, a metal oxide with In:Sn:Si of 45:5:4 or 95:5:8 or the vicinity thereof can be used.

For an analysis of the composition of the semiconductor layer 108 and the semiconductor layer 208, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50 % of that of the sputtering target.

The semiconductor layer 108 and the semiconductor layer 208 may each have a stacked-layer structure including two or more metal oxide layers. The two or more metal oxide layers included in each of the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in each of the semiconductor layer 108 and the semiconductor layer 208 may have different compositions. For example, a stacked-layer structure of a first metal oxide layer having In:M:Zn=1:3:4 [atomic ratio] or a composition in the neighborhood thereof and a second metal oxide layer that is provided over the first metal oxide layer and has In:M:Zn=1:1:1 [atomic ratio] or a composition in the neighborhood thereof can be suitably used. In particular, gallium, aluminum, or tin is preferably used as the element M. The elements M in the first metal oxide layer and the second metal oxide layer may be the same or different from each other. For example, the first metal oxide layer and the second metal oxide layer may be IGZO layers having different compositions.

For another example, a stacked-layer structure of the first metal oxide layer having In:Zn=4:1 [atomic ratio] or a composition in the neighborhood thereof and the second metal oxide layer having In:M:Zn=1:1:1 [atomic ratio] or a composition in the neighborhood thereof and being formed over the first metal oxide layer can be favorably employed.

A stacked-layer structure of any one selected from an indium oxide, an indium gallium oxide, and an IGZO and any one selected from an IAZO, an IAGZO, and an ITZO (registered trademark) may be employed, for example.

Note that when the first metal oxide layer including a first metal oxide and the second metal oxide layer including a second metal oxide form a stacked-layer structure and the first metal oxide and the second metal oxide have the same or substantially the same compositions, the boundary (interface) between the first metal oxide layer and the second metal oxide layer is difficult to be clearly observed in some cases.

It is preferable that the semiconductor layer 108 and the semiconductor layer 208 each include a metal oxide having crystallinity. Examples of the structure of a metal oxide having crystallinity include a CAAC (c-axis aligned crystal) structure, a polycrystalline structure, and a nano-crystal (nc) structure. By using a metal oxide layer having crystallinity, the density of defect states in the semiconductor layer 108 and the semiconductor layer 208 can be reduced, which enables the semiconductor device to have high reliability.

The use of a metal oxide having high crystallinity in a channel formation region can reduce the density of defect states in the channel formation region. By contrast, the use of a metal oxide having low crystallinity enables a transistor to flow a large amount of current.

In the case where the metal oxide is formed by a sputtering method, the crystallinity of the formed metal oxide can be increased as the substrate temperature at the time of formation is higher. For example, the substrate temperature at the time of formation can be adjusted by the temperature of the stage on which the substrate is placed. As the proportion of the flow rate of an oxygen gas to the total flow rate of the film formation gas used for formation (hereinafter also referred to as the oxygen flow rate ratio) or the oxygen partial pressure in a processing chamber is higher, the metal oxide can be formed to have higher crystallinity.

The crystallinity of the semiconductor layer 108 and the semiconductor layer 208 can be analyzed with X-ray diffraction (XRD) pattern, a transmission electron microscope (TEM) image, electron diffraction (ED) pattern, or the like, for example. Alternatively, these methods may be combined for the analysis.

In the case where a metal oxide is used for each of the semiconductor layer 108 and the semiconductor layer 208, the amount of V_{O}H in the channel formation region is preferably reduced as much as possible so that each of the semiconductor layer 108 and the semiconductor layer 208 becomes a highly purified intrinsic or substantially highly purified intrinsic semiconductor layer. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair oxygen vacancies (V_{O}). When a metal oxide in which impurities such as V_{O}H are sufficiently reduced is used for a channel formation region of a transistor, stable electrical characteristics can be given. Supplying oxygen to a metal oxide to repair oxygen vacancies (V_{O}) is sometimes referred to as oxygen adding treatment.

When a metal oxide is used for each of the semiconductor layer 108 and the semiconductor layer 208, the carrier concentration of the channel formation region is preferably lower than or equal to 1×10⁻¹⁸ cm⁻³, further preferably lower than 1×10⁻¹⁷ cm⁻³, still further preferably lower than 1×10 ¹⁶ cm⁻³, yet still further preferably lower than 1×10 ¹³ cm⁻³, yet still further preferably lower than 1×10 ¹² cm⁻³. Note that the lower limit of the carrier concentration of the channel formation region is not particularly limited and can be, for example, 1×10⁻-9 cm⁻³.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be used for a pixel circuit of an X-ray flat panel detector. Moreover, an OS transistor can be used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered material serving as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that serves as a semiconductor and has high two-dimensional electrical conductivity is used for a channel formation region, a transistor having high on-state current can be provided.

Examples of the layered material include graphene, silicene, and chalcogenide. Chalcogenide is a compound including chalcogen (an element belonging to Group 16). Examples of chalcogenide include transition metal chalcogenide and chalcogenide of Group 13 elements. Specific examples of the transition metal chalcogenide which can be used for the channel formation region of a transistor include a molybdenum sulfide (typically MoS₂), a molybdenum selenide (typically MoSe₂), a molybdenum telluride (typically MoTe₂), a tungsten sulfide (typically WS₂), a tungsten selenide (typically WSe₂), a tungsten telluride (typically WTe₂), a hafnium sulfide (typically HfS₂), a hafnium selenide (typically HfSe₂), a zirconium sulfide (typically ZrS₂), and a zirconium selenide (typically ZrSe₂).

### Conductive Layer 112a, Conductive Layer 112b, Conductive Layer 104, Conductive Layer 204, Conductive Layer 212a, Conductive Layer 212b, and Conductive Layer 202

The conductive layer 112a, the conductive layer 112b, the conductive layer 104, the conductive layer 204, the conductive layer 212a, the conductive layer 212b, and the conductive layer 202 may each have a single-layer structure or a stacked-layer structure of two or more layers. The conductive layer 112a, the conductive layer 112b, the conductive layer 104, the conductive layer 204, the conductive layer 212a, the conductive layer 212b, and the conductive layer 202 can each be formed using, for example, one or more of chromium, copper, aluminum, gold, silver, zinc, tantalum, titanium, tungsten, manganese, nickel, iron, cobalt, molybdenum, and niobium, or an alloy including one or more of these metals as its components. For the conductive layer 112a, the conductive layer 112b, the conductive layer 104, the conductive layer 204, the conductive layer 212a, the conductive layer 212b, and the conductive layer 202, a conductive material with low resistance that includes one or more of copper, silver, gold, and aluminum can be used. Copper or aluminum is particularly preferable because of its high mass-productivity.

For the conductive layer 112a, the conductive layer 112b, the conductive layer 104, the conductive layer 204, the conductive layer 212a, the conductive layer 212b, and the conductive layer 202, a conductive metal oxide (also referred to as an oxide conductor) can be used. Examples of an oxide conductor (OC) include an indium oxide, a zinc oxide, an In—Sn oxide (ITO), an In—Zn oxide, an In—W oxide, an In—W—Zn oxide, an In—Ti oxide, an In—Ti—Sn oxide, an In—Sn—Si oxide (also referred to as ITO including silicon or ITSO), a zinc oxide to which gallium is added, and an In—Ga—Zn oxide. A conductive oxide including indium has high conductivity, and thus is particularly preferable.

When an oxygen vacancy (V_{O}) is formed in a metal oxide having semiconductor characteristics and hydrogen is added to the oxygen vacancy (V_{O}), a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 104, the conductive layer 204, the conductive layer 212a, the conductive layer 212b, and the conductive layer 202 may have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 204, the conductive layer 212a, the conductive layer 212b, and the conductive layer 202. The use of a Cu—X alloy film enables the manufacturing cost to be reduced because a wet etching method can be used in the processing.

Note that the conductive layer 112a, the conductive layer 112b, the conductive layer 104, the conductive layer 204, the conductive layer 212a, the conductive layer 212b, and the conductive layer 202 may be formed using the same material or different materials.

Each of the conductive layer 112a and the conductive layer 112b has a region that is in contact with the semiconductor layer 108. In the case where the semiconductor layer 108 is formed using a metal oxide, when the conductive layer 112a or the conductive layer 112b is formed using a metal that is likely to be oxidized (e.g., aluminum), an insulating oxide (e.g., an aluminum oxide) is formed between the conductive layer 112a and the semiconductor layer 108 and between the conductive layer 112b and the semiconductor layer 108, which might prevent electrical continuity between the conductive layer 112a and the semiconductor layer 108 and between the conductive layer 112b and the semiconductor layer 108. Thus, a conductive material that is less likely to be oxidized, a conductive material that maintains low electric resistance even after being oxidized, or an oxide conductive material is preferably used for the conductive layer 112a and the conductive layer 112b.

For the conductive layer 112a and the conductive layer 112b, for example, titanium, a tantalum nitride, a titanium nitride, a nitride including titanium and aluminum, a nitride including tantalum and aluminum, ruthenium, a ruthenium oxide, a ruthenium nitride, an oxide including strontium and ruthenium, or an oxide including lanthanum and nickel is preferably used. These materials are preferable because they are conductive materials that are less likely to be oxidized or materials that maintain low electric resistance even when being oxidized. In the case where the conductive layer 112a has a stacked-layer structure, at least the layer thereof that is in contact with the semiconductor layer 108 is preferably formed using a conductive material that is less likely to be oxidized.

The above-described oxide conductor can be used for each of the conductive layer 112a and the conductive layer 112b. Specifically, a conductive oxide such as an indium oxide, a zinc oxide, an ITO, an In—Zn oxide, an In—W oxide, an In—W—Zn oxide, an In—Ti oxide, an In—Ti—Sn oxide, an In—Sn oxide including silicon, or a zinc oxide to which gallium is added can be used.

For the conductive layer 112a and the conductive layer 112b, a nitride conductor may be used. Examples of the nitride conductor include a tantalum nitride and a titanium nitride.

In the capacitor 150, the conductive layer 112b is provided over the insulating layer 120b. As described above, a conductive material that is less likely to be oxidized, a conductive material that maintains low electric resistance even after being oxidized, or an oxide conductive material is preferably used for the conductive layer 112b. The amount of oxygen released from the insulating layer 120b is smaller than that of oxygen released from the insulating layer 110b. Accordingly, oxidization of the conductive layer 112b including the region in contact with the insulating layer 120b to increase the electric resistance of the conductive layer 112b is less likely to occur.

The conductive layer 112a, the conductive layer 112b, and the conductive layer 104 may each have a stacked-layer structure. For example, the conductive layer 112a may have a two-layer structure. Specifically, for example, the conductive layer 112a may have a stacked-layer structure of a conductive layer 112a_1 (not shown) and a conductive layer 112a_2 (not shown) over the conductive layer 112a_1.

A conductive material that is less likely to be oxidized, a conductive material that maintains low electric resistance even after being oxidized, or an oxide conductive material is preferably used for the conductive layer 112a_2 including a region in contact with the semiconductor layer 108. The description of the conductive layer 112a can be referred to for the material usable for the conductive layer 112a_2.

The conductive layer 112a_1 does not have a region in contact with the semiconductor layer 108 and there is no limitation on the material. For the conductive layer 112a_1, a material having lower electrical resistivity than the conductive layer 112a_2 is preferably used, for example. Thus, electric resistance of the conductive layer 112a can be reduced. For example, an In—Sn—Si oxide (ITSO) can be used for the conductive layer 112a_2, and copper or tungsten can be used for the conductive layer 112a_1.

The thicknesses of the conductive layer 112a_1 and the thicknesses of the conductive layer 112a_2 may be the same, substantially the same, or different. For example, the conductive layer 112a_1 may include a material having lower electrical resistivity and have a larger thickness than the conductive layer 112a_2, whereby the conductive layer 112a_1 may have larger thickness than the conductive layer 112a_2. Thus, electric resistance of the conductive layer 112a can be reduced.

The end portion of the conductive layer 112a_1 and the end portion of the conductive layer 112a_2 may be aligned or substantially aligned with each other or are not necessarily aligned with each other. For instance, the conductive layer 112a_2 can be provided to cover the conductive layer 112a_1. That is, the conductive layer 112a_2 is in contact with the top surface and the side surface of the conductive layer 112a_1. It can also be said that the conductive layer 112a_2 includes a portion protruding beyond the end portion of the conductive layer 112a_1.

The structure of the conductive layer 112a described above can be applied to other structure examples.

### Insulating Layer 106

The insulating layer 106 may have a single-layer structure or a stacked-layer structure of two or more layers. The insulating layer 106 preferably includes one or more inorganic insulating films. Examples of a material usable for the inorganic insulating film include an oxide, a nitride, an oxynitride, and a nitride oxide. For the insulating layer 106, a material usable for the insulating layer 110 can be used.

The insulating layer 106 includes a region that is in contact with the semiconductor layer 108 and a region that is in contact with the semiconductor layer 208. In the case where the semiconductor layer 108 and the semiconductor layer 208 are formed using a metal oxide, at least the film that is included in the insulating layer 106 and in contact with the semiconductor layer 108 and the semiconductor layer 208 is preferably formed using any of the above-described oxide and oxynitride. A film from which oxygen is released by heating is further preferably used as the insulating layer 106.

Specifically, in the case where the insulating layer 106 has a single-layer structure, the insulating layer 106 is preferably formed using an oxide or an oxynitride. Specifically, for the insulating layer 106, silicon oxide or silicon oxynitride can be used.

In the case of the insulating layer 106 having a stacked-layer structure, preferably, an oxide or an oxynitride is included in the insulating film in contact with the semiconductor layer 108 and the semiconductor layer 208 while a nitride or a nitride oxide is included in the insulating film in contact with the conductive layer 104 and the conductive layer 204. As the oxide or the oxynitride, for example, a silicon oxide or a silicon oxynitride can be used. As the nitride or the nitride oxide, a silicon nitride or a silicon nitride oxide can be used.

Silicon nitride and silicon nitride oxide can be used for the insulating layer 106 because the silicon nitride and the silicon nitride oxide release fewer impurities (e.g., water and hydrogen) and are less likely to transmit oxygen and hydrogen. Diffusion of impurities from the insulating layer 106 to the semiconductor layer 108 and the semiconductor layer 208 is inhibited, whereby the transistors can have favorable electrical characteristics and high reliability.

A miniaturized transistor including a thin gate insulating layer may have high gate leakage current. When a material having high relative permittivity (also referred to as a high-k material) is used for the gate insulating layer, the voltage at the time of operation of the transistor can be reduced while the physical thickness is maintained. Examples of the high-k material usable for the insulating layer 106 include a gallium oxide, a hafnium oxide, a zirconium oxide, an oxide including aluminum and hafnium, an oxynitride including aluminum and hafnium, an oxide including silicon and hafnium, an oxynitride including silicon and hafnium, and a nitride including silicon and hafnium.

### Insulating Layer 195

The insulating layer 195 serving as a protective layer of the transistor 100, the transistor 200, and the capacitor 150 is preferably formed using a material that does not easily allow diffusion of impurities. Providing the insulating layer 195 can effectively inhibit diffusion of impurities into the transistors from the outside and increase the reliability of the semiconductor device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be used for the insulating layer 195. More specifically, one or more of a silicon nitride, a silicon nitride oxide, a silicon oxynitride, an aluminum oxide, an aluminum oxynitride, an aluminum nitride, a hafnium oxide, and a hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### Substrate 102

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate including a material such as silicon germanium, an SOI substrate, a glass substrate, a quartz substrate, a sapphire substrate, a ceramic substrate, or an organic resin substrate may be used as the substrate 102. The substrate 102 may be provided with a semiconductor element. The shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100, for example. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

In one embodiment of the present invention, for example, in the semiconductor device 60 described in Embodiment 1, a vertical transistor such as the transistor 100 is preferably used as at least one of the transistors included in the semiconductor device 60. Note that the transistor 200 may be used as each of the driving transistors (the transistor M11 and the transistor M18) and each of the load transistors (the transistor M12 and the transistor M19), and the capacitor 150 may be used as the capacitor C11, for example.

According to one embodiment of the present invention, a vertical transistor such as the transistor 100 is preferably used as any of the transistor M1, the transistor M3 to the transistor M6 in the semiconductor device 20A described in Embodiment 1, for example. Note that the transistor 200 may be used as the transistor M2 and the capacitor 150 may be used as each of the capacitor C1 and the capacitor C2, for example.

### Structure Example 2

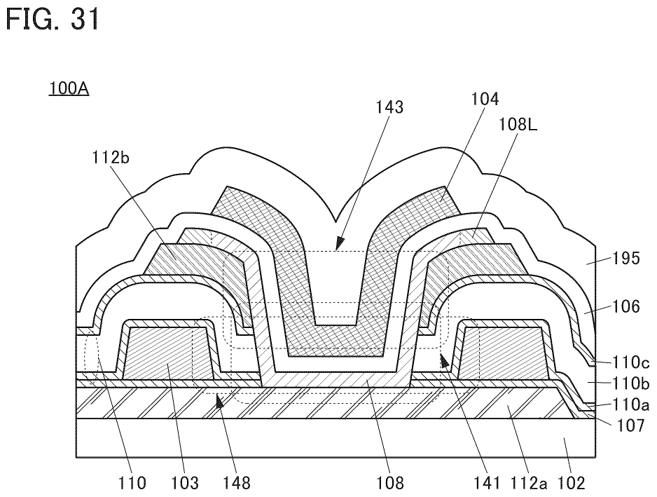

FIG. 31 is a cross-sectional view of a transistor 100A that can be used in the semiconductor device of one embodiment of the present invention. The transistor 100A is different from the transistor 100 shown in FIG. 28B and the like mainly in including a back gate. Note that the above description of the transistor 100 can be referred to; thus, the detailed description thereof is omitted.

The transistor 100A includes the conductive layer 112a, a conductive layer 103, an insulating layer 107, the insulating layer 110, the semiconductor layer 108, the conductive layer 112b, the insulating layer 106, and the conductive layer 104. The layers forming the transistor 100A may each have a single-layer structure or a stacked-layer structure.

The conductive layer 112a is provided over the substrate 102. The conductive layer 112a serves as one of a source electrode and a drain electrode of the transistor 100A.

The insulating layer 107 is positioned over the conductive layer 112a. The insulating layer 107 is provided so as to cover the top surface and the side surface of the conductive layer 112a.

The conductive layer 103 is positioned over the insulating layer 107. The conductive layer 112a and the conductive layer 103 are electrically insulated from each other by the insulating layer 107. In the conductive layer 103, an opening 148 reaching the insulating layer 107 is provided in a region overlapping with the conductive layer 112a.

The insulating layer 110 is provided over the insulating layer 107 and the conductive layer 103. The insulating layer 110 is provided so as to cover the top surface and the side surface of the conductive layer 103 and the top surface of the insulating layer 107.

The insulating layer 110 preferably has a stacked-layer structure. FIG. 31 shows an example in which the insulating layer 110 has a stacked-layer structure of the insulating layer 110a, the insulating layer 110b over the insulating layer 110a, and the insulating layer 110c over the insulating layer 110b.

The insulating layer 110a is positioned over the insulating layer 107 and the conductive layer 103. The insulating layer 110a is provided to cover the top surface and the side surface of the conductive layer 103. In addition, the insulating layer 110a is provided to cover part of the opening 148. The insulating layer 110a is in contact with the insulating layer 107 through the opening 148.

The insulating layer 110b is provided over the insulating layer 110a, and the insulating layer 110c is provided over the insulating layer 110b. The opening 141 reaching the conductive layer 112a is provided in the insulating layer 107 and the insulating layer 110.

The conductive layer 112b is positioned over the insulating layer 110c. The opening 143 overlapping with the opening 141 is provided in the conductive layer 112b. The conductive layer 112b serves as the other of the source electrode and the drain electrode of the transistor 100A. The conductive layer 112b includes a region overlapping with the conductive layer 112a with the insulating layer 107 and the insulating layer 110 therebetween.

In this specification and the like, the top surface shape of the opening 148 refers to the shape of the end portion of the top surface or the bottom surface of the conductive layer 103 on the opening 148 side. Note that there is no limitation on the top surface shape of the opening 148 as those of the opening 141 and the opening 143.

When the top surface shape of each of the opening 141 and the opening 148 is circular, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

The semiconductor layer 108 is in contact with the top surface of the conductive layer 112a, the side surface of the insulating layer 107, the side surface of the insulating layer 110, and the top surface and the side surface of the conductive layer 112b. The semiconductor layer 108 is provided to cover the opening 141 and the opening 143. The semiconductor layer 108 is provided in contact with the side surfaces of the insulating layer 107 and the insulating layer 110 on the opening 141 side and an end portion of the conductive layer 112b on the opening 143 side (which can also be referred to as part of the top surface of the conductive layer 112b and the side surface of the conductive layer 112b on the opening 143 side). The semiconductor layer 108 is in contact with the conductive layer 112a through the opening 141 and the opening 143.

Although an example where the end portion of the semiconductor layer 108 is in contact with the top surface of the conductive layer 112b is shown in FIG. 31, one embodiment of the present invention is not limited to this example. The semiconductor layer 108 may cover the end portion of the conductive layer 112b, and the end portion of the semiconductor layer 108 may be in contact with the top surface of the insulating layer 110c.

The insulating layer 106 is positioned over the insulating layer 110c, the semiconductor layer 108, and the conductive layer 112b. The insulating layer 106 is provided to cover the opening 141 and the opening 143 through the semiconductor layer 108. Part of the insulating layer 106 serves as the gate insulating layer of the transistor 100A.

The conductive layer 104 is positioned over the insulating layer 106. The conductive layer 104 overlaps with the semiconductor layer 108 with the insulating layer 106 therebetween. The conductive layer 104 serves as a gate electrode of the transistor.

In the transistor 100A, the semiconductor layer 108 has a region overlapping with the conductive layer 104 with the insulating layer 106 therebetween and overlapping with the conductive layer 103 with part of the insulating layer 110 (specifically, the insulating layer 110a and the insulating layer 110b) therebetween. In other words, the region of the semiconductor layer 108 is sandwiched between the conductive layer 104 and the conductive layer 103 with the insulating layer 106 provided between the region and the conductive layer 104 and with part (e.g., the insulating layer 110a and the insulating layer 110b) of the insulating layer 110 provided between the region and the conductive layer 103.

The conductive layer 103 serves as a back gate electrode of the transistor 100A. Part of the insulating layer 110 serves as a back gate insulating layer of the transistor 100A.

Providing the back gate electrode for the transistor 100A enables the potential on the back channel side of the semiconductor layer 108 to be fixed, so that the saturation of the transistor 100A can be improved.

Since the transistor 100A includes the back gate electrode, the potential on the back channel side of the semiconductor layer 108 can be fixed and a shift of the threshold voltage can be inhibited. A shift in the threshold voltage of the transistor might increase the drain current flowing at a gate voltage of 0 V (hereinafter, also referred to as cut-off current). When the threshold voltage shift of the transistor 100A is inhibited, the cut-off current can be reduced in the transistor. Note that the low cut-off current is sometimes referred to as normally-off.

Although FIG. 31 shows an example in which the semiconductor layer 108, the insulating layer 106, and the conductive layer 104 cover the opening 141 and the opening 143, one embodiment of the present invention is not limited thereto. A step may be formed between the conductive layer 112a and each of the insulating layer 107, the insulating layer 110, and the conductive layer 112b, and the semiconductor layer 108, the insulating layer 106, and the conductive layer 104 may be provided along the step.

### Structure Example 3

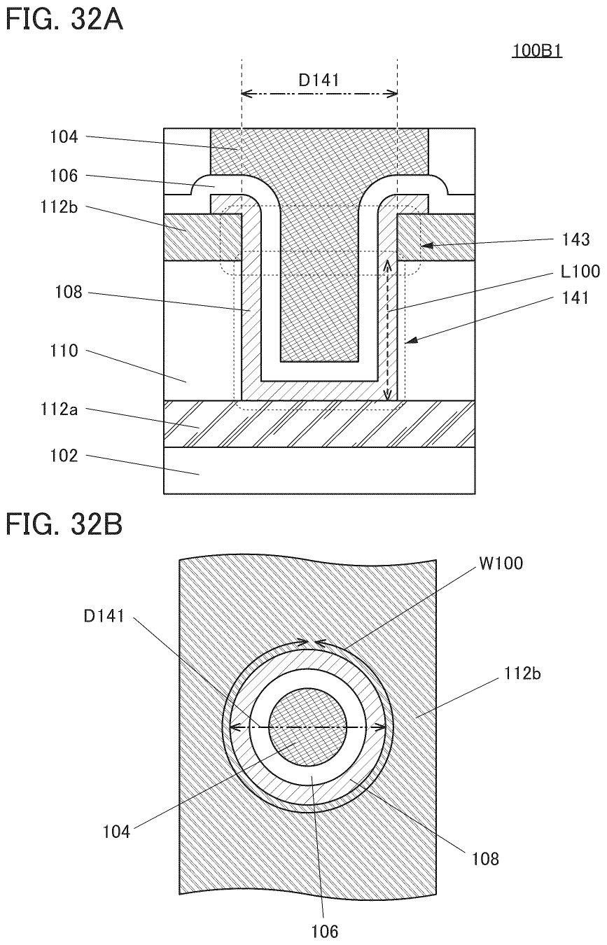

FIG. 32A is a longitudinal cross-sectional view of the transistor 100B1, which can be used in the semiconductor device of one embodiment of the present invention, along the plane that passes through the center of the opening 141. FIG. 32B is a transverse cross-sectional view of the transistor 100B1 when a cross-section of the opening 143 and the conductive layer 112 b is seen from the above.

The transistor 100B1 is different from the transistor 100 shown in FIG. 28B and the like mainly in that the side surface of the insulating layer 110 on the opening 141 side has a vertical shape. In other words, the transistor 100B1 has a structure in which the angle θ110 in FIG. 29B is 90°. The transistor 100B1 is different from the transistor 100 shown in FIG. 28B and the like mainly in that the insulating layer 110 is a single layer, in that the conductive layer 104 is provided to fill the opening 141 and the opening 143, and in that the conductive layer 104 is configured to extend to and cover the end portion of the semiconductor layer 108 (i.e., the region 108L is not formed). Note that the above description of the transistor 100 can be referred to; thus, the detailed description thereof is omitted.

### Structure Example 4

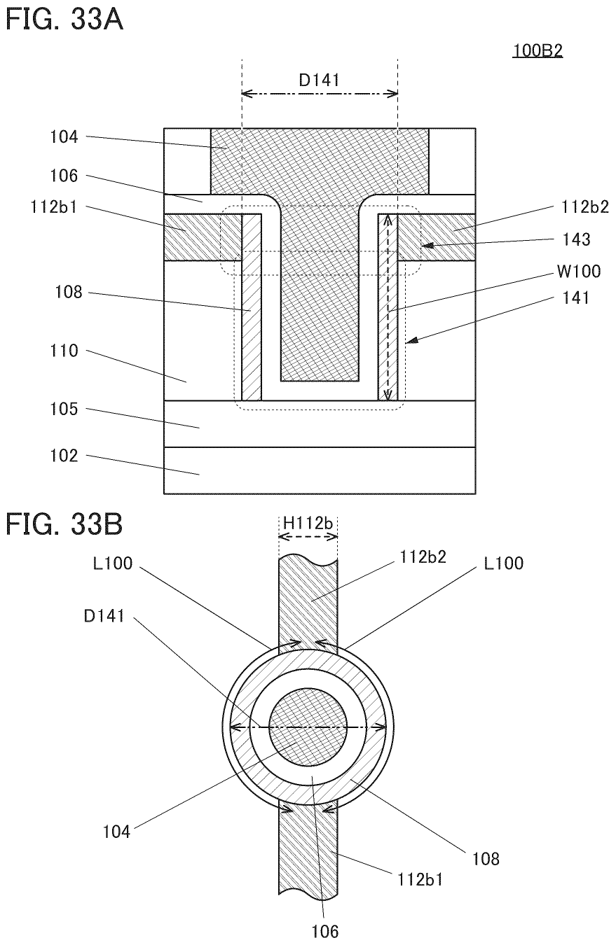

FIG. 33A is a longitudinal cross-sectional view of a transistor 100B2, which can be used in the semiconductor device of one embodiment of the present invention, along the plane that passes through the center of the opening 141 and includes the conductive layer 112b. FIG. 33B is a transverse cross-sectional view of the transistor 100B2 when a cross-section of the opening 143 and the conductive layer 112b is seen from the above. The transistor 100B2 is different from the transistor 100B1 mainly in that the conductive layer 112 a is not included, in that the transistor 100B2 is provided over an insulating layer 105, in that a conductive layer 112b1 and a conductive layer 112b2 are included instead of the conductive layer 112b, and in the shape of the semiconductor layer 108. The conductive layer 112b1 serves as one of a source electrode and a drain electrode, and the conductive layer 112b2 serves as the other.

The semiconductor layer 108 has a circular shape. Specifically, the semiconductor layer 108 in the opening 141 and the opening 143 includes a region in contact with the side surface of the conductive layer 112b1, a region in contact with the side surface of the conductive layer 112b2, and a region in contact with the side surface of the insulating layer 110. Here, the semiconductor layer 108 is not in contact with the top surfaces of the conductive layer 112b1 and the conductive layer 112b2. The semiconductor layer 108 having such a shape can be formed by processing by anisotropic etching, for example.

As shown in FIG. 33B, a width H112b of the conductive layer 112b1 and the conductive layer 112b2 is smaller than the width D141 of the opening 141 and the opening 143. In that case, the peripheral direction of the opening 141 and the opening 143 corresponds to the channel length direction of the transistor 100B2. Here, since the semiconductor layer 108 has a circular shape, two current paths (i.e., channels) from the conductive layer 112b1 to the conductive layer 112b2 exist. Note that the semiconductor layer 108 does not necessarily have a circular shape as long as being in contact with both the conductive layer 112b1 and the conductive layer 112b2.

The channel length can be controlled by the shapes and sizes of the opening 141 and the opening 143. For example, in the case where the channel length is desired to be large, the perimeters of the opening 141 and the opening 143 are made long. Although an example where the opening 141 and the opening 143 are circular in the top view is described in this embodiment, one embodiment of the present invention is not limited thereto. For example, the opening 141 and the opening 143 can have an elliptical shape or a quadrangular shape with rounded corners besides the circular shape in the top view. Alternatively, for example, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a quadrangular shape with rounded corners, a closed curve in which a straight line and a curve are combined, or the like can be employed. In that case, the maximum widths of the opening 141 and the opening 143 are preferably calculated as appropriate in accordance with the shapes of the uppermost portions of the opening 141 and the opening 143. For example, in the case where the opening is a square or a rectangle in the top view, the maximum widths of the opening 141 and the opening 143 are preferably diagonals of the uppermost portions of the opening 141 and the opening 143.

As shown in FIG. 33A, the height of the semiconductor layer 108 is the channel width W100 of the transistor 100B2. Thus, the channel width W100 of the transistor 100B2 can be controlled by the thickness of the insulating layer 110. Thus, the transistor 100B2 can have an extremely small channel width smaller than or equal to the light exposure limit of photolithography (e.g., greater than or equal to 1 nm, greater than or equal to 5 nm, greater than or equal to 7 nm, or greater than or equal to 10 nm, and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 60 nm, less than or equal to 50 nm, less than or equal to 40 nm, less than or equal to 30 nm, less than or equal to 20 nm, or less than or equal to 10 nm).

In the transistor 100B2, the source electrode and the drain electrode are positioned at the same level with respect to the surface of the substrate 102 over which the transistor 100B2 is formed, and the drain current flows in a direction parallel or substantially parallel to the surface of the substrate 102. In the transistor 100B2, the drain current can also be regarded as flowing in the lateral direction or the substantially lateral direction. Accordingly, the transistor 100B2 of one embodiment of the present invention can be referred to as a VLFET (Vertical Lateral Field Effect Transistor), for example.

The transistor 100B1 can have an extremely small channel length and a large channel width. Thus, high on-state current can be realized. Meanwhile, the transistor 100B2 can have an extremely small channel width and a large channel length. Thus, for example, appropriate on-state current can be achieved, which facilitates fine control of drain current in accordance with gate voltage in a saturation region. Furthermore, short-channel effects such as drain-induced barrier lowering (DIBL) can be suppressed, for example. The manufacturing process of the transistor 100B1 and that of the transistor 100B2 can share some of the steps, and the transistor 100B1 and the transistor 100B2 can be formed separately over one substrate. For example, in a display apparatus, the transistor 100B2 can be used as a driving transistor for controlling current flowing through the light-emitting element, and the transistor 100B1 can be used as a transistor serving as a switch.

In one embodiment of the present invention, for example, in the semiconductor device 60 described in Embodiment 1, the transistor 100B1 can be used as each of the transistors serving as switches (the transistor M13 to the transistor M17), and the transistor 100B2 can be used as each of the driving transistors (the transistor M11 and the transistor M18) and each of the load transistors (the transistor M12 and the transistor M19).

For example, in the semiconductor device 20A described in Embodiment 1, the transistor 100B1 can be used as each of the transistors serving as switches (the transistor M1, the transistor M3 to the transistor M6), and the transistor 100B2 can be used as the driving transistor (the transistor M2).

### Structure Example 5

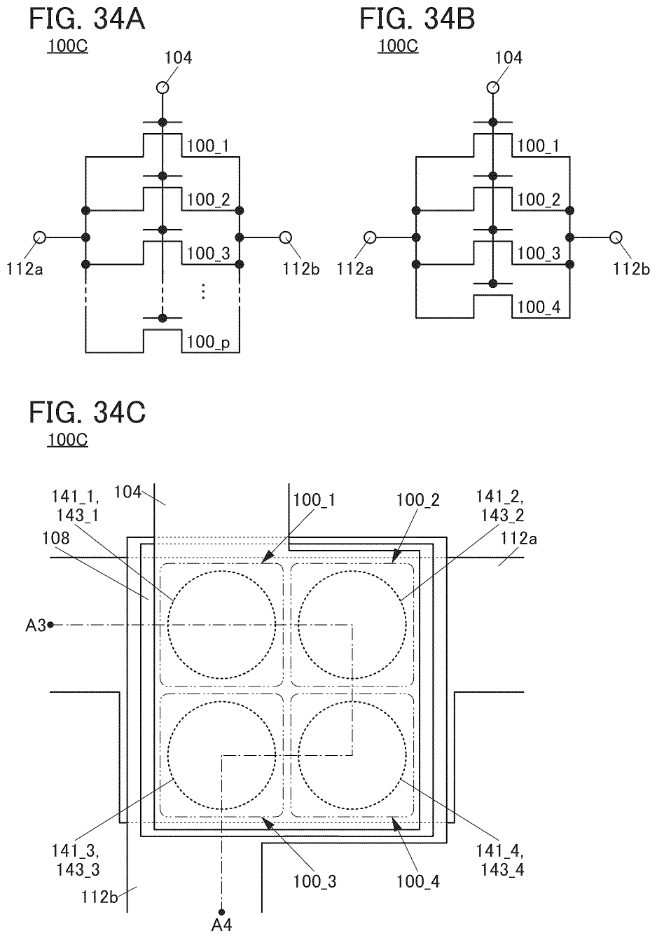

FIG. 34A shows an equivalent circuit diagram of a transistor 100C that can be used in the semiconductor device of one embodiment of the present invention. The transistor 100C is a transistor group including a transistor 100_1 to a transistor 100_p (p is an integer greater than or equal to 2). The transistor group 100C can be regarded as one transistor, in which the transistor 100_1 to the transistor 100_p are connected in parallel.

Gate electrodes of the transistor 100_1 to the transistor 100_p are electrically connected to one another. Source electrodes of the transistor 100_1 to the transistor 100_p are electrically connected to one another. Drain electrodes of the transistor 100_1 to the transistor 100_p are electrically connected to one another.

Although the transistor 100_1 to the transistor 100_p are shown as n-channel transistors in FIG. 34A, one embodiment of the present invention is not limited thereto. The transistor 100_1 to the transistor 100_p may be p-channel transistors.

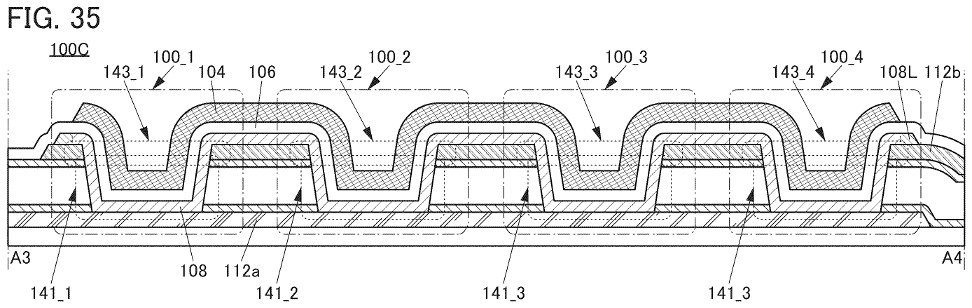

The case where p is 4 is specifically described as an example. FIG. 34B is an equivalent circuit diagram of the transistor 100C of one embodiment of the present invention. FIG. 34C shows a top view of the transistor 100C. FIG. 35 is a cross-sectional view of a cross section along the dashed-dotted line A3-A4 in FIG. 34C.

The transistor 100C includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A, the transistor 100B1, and the transistor 100B2 may be used as the transistor 100_1 to the transistor 100_4.

Although the transistor 100_1 to the transistor 100_4 are arranged in two rows and two columns in FIG. 34C and the like, there is no limitation on the transistor arrangement. For example, the transistor 100_1 to the transistor 100_4 may be arranged in one row and four columns. The transistors may be arranged in a matrix or other ways.

The transistor 100_1 to the transistor 100_4 each include the conductive layer 104, the insulating layer 106, the semiconductor layer 108, the conductive layer 112a, and the conductive layer 112b. The conductive layer 104 serves as a gate electrode of each of the transistor 100_1 to the transistor 100_4. Part of the insulating layer 106 serves as a gate insulating layer of each of the transistor 100_1 to the transistor 100_4. The conductive layer 112a serves as the other of the source electrode and the drain electrode, and the conductive layer 112b serves as one thereof in each of the transistor 100_1 to the transistor 100_4.

Since the description of the opening 141 and the opening 143 can be referred to for an opening 141_1 to an opening 141_4 and the opening 143_1 to the opening 143_4 included in each of the transistor 100_1 to the transistor 100_4, the detailed description thereof is omitted.

Here, in the case where the transistor 100C is regarded as one transistor, the channel width of the transistor is the sum of the channel widths of the transistor 100_1 to the transistor 100_4. For example, in the case where the top surface shapes of the opening 141_1 to the opening 141_4 are circular and the width D141 corresponds to the width of each of the opening 141_1 to the opening 141_4, the transistor 100C can be regarded as a transistor having a channel width of “D141×π×4” (see FIG. 29A and FIG. 29B). The transistor 100C composed of p transistors can be regarded as a transistor having a channel width of “D141×π×p”. Note that the transistor 100C can be regarded as a transistor having the channel length L100 (see FIG. 29B). A plurality of transistors connected in parallel can have a larger channel width and higher on-state current. By adjusting the number (p) of transistors connected in parallel, the channel width can be changed. The number (p) of transistors connected in parallel is determined so that desired on-state current is obtained.

Although FIG. 34C and the like shows the structure in which the transistor 100_1 to the transistor 100_4 share the semiconductor layer 108, one embodiment of the present invention is not limited thereto. The semiconductor layer 108 may be separated for each of the transistor 100_1 to the transistor 100_4.

Note that the structure of the transistor 100C described in Structure example 5 can also be applied to other structure examples. For example, the transistor 100C may be used as one or more of the transistors included in the semiconductor devices in FIG. 28 to FIG. 33.

### Structure Example 6

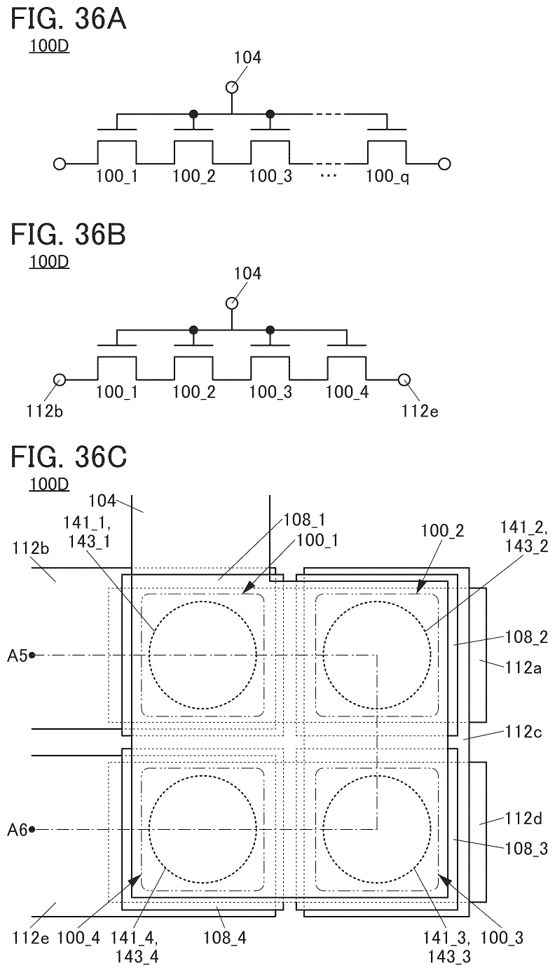

FIG. 36A shows an equivalent circuit diagram of a transistor 100D that can be used in the semiconductor device of one embodiment of the present invention. The transistor 100D is a transistor group including the transistor 100_1 to a transistor 100_q (q is an integer greater than or equal to 2). The transistor 100D in which the transistor 100_1 to the transistor 100_q are connected in series can be regarded as one transistor.

Although the transistor 100_1 to the transistor 100_q are shown as n-channel transistors in FIG. 36A, one embodiment of the present invention is not limited thereto. The transistor 100_1 to the transistor 100_q may be p-channel transistors.

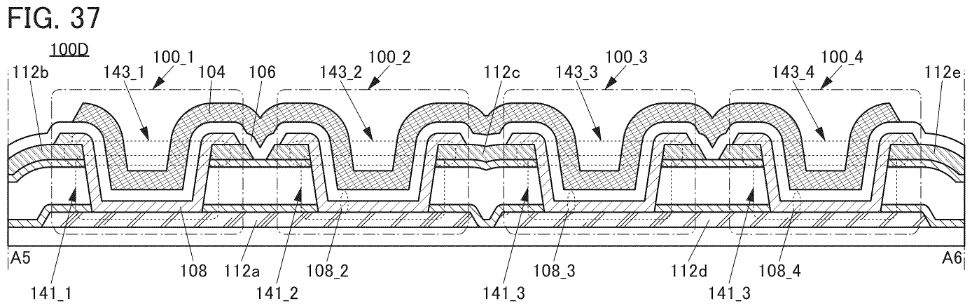

The case where q is 4 is specifically described as an example. FIG. 36B is an equivalent circuit diagram of the transistor 100D of one embodiment of the present invention. FIG. 36C shows a top view of the transistor 100D. FIG. 37 shows a cross-sectional view of a cross section along the dashed-dotted line A5-A6 in FIG. 36C.

The transistor group 100D includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A, the transistor 100B1, and the transistor 100B2 may be used as the transistor 100_1 to the transistor 100_4.

Although the transistor 100_1 to the transistor 100_4 are arranged in two rows and two columns in FIG. 36C and the like, there is no limitation on the transistor arrangement. For example, the transistor 100_1 to the transistor 100_4 may be arranged in one row and four columns. The transistors may be arranged in a matrix or other ways.

The transistor 100_1 includes the conductive layer 104, the insulating layer 106, a semiconductor layer 108_1, the conductive layer 112a, and the conductive layer 112b. The conductive layer 112a serves as one of the source electrode and the drain electrode of the transistor 100_1, and the conductive layer 112b serves as the other of the source and the drain of the transistor 100_1.

The transistor 100_2 includes the conductive layer 104, the insulating layer 106, a semiconductor layer 108_2, the conductive layer 112a, and a conductive layer 112c. The conductive layer 112a serves as one of the source electrode and the drain electrode of the transistor 100_2, and the conductive layer 112c serves as the other of the source electrode and the drain electrode of the transistor 100_2. The conductive layer 112a is shared by the transistor 100_1 and the transistor 100_2.

The transistor 100_3 includes the conductive layer 104, the insulating layer 106, a semiconductor layer 108_3, the conductive layer 112c, and a conductive layer 112d. The conductive layer 112c serves as one of the source electrode and the drain electrode of the transistor 100_3, and the conductive layer 112d serves as the other of the source electrode and the drain electrode of the transistor 100_3. The conductive layer 112c is shared by the transistor 100_2 and the transistor 100_3.

The transistor 100_4 includes the conductive layer 104, the insulating layer 106, a semiconductor layer 108_4, the conductive layer 112d, and a conductive layer 112e. The conductive layer 112d serves as one of the source electrode and the drain electrode of the transistor 100_4, and the conductive layer 112e serves as the other of the source electrode and the drain electrode of the transistor 100_4. The conductive layer 112d is shared by the transistor 100_3 and the transistor 100_4.

Since the description of the opening 141 and the opening 143 can be referred to for the opening 141_1 to the opening 141_4 and the opening 143_1 to the opening 143_4 included in each of the transistor 100_1 to the transistor 100_4, the detailed description thereof is omitted.

The one of the source electrode and the drain electrode of the transistor 100_1 is electrically connected to the one of the source electrode and the drain electrode of the transistor 100_2. The other of the source electrode and the drain electrode of the transistor 100_2 is electrically connected to the one of the source electrode and the drain electrode of the transistor 100_3. The other of the source electrode and the drain electrode of the transistor 100_3 is electrically connected to the one of the source electrode and the drain electrode of the transistor 100_4.

Here, in the case where the transistor 100D is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 100_4, the transistor 100D can be regarded as a transistor having a channel length of “L100×4” (see FIG. 29B). The transistor 100D composed of q transistors can be regarded as a transistor having a channel length of “L100×q”. Note that the transistor 100D can be regarded as a transistor having the channel width W100 (see FIG. 29A and FIG. 29B). A plurality of transistors connected in series can have a larger channel length and favorable saturation. By adjusting the number (q) of transistors connected in series, the channel length can be changed. The number (q) of transistors connected in series is determined so that desired saturation is obtained.

Note that the structure of the transistor 100D described in Structure example 6 can also be applied to other structure examples. For example, the transistor 100D may be used as one or more of the transistors included in the semiconductor devices in FIG. 28 to FIG. 33.

The transistor 100D may be used as each transistor included in the transistor 100C. That is, the groups of transistors connected in parallel can further be connected in series (hereinafter also referred to as series-parallel connection). The transistor 100C may be used as each transistor included in the transistor 100D. That is, the groups of transistors connected in series can further be connected in parallel (hereinafter also referred to as parallel-series connection).

According to one embodiment of the present invention, for example, one or both of the transistor 100C and the transistor 100D can be used as the transistor included in the peripheral driver circuit of the display apparatus 40 described in Embodiment 1.

The structures and the like described in this embodiment can be used in appropriate combination with any of the structures and the like described in the other embodiments and the like. In the case where a plurality of structures examples are described in one embodiment in this specification and the like, the structures examples can be used in combination as appropriate.

### Embodiment 3

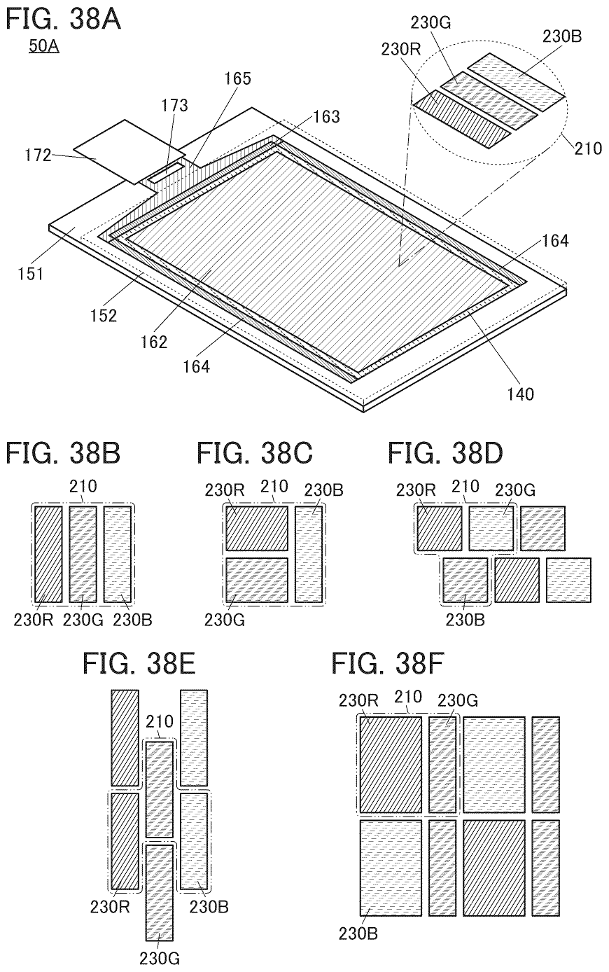

In this embodiment, display apparatuses of one embodiment of the present invention will be described with reference to FIG. 38 to FIG. 40. The display apparatus of one embodiment of the present invention can be a high-definition display apparatus or a large-sized display apparatus, for example. The display apparatus of one embodiment of the present invention can be a high-resolution display apparatus, for example.

The semiconductor device of one embodiment of the present invention can be used for a display apparatus or a module including the display apparatus. Examples of the module including the display apparatus are a module in which a connector such as a flexible printed circuit board (FPC) or a TCP (Tape Carrier Package) is attached to the display apparatus and a module in which the display apparatus is mounted with an integrated circuit (IC) by a COG (Chip On Glass) method, a COF (Chip On Film) method, or the like.

The display apparatus of one embodiment of the present invention may have a function of a touch panel. The display apparatus can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element (also referred to as a display device) and a counter substrate.

### Structure Example 1 of Display Apparatus

FIG. 38A is a perspective view of a display apparatus 50A.

In the display apparatus 50A, a substrate 152 and a substrate 151 are bonded to each other. In FIG. 38A, the substrate 152 is indicated by a dashed line.

The display apparatus 50A includes a display portion 162, a connection portion 140, a circuit portion 164, a circuit portion 163, a conductive layer 165, and the like. FIG. 38A shows an example where an IC 173 and an FPC 172 are mounted on the display apparatus 50A. Thus, the structure shown in FIG. 38A can be regarded as a display module including the display apparatus 50A, the IC, and the FPC.

The connection portion 140 is provided outside the display portion 162. The connection portion 140 can be provided along one or more sides of the display portion 162. The number of the connection portions 140 can be one or more. FIG. 38A shows an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver or a scan driver), for example. The circuit portion 163 includes a signal line driver circuit (also referred to as a source driver or a data driver), for example.

The conductive layer 165 has a function of supplying a signal and power to the display portion 162, the circuit portion 164, and the circuit portion 163. The signal and power are input to the conductive layer 165 from the outside of the display apparatus 50A through the FPC 172 or input to the conductive layer 165 from the IC 173.

FIG. 38A shows an example where the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. In addition, the IC may be mounted on the FPC by a COF method or the like.

Note that one or both of the IC 173 and the circuit portion 164 may constitute a scan line driver circuit. In that case, the IC 173 is referred to as a gate driver IC in some cases. Alternatively, one or both of the IC 173 and the circuit portion 163 may constitute a signal line driver circuit. In that case, the IC 173 is referred to as a source driver IC in some cases.

The semiconductor device of one embodiment of the present invention can be used for at least part of the display portion 162, the circuit portion 164, and the circuit portion 163 of the display apparatus 50A, for example.

When the semiconductor device of one embodiment of the present invention is used for a pixel circuit of a display apparatus, for example, the area occupied by the pixel circuit can be reduced and a high-resolution display apparatus can be obtained. For example, the resolution of the display apparatus can be higher than or equal to 300 ppi, higher than or equal to 500 ppi, higher than or equal to 1000 ppi, higher than or equal to 2000 ppi, or higher than or equal to 3000 ppi.

When the semiconductor device of one embodiment of the present invention is used for a driver circuit (e.g., one or both of a scan line driver circuit and a signal line driver circuit) of a display apparatus, the area occupied by the driver circuit can be reduced and the display apparatus can have a narrow bezel, for example.

Since the semiconductor device of one embodiment of the present invention has favorable electrical characteristics, a display apparatus can have increased reliability by using the semiconductor device.

According to one embodiment of the present invention, the display apparatus 40 described in Embodiment 1, for example, can be used as the display apparatus 50A. In that case, the display portion 162 corresponds to the display portion 42, the circuit portion 164 corresponds to the first driver circuit portion 43, and the circuit portion 163 corresponds to the second driver circuit portion 44.

The display portion 162 of the display apparatus 50A is a region where an image is to be displayed, and includes a plurality of pixels 210 that are periodically arranged. An enlarged view of one pixel 210 is shown in FIG. 38A.

The pixel 210 shown in FIG. 38A includes a pixel 230R that emits red (R) light, a pixel 230G that emits green (G) light, and a pixel 230B that emits blue (B) light. One pixel 230R, one pixel 230G, and one pixel 230B form one pixel 210, which achieves full-color display. The pixel 230R, the pixel 230G, and the pixel 230B each serve as a subpixel. The display apparatus 50A shown in FIG. 38A shows an example in which the pixel 230R, the pixel 230G, and the pixel 230B each serving as a subpixel are arranged in a stripe pattern. Note that the number of subpixels for forming one pixel 210 is not limited to three, and may be four or more. For example, four subpixels which emit light of R, G, B, and white (W) may be included. Alternatively, four subpixels which emit light of four colors, R, G, B, and yellow (Y) may be included.

In the description in this specification and the like, identification signs such as “R”, “G”, and “B” are sometimes used to indicate the components related to red light, green light, and blue light, respectively. Such identification signs are sometimes omitted in the description common to the components. For example, a plurality of pixels 230 are sometimes shown individually as the pixel 230R, the pixel 230G, and the pixel 230B when they need to be distinguished from one another. For example, the pixel 230R, the pixel 230G, and the pixel 230B are sometimes shown simply as the pixel 230 when there is no need to distinguish between them.

The pixel 230R, the pixel 230G, and the pixel 230B each include a display element and a circuit for controlling the driving of the display element (pixel circuit).

In the display apparatus of one embodiment of the present invention, there is no particular limitation on the arrangement of pixels and a variety of arrangements can be employed as shown in FIG. 38B to FIG. 38F. Examples of the arrangement of pixels include a stripe arrangement (see FIG. 38B), an S-stripe arrangement (see FIG. 38C), a delta arrangement (see FIG. 38D), a zigzag arrangement (see FIG. 38E), and a PenTile arrangement (see FIG. 38F). Other examples include a mosaic arrangement, a diamond arrangement, and a Bayer arrangement.

Furthermore, examples of the top surface shape of each subpixel (the pixel 230R, the pixel 230G, and the pixel 230B) in FIG. 38B to FIG. 38F include polygons such as a triangle, a tetragon (including a rectangle and a square), and a pentagon, polygons with rounded corners, an ellipse, and a circle. Here, the top surface shape of the subpixel corresponds to a top surface shape of a display region of the display element included in the subpixel. In this manner, the top surface shapes and sizes of the subpixels can be determined independently. Note that the positions of the pixel 230R, the pixel 230G, and the pixel 230B may be interchanged with one another as appropriate. The arrangement of the display elements and the arrangement of the pixel circuits may be the same or different.

Here, PenTile arrangement is a unique pixel arrangement that increases resolution in a pseudo manner. Thus, stripe arrangement or the like is preferably employed for the display apparatus, for example. According to one embodiment of the present invention, for example, the structure of the transistor 100 described in Embodiment 2 or the like is employed for some or all of the transistors included in the pixel circuit, whereby the area occupied by the pixel circuit can be reduced. This allows PenTile arrangement to be replaced with stripe arrangement or the like as the pixel arrangement without a reduction in the resolution of the display apparatus, for example.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display apparatus using a liquid crystal element, a transmissive liquid display apparatus, a reflective liquid display apparatus, and a transflective liquid display apparatus can be given.

Examples of a mode that can be used for a display apparatus using a liquid crystal element include a vertical alignment (VA) mode, a FFS (Fringe Field Switching) mode, an IPS (In-Plane Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include a MVA (Multi-Domain Vertical Alignment) mode, a PVA (Patterned Vertical Alignment) mode, and an ASV (Advanced Super View) mode.

Examples of a liquid crystal material that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used.

Examples of the light-emitting element include a self-luminous light-emitting element such as an LED (Light Emitting Diode), an organic EL (Electro Luminescence) element (OLED (Organic LED)), and a semiconductor laser. Examples of the LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode (also referred to as an anode electrode), and the other electrode functions as a cathode (also referred to as a cathode electrode).

In this embodiment, the case where a light-emitting element is used as the display element is mainly described as an example. In particular, the case where an organic EL element is used as the light-emitting element is described as an example. Thus, one embodiment of the present invention is a display apparatus using an organic EL element.

The display apparatus of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

Since the occupied area can be reduced with the use of the semiconductor device of one embodiment of the present invention, the aperture ratio of a pixel can be increased in a display apparatus having a bottom-emission structure. For example, the aperture ratio can be higher than or equal to 50%, higher than or equal to 55%, or higher than or equal to 60% in the display apparatus.

In this specification and the like, the aperture ratio refers to a proportion of the area of the region, where light is emitted, to the area of a pixel.

### Structure Example 2 of Display Apparatus

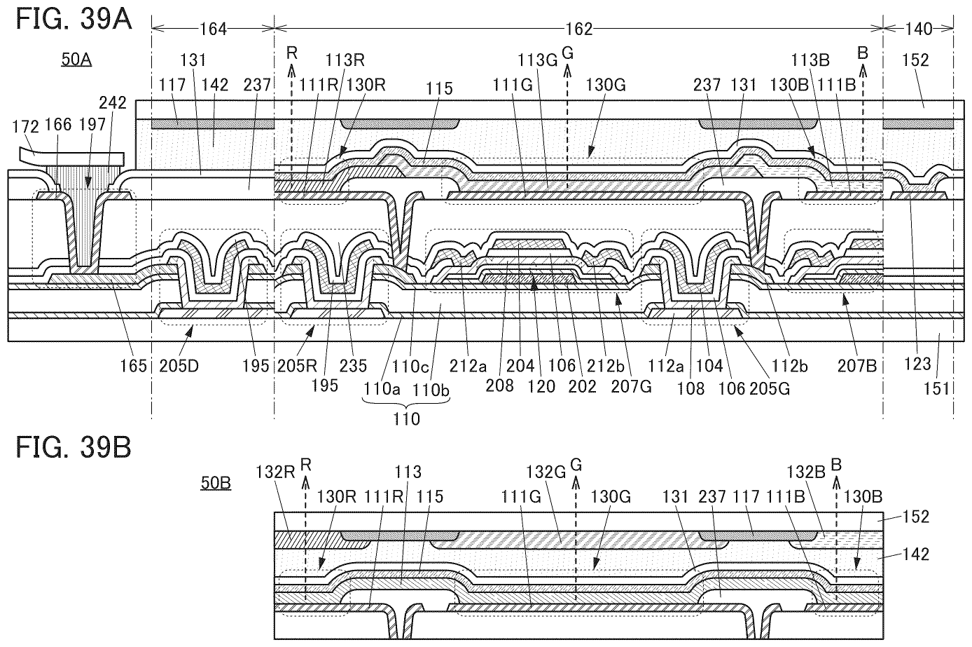

FIG. 39A shows an example of cross sections of part of a region including the FPC 172, part of the circuit portion 164, part of the display portion 162, part of the connection portion 140, and part of a region including the end portion of the display apparatus 50A. The description of the circuit portion 164 can be referred to for the circuit portion 163.

The display apparatus 50A shown in FIG. 39A includes a transistor 205D, a transistor 205R, a transistor 205G, and a transistor 207G, a transistor 207B, a light-emitting element 130R, a light-emitting element 130G, a light-emitting element 130B, and the like between the substrate 151 and the substrate 152. The light-emitting element 130R is a display element included in the pixel 230R that emits red light, the light-emitting element 130G is a display element included in the pixel 230G that emits green light, and the light-emitting element 130B is a display element included in the pixel 230B that emits blue light. Note that matters that are common to the light-emitting element 130R, the light-emitting element 130G, and the light-emitting element 130B are described, the light-emitting elements may be simply referred to as the light-emitting element 130.

The display apparatus 50A employs a side-by-side (SBS) structure. The SBS structure can optimize materials and structures of light-emitting elements and thus can increase the degree of freedom in selecting materials and structures, so that the emission intensity and the reliability can be easily improved.

The display apparatus 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistor 205D, the transistor 205R, the transistor 205G, the transistor 207G, and the transistor 207B are formed over the substrate 151. Some of the formation steps can be the same among these transistors.

Any one or more kinds of the above-described transistor 100, the transistor 100A, the transistor 100B1, the transistor 100B 2, the transistor 100C, the transistor 100D, and the transistor 200 can be used as one or more of the transistor 205D, the transistor 205R, the transistor 205G, the transistor 207G, and the transistor 207B. FIG. 39A shows a structure example in which the above-described transistor 100 is used as each of the transistor 205D, the transistor 205R, and the transistor 205G and the above-described transistor 200 is used as each of the transistor 207G and the transistor 207B.

The use of any one or more kinds of the above-described transistor 100, the transistor 100A, the transistor 100B1, the transistor 100B2, the transistor 100C, and the transistor 100D as the transistor provided in the display portion 162 allows the display apparatus to have a high resolution. The transistor 200 having favorable saturation can be used as a driving transistor for the light-emitting element 130. In that case, the display apparatus can be highly reliable.

The use of any one or more kinds of the above-described transistor 100, the transistor 100A, the transistor 100B1, the transistor 100B2, the transistor 100C, and the transistor 100D as the transistor provided in the circuit portion 164 allows the display apparatus to have a high operation speed. The transistor provided in the circuit portion 164 is sometimes required to have higher on-state current than the transistor provided in the display portion 162. The peripheral circuit portion 164 preferably includes a transistor with a short channel length. For example, one or more kinds of the above-described transistor 100, the transistor 100A, the transistor 100B1, the transistor 100B2, the transistor 100C, and the transistor 100D can be used in the circuit portion 164. With the use of one or more kinds of the transistor 100, the transistor 100A, the transistor 100B1, the transistor 100B 2, the transistor 100C, and the transistor 100D in the circuit portion 164, the area occupied by the transistors can be reduced, whereby a display apparatus with a narrow bezel can be achieved. Note that the transistor 200 may be used in the circuit portion 164.

Note that the transistor included in the display apparatus of this embodiment is not limited to the transistor included in the semiconductor device of one embodiment of the present invention. For example, the display apparatus of this embodiment may include the transistor included in the semiconductor device of one embodiment of the present invention and a transistor having another structure in combination. The display apparatus may include one or more of a planar transistor, a staggered transistor, and an inverted staggered transistor. The display apparatus may have either a top-gate structure or a bottom-gate structure. Alternatively, gates may be provided above and below the semiconductor layer where a channel is formed.

An OS transistor can be used as each of the transistor 205D, the transistor 205R, the transistor 205G, the transistor 207G, and the transistor 207B.

A Si transistor may be included in the display apparatus of this embodiment.

To increase the emission intensity of the light-emitting element included in the pixel circuit, the amount of current flowing through the light-emitting element needs to be increased. To increase the amount of current, voltage between the source and the drain of a driving transistor included in the pixel circuit needs to be increased. Since an OS transistor has a higher withstand voltage between the source and the drain than a Si transistor, high voltage can be applied between the source and the drain of the OS transistor. Accordingly, when an OS transistor is used as the driving transistor included in the pixel circuit, the amount of current flowing through the light-emitting element can be increased, so that the emission intensity of the light-emitting element can be increased.

When a transistor operates in a saturation region, a change in current flowing from the drain to the source relative to a change in gate-source voltage can be smaller in an OS transistor than in a Si transistor. Accordingly, when an OS transistor is used as the driving transistor included in the pixel circuit, the amount of current flowing from the drain to the source can be set minutely by a change in the gate-source voltage; hence, the amount of current flowing through the light-emitting element can be controlled. Thus, the number of gray levels in the pixel circuit can be increased.

Regarding saturation characteristics of current flowing when a transistor operates in a saturation region, even in the case where the drain-source voltage of an OS transistor increases gradually, more stable current (saturation current) can be made to flow through an OS transistor than through a Si transistor. Thus, by using an OS transistor as the driving transistor, stable current can be made to flow through a light-emitting element even when the current-voltage characteristics of a light-emitting element vary, for example. In other words, when the OS transistor operates in the saturation region, the current flowing from the drain to the source hardly changes with a change in the drain-source voltage; hence, the emission intensity of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. As another example, a structure is given in which an OS transistor is used as a transistor serving as a switch for controlling electrical continuity and discontinuity between wirings and an LTPS transistor is used as a transistor for controlling current.

For example, one of the transistors included in the display portion 162 serves as a transistor for controlling current flowing through the light-emitting element and can also be referred to as a driving transistor. One of a source and a drain of the driving transistor is electrically connected to a pixel electrode of the light-emitting element. An LTPS transistor can be used as the driving transistor. In that case, the amount of current flowing through the light-emitting element can be increased in the pixel circuit.

By contrast, another transistor included in the display portion 162 serves as a switch for controlling selection or non-selection of a pixel and can also be referred to as a selection transistor. A gate of the selection transistor is electrically connected to a gate line (scan line), and one of a source and a drain thereof is electrically connected to a source line (signal line). An OS transistor is preferably used as the selection transistor. Accordingly, the gray level of the pixel can be maintained even with an extremely low refresh rate (e.g., lower than or equal to 1 Hz); thus, power consumption can be reduced by stopping the driver (driver circuit) in displaying a still image.

The insulating layer 195 is provided to cover the transistor 205D, the transistor 205R, the transistor 205G, the transistor 207G, and the transistor 207B, and an insulating layer 235 is provided over the insulating layer 195.

The light-emitting element 130R, the light-emitting element 130G, and the light-emitting element 130B are provided over the insulating layer 235.

The light-emitting element 130R includes a pixel electrode 111R over the insulating layer 235, an EL layer 113R over the pixel electrode 111R, and a common electrode 115 over the EL layer 113R. The light-emitting element 130R shown in FIG. 39A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G shown in FIG. 39A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B shown in FIG. 39A emits blue light (B). The EL layer 113B includes a light-emitting layer that emits blue light.

Although FIG. 39A shows the EL layer 113R, the EL layer 113G, and the EL layer 113B that have the same thickness, the present invention is not limited thereto. The EL layer 113R, the EL layer 113G, and the EL layer 113B may have different thicknesses. For example, the thicknesses of the EL layer 113R, the EL layer 113G, and the EL layer 113B are preferably set in accordance with an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 195, and the insulating layer 235. In a similar manner, the pixel electrode 111G is electrically connected to the conductive layer 112 b included in the transistor 205G, and the pixel electrode 111B is electrically connected to the conductive layer 112b included in a transistor 205B (not shown).

The end portions of the pixel electrode 111R, the pixel electrode 111G, and the pixel electrode 111B are covered with an insulating layer 237. The insulating layer 237 serves as a partition. The insulating layer 237 can be provided to have a single-layer structure or a stacked-layer structure using one or both of an inorganic insulating material and an organic insulating material. A material usable for the insulating layer 195 and a material usable for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display apparatus 50A.

The common electrode 115 is one continuous film shared by the light-emitting element 130R, the light-emitting element 130G, and the light-emitting element 130B. The common electrode 115 shared by the plurality of light-emitting elements is electrically connected to a conductive layer 123 provided in the connection portion 140. As the conductive layer 123, a conductive layer formed using the same material and the same process as the pixel electrode 111R, the pixel electrode 111G, and the pixel electrode 111B is preferably used.

In the display apparatus of one embodiment of the present invention, a conductive film transmitting visible light is preferably used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display apparatus.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy including appropriate combination of any of these metals. Other examples of the material include an indium tin oxide (also referred to as an In—Sn oxide or an ITO), an In—Si—Sn oxide (also referred to as an ITSO), an indium zinc oxide (an In—Zn oxide), and an In—W—Zn oxide. Other examples of the material include an alloy including aluminum (aluminum alloy), such as an alloy of aluminum, nickel, and lanthanum (Al—Ni—La), and an alloy including silver, such as an alloy of silver and magnesium and an alloy of silver, palladium, and copper (also referred to as Ag—Pd—Cu or an APC). Other examples of the material include an element belonging to Group 1 or Group 2 of the periodic table that is not described above (e.g., lithium, cesium, calcium, or strontium), a rare earth metal such as europium or ytterbium, an alloy including an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40 %. For example, an electrode having a visible light (light with wavelengths greater than or equal to 400 nm and less than 750 nm) transmittance higher than or equal to 40 % is preferably used as the transparent electrode of the light-emitting element. The transflective electrode has a visible light reflectance higher than or equal to 10 % and lower than or equal to 95 %, preferably higher than or equal to 30 % and lower than or equal to 80 %. The reflective electrode has a visible light reflectance higher than or equal to 40 % and lower than 100 %, preferably higher than or equal to 70 % and lower than 100 %. These electrodes preferably have a resistivity lower than or equal to 1×10 ⁻² Ωcm.

The EL layer 113R, the EL layer 113G, and the EL layer 113B are each provided to have an island shape. In FIG. 39A, the end portion of the EL layer 113R and the end portion of the EL layer 113G that are adjacent to each other overlap with each other, the end portion of the EL layer 113G and the end portion of the EL layer 113B that are adjacent to each other overlap with each other, and the end portion of the EL layer 113R and the end portion of the EL layer 113B that are adjacent to each other overlap with each other. When island-shaped EL layers are formed using a metal mask (or a fine metal mask), the end portions of the EL layers adjacent to each other may overlap with each other as shown in FIG. 39A; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display apparatus.

Each of the EL layer 113R, the EL layer 113G, and the EL layer 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a bipolar substance and a TADF material.

Either a low molecular compound or a high molecular compound can be used for the light-emitting element, and an inorganic compound may also be included. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of emitting light with high emission intensity. Furthermore, the amount of current needed for obtaining the same emission intensity can be smaller in a tandem structure than in a single structure; thus, a tandem structure enables higher reliability. The tandem structure may be referred to as a stack structure.

In the case of using a light-emitting element having a tandem structure in FIG. 39A, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. For example, a solid sealing structure or a hollow sealing structure can be employed to seal the light-emitting elements. In FIG. 39A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is also preferable that the protective layer 131 be provided to extend to the end portion of the display apparatus 50A. Meanwhile, a connection portion 197 has a portion not provided with the protective layer 131 so that the FPC 172 and a conductive layer 166 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one type of insulating films, semiconductor films, and conductive films can be used.

The protective layer 131 including an inorganic film can inhibit deterioration of the light-emitting element by preventing oxidation of the common electrode 115 and inhibiting entry of impurities (e.g., moisture and oxygen) into the light-emitting element, for example; thus, the reliability of the display apparatus can be improved.

An inorganic insulating film can be used as the protective layer 131. Examples of a material usable for the inorganic insulating film include an oxide, a nitride, an oxynitride, and a nitride oxide. Specific examples of these inorganic insulating film are as described above. In particular, the protective layer 131 preferably includes a nitride or a nitride oxide, and further preferably includes a nitride.

An inorganic film including an ITO, an In—Zn oxide, a Ga—Zn oxide, an Al—Zn oxide, an IGZO, or the like can be used as the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a high visible-light-transmitting property. For example, an ITO, an IGZO, and an aluminum oxide are preferable because they are each an inorganic material having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film. Examples of an organic film usable for the protective layer 131 include organic insulating films usable for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. In this example, the conductive layer 165 has a single-layer structure of a conductive layer obtained by processing the same conductive film as the conductive layer 112b. In this example, the conductive layer 166 is a single conductive layer obtained by processing the same conductive film as the pixel electrode 111R, the pixel electrode 111G, and the pixel electrode 111B. On the top surface of the connection portion 197, the conductive layer 166 is exposed. Thus, the connection portion 197 and the FPC 172 can be electrically connected to each other through the connection layer 242.

The display apparatus 50A has a top-emission structure. Light emitted from the light-emitting element is emitted toward the substrate 152 side. For the substrate 152, a material having a high visible-light-transmitting property is preferably used. The pixel electrode 111R, the pixel electrode 111G, and the pixel electrode 111B include a material that reflects visible light, and the counter electrode (the common electrode 115) includes a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of damage can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side where light from the light-emitting element is extracted, a material that transmits the light is used. The use of a material having flexibility for each of the substrate 151 and the substrate 152 can increase the flexibility of the display apparatus and can offer a flexible display (e.g., a bendable display, a foldable display, a rollable display, a slidable display, or a stretchable display). Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability that is an epoxy resin is preferable. A two-liquid-mixture-type resin may be used. Alternatively, an adhesive sheet may be used.

As the connection layer 242, an anisotropic conductive film (ACF), an anisotropic conductive paste (ACP), or the like can be used.

### Structure Example 3 of Display Apparatus

FIG. 39B shows an example of a cross section of the display portion 162 of a display apparatus 50B. The display apparatus 50B is different from the display apparatus 50A mainly in that the subpixels of different colors include respective coloring layers (color filters or the like) and the light-emitting elements which share the EL layer 113. The structure shown in FIG. 39B can be combined with the structure shown in FIG. 39A of the region including the FPC 172, the circuit portion 164, the stacked-layer structure from the substrate 151 to the insulating layer 235 in the display portion 162, the connection portion 140, and the end portion. As for the following description of the display apparatus, description of portions similar to those of the above-described display apparatus is omitted in some cases.

The display apparatus 50B shown in FIG. 39B includes the light-emitting element 130R, the light-emitting element 130G, and the light-emitting element 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display apparatus 50B through the coloring layer 132B.

The EL layer 113 and the common electrode 115 are shared between the light-emitting element 130R, the light-emitting element 130G, and light-emitting element 130B. The number of manufacturing processes can be smaller in the structure where the EL layer 113 is provided to be shared between the subpixels of different colors than the structure where the subpixels of different colors are provided with different EL layers.

The light-emitting element 130R, the light-emitting element 130G, and light-emitting element 130B shown in FIG. 39B emit white light, for example. When white light emitted from the light-emitting element 130R, the light-emitting element 130G, and light-emitting element 130B passes through the coloring layer 132R, the coloring layer 132G, and the coloring layer 132B, light of intended colors can be obtained.

The light-emitting element that emits white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

The EL layer 113 preferably includes a light-emitting layer including a light-emitting substance that emits blue light and a light-emitting layer including a light-emitting substance that emits visible light having a longer wavelength than blue light, for example. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specifically, examples of applicable structures are as follows: a two-unit tandem structure including a light-emitting unit emitting yellow (Y) light and a light-emitting unit emitting blue (B) light; a two-unit tandem structure including a light-emitting unit emitting red (R) light and green (G) light and a light-emitting unit emitting blue light; a three-unit tandem structure in which a light-emitting unit emitting blue light, a light-emitting unit emitting yellow light, yellow-green light, or green light, and a light-emitting unit emitting blue light are stacked in this order; and a three-unit tandem structure in which a light-emitting unit emitting blue light, a light-emitting unit emitting yellow light, yellow-green light, or green light and red light, and a light-emitting unit emitting blue light are stacked in this order. Examples of the number of stacked light-emitting units and the order of colors from the anode side include a two-unit structure of B and Y; a two-unit structure of B and X (a light-emitting unit X); a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength such as red, green, or blue is sometimes intensified and emitted.

Alternatively, the light-emitting element 130R, the light-emitting element 130G, and light-emitting element 130B shown in FIG. 39B emit blue light, for example. In this case, the EL layer 113 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by the subpixel can be improved.

### Structure Example 4 of Display Apparatus

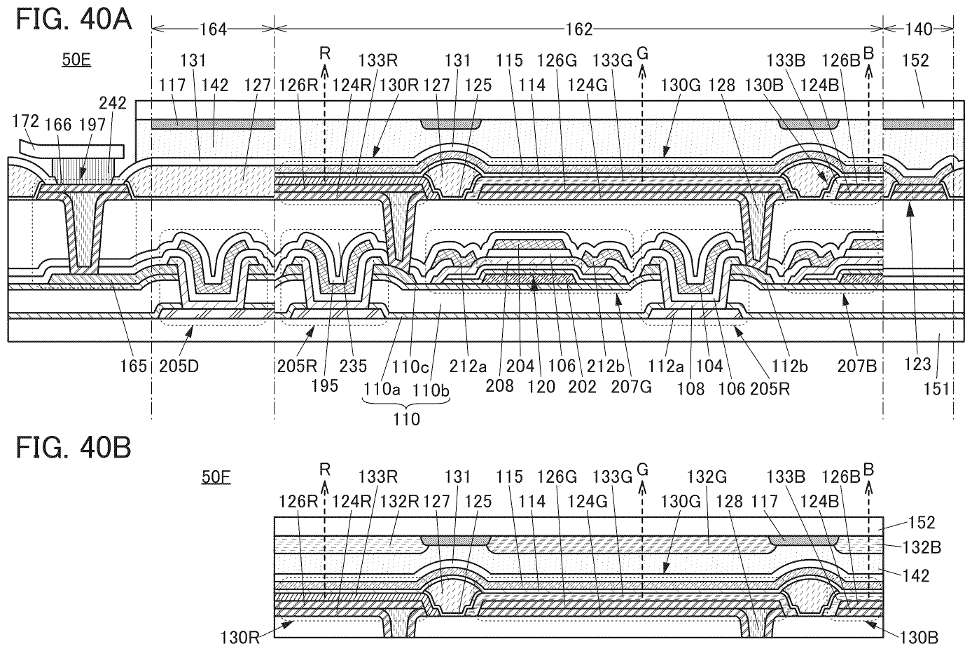

A display apparatus 50E shown in FIG. 40A is an example of a display apparatus having an MML (metal maskless) structure. In other words, the display apparatus 50E includes a light-emitting element that is formed without using a metal mask (a fine metal mask). The stacked-layer structure from the substrate 151 to the insulating layer 235 and the stacked-layer structure from the protective layer 131 to the substrate 152 are similar to those in the display apparatus 50A; thus, the description thereof is omitted.

A light-emitting element having the MML (metal maskless) structure can be manufactured without using a metal mask. Thus, a display apparatus that breaks through the definition limit due to alignment accuracy of the metal mask can be achieved. Furthermore, the manufacturing facilities for metal masks and washing process for metal masks can be unnecessary. This enables mass production of display apparatuses.

Furthermore, the display apparatus employing the MML structure enables the display apparatus in which minute light-emitting elements are integrated. Without a pseudo improvement in resolution by employing a unique pixel arrangement such as a PenTile arrangement, the display apparatus can achieve resolution higher than or equal to 500 ppi, higher than or equal to 1000 ppi, higher than or equal to 2000 ppi, higher than or equal to 3000 ppi, or higher than or equal to 5000 ppi while having what is called a stripe arrangement where R, G, and B are arranged in one direction.

In FIG. 40A, the light-emitting element 130R, the light-emitting element 130G, and light-emitting element 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R shown in FIG. 40A emits red (R) light. The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G shown in FIG. 40A emits green (G) light. The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B shown in FIG. 40A emits blue (B) light. The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. In this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, leakage current between adjacent light-emitting elements can be inhibited. This can prevent unintended light emission due to crosstalk, so that a display apparatus with extremely high contrast can be obtained.

Although the layer 133R, the layer 133G, and the layer 133B have the same thickness in FIG. 40A, the present invention is not limited thereto. The layer 133R, the layer 133G, and the layer 133B may have different thicknesses.

The conductive layer 124R is electrically connected to the conductive layer 112b included in the transistor 205R through an opening provided in the insulating layer 106, the insulating layer 195, and the insulating layer 235. In a similar manner, the conductive layer 124G is electrically connected to the conductive layer 112 b included in the transistor 205G, and the conductive layer 124B is electrically connected to the conductive layer 112b included in the transistor 205B.

The conductive layer 124R, the conductive layer 124G, and the conductive layer 124B are formed to cover the openings provided in the insulating layer 235. A layer 128 is embedded in the depressed portion of each of the conductive layer 124R, the conductive layer 124G, and the conductive layer 124B.

The layer 128 has a planarization function for the depressed portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also be used as light-emitting regions, increasing the aperture ratio of the pixels. The conductive layer 124R and the conductive layer 126R each preferably include a conductive layer serving as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material usable for the insulating layer 237 can be used, for example.

Although FIG. 40A shows an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

The end portion of the conductive layer 126R may be aligned with the end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layer 124G and the conductive layer 126G, and the conductive layer 124B and the conductive layer 126B are similar to the conductive layer 124R and the conductive layer 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layer 126R, the conductive layer 126G, and the conductive layer 126B can be entirely used as the light-emitting regions of the light-emitting element 130R, the light-emitting element 130G, and the light-emitting element 130B, thereby increasing the aperture ratio of the pixels.

The side surface and part of the top surface of each of the layer 133R, the layer 133G, and the layer 133B are covered with an insulating layer 125 and an insulating layer 127. The common layer 114 is provided over the layer 133R, the layer 133G, the layer 133B, the insulating layer 125, and the insulating layer 127, and the common electrode 115 is provided over the common layer 114. The common layer 114 and the common electrode 115 are each a continuous film shared by a plurality of light-emitting elements.

In FIG. 40A, the insulating layer 237 shown in FIG. 39A or the like is not provided between the conductive layer 126R and the layer 133R. That is, an insulating layer (also referred to as a partition wall, a bank, a spacer, or the like) in contact with the pixel electrode and covering the end portion of the top surface of the pixel electrode is not provided in the display apparatus 50E. Thus, the distance between adjacent light-emitting elements can be extremely narrowed. Accordingly, the display apparatus can have a high resolution or a high definition. In addition, a mask (a photomask, for example) for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting element 130R, the light-emitting element 130G, and the light-emitting element 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes, the layer 133R, the layer 133G, and the layer 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to level difference can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

Various inorganic insulating films can be used for the insulating layer 125. Examples of a material usable for the inorganic insulating film include an oxide, a nitride, an oxynitride, and a nitride oxide. Specific examples of these inorganic insulating film are as described above. The insulating layer 125 may have a single-layer structure or a stacked-layer structure. In particular, an aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that may diffuse into the light-emitting elements from the outside can be inhibited. With this structure, a highly reliable light-emitting element and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer including an organic material can be used. As the organic material, a photosensitive organic resin is preferably used, and for example, a photosensitive resin composite including an acrylic resin is preferably used. In this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. Alternatively, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### Structure Example 5 of Display Apparatus

FIG. 40B shows an example of a cross section of the display portion 162 of a display apparatus 50F. The display apparatus 50F is different from the display apparatus 50E mainly in that the subpixels of different colors include respective coloring layers (color filters or the like) and the light-emitting elements each of which include the layer 133R, the layer 133G, and the layer 133B. The structure shown in FIG. 40B can be combined with the structure shown in FIG. 40A of the region including the FPC 172, the circuit portion 164, the stacked-layer structure from the substrate 151 to the insulating layer 235 in the display portion 162, the connection portion 140, and the end portion.

The display apparatus 50F shown in FIG. 40B includes the light-emitting element 130R, the light-emitting element 130G, and the light-emitting element 130B, the coloring layer 132R transmitting red light, the coloring layer 132G transmitting green light, the coloring layer 132B transmitting blue light, and the like.

Light emitted from the light-emitting element 130R is extracted as red light to the outside of the display apparatus 50F through the coloring layer 132R. Similarly, light emitted from the light-emitting element 130G is extracted as green light to the outside of the display apparatus 50F through the coloring layer 132G. Light emitted from the light-emitting element 130B is extracted as blue light to the outside of the display apparatus 50F through the coloring layer 132B.

The light-emitting element 130R, the light-emitting element 130G, and light-emitting element 130B each include the layer 133R, the layer 133G, and the layer 133B. The layer 133R, the layer 133G, and the layer 133B are formed using the same material in the same step. The layer 133R, the layer 133G, and the layer 133B are separated from one another. When the EL layer is provided to have an island shape for each light-emitting element, leakage current between adjacent light-emitting elements can be inhibited. This can prevent unintended light emission due to crosstalk, so that a display apparatus with extremely high contrast can be obtained.

The light-emitting element 130R, the light-emitting element 130G, and light-emitting element 130B shown in FIG. 40B emit white light, for example. When white light emitted from the light-emitting element 130R, the light-emitting element 130G, and light-emitting element 130B passes through the coloring layer 132R, the coloring layer 132G, and the coloring layer 132B, light of intended colors can be obtained.

Alternatively, the light-emitting element 130R, the light-emitting element 130G, and light-emitting element 130B shown in FIG. 40B emit blue light, for example. In this case, the layer 133R, the layer 133G, and the layer 133B include one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by the subpixel can be improved.

This embodiment can be combined with the other embodiments as appropriate.

### Embodiment 4

In this embodiment, a transistor including an oxide semiconductor in a channel formation region (OS transistor) is described. In the description of the OS transistor, comparison with a transistor including silicon in a channel formation region (also referred to as a Si transistor) is also described simply.

### OS Transistor

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10⁻¹⁷ cm⁻³, further preferably lower than 1×10 ¹⁶ cm⁻³, still further preferably lower than 1×10 ¹³ cm⁻³, yet further preferably lower than 1×10 ¹⁰ cm⁻³, and higher than or equal to 1×10 ⁻⁹ cm⁻³. In order to reduce the carrier concentration in an oxide semiconductor, the impurity concentration in the oxide semiconductor is reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, an element other than the main components of the oxide semiconductor. For example, an element with a concentration lower than 0.1 atomic% can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as V_{O}H) is formed in the oxide semiconductor of the OS transistor, which generates an electron serving as a carrier. Formation of V_{O}H in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Thus, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a wider band gap than silicon, the off-state current of the transistor (also referred to as Ioff) can be reduced.

In a Si transistor, a short-channel effect (SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Thus, the OS transistor has higher resistance to the short-channel effect than the Si transistor. That is, in the case where a transistor with a short channel length is to be manufactured, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be more suitably used as a short-channel transistor than the Si transistor. Note that the gate length refers to the length of a gate electrode in a direction in which carriers move inside a channel formation region during operation of the transistor and to the width of the bottom surface of the gate electrode in a plan view of the transistor.

Miniaturization of the OS transistor can improve the high frequency characteristics of the transistor. Specifically, the cutoff frequency of the transistor can be improved. When the gate length of the OS transistor falls within any of the above ranges, the cutoff frequency of the transistor can be greater than or equal to 50 GHz, preferably greater than or equal to 100 GHZ, further preferably greater than or equal to 150 GHz in a room temperature environment, for example.

The above-described comparison of the OS transistor with the Si transistor demonstrates that the OS transistor has an effect superior to the Si transistor, such as low off-state current and capability of short-channel transistor formation.

The structures, configurations, methods, and the like described in this embodiment can be used in combination as appropriate with the structures, configurations, methods, and the like described in the other embodiments and the like.

### Embodiment 5

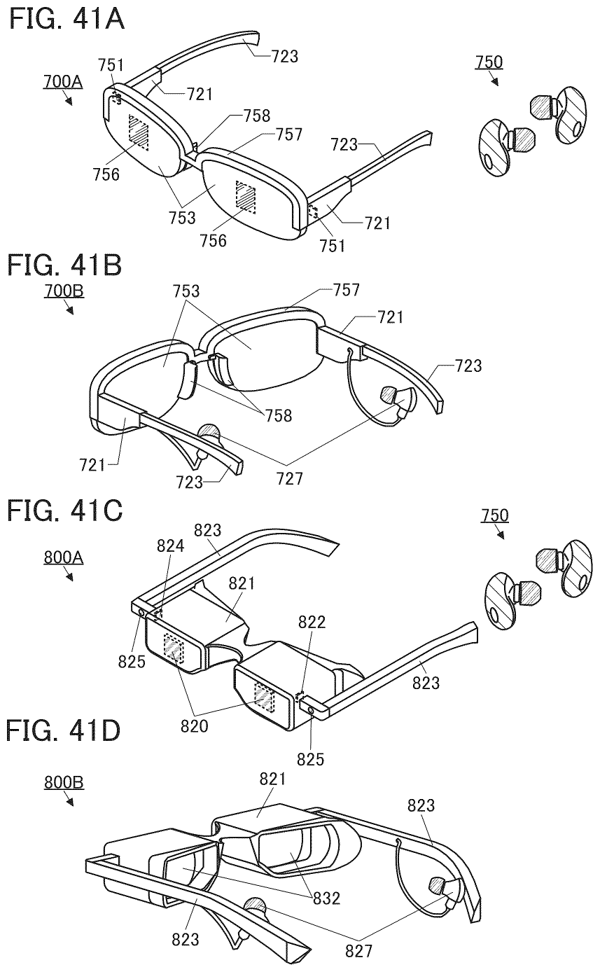

In this embodiment, electronic devices of one embodiment of the present invention will be described with reference to FIG. 41 to FIG. 43.

In the electronic device of this embodiment, a display portion includes the display apparatus of one embodiment of the present invention or the display apparatus using the semiconductor device of one embodiment of the present invention. The display apparatus of one embodiment of the present invention can be easily increased in resolution and definition. Thus, the display apparatus of one embodiment of the present invention can be used for a display portion of a variety of electronic devices.

Note that the semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have a high resolution, and thus can be used for an electronic device having a relatively small display portion. Examples of such an electronic device include wearable devices capable of being worn on a wrist, such as watch-type and bracelet-type information terminal devices; and wearable devices capable of being worn on a head, such as a VR device like a head-mounted display, a glasses-type AR device, an SR (Substitutional Reality) device, and a MR (Mixed Reality) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on a display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 41A to FIG. 41D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A shown in FIG. 41A and an electronic device 700B shown in FIG. 41B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display apparatus of one embodiment of the present invention can be used for the display panels 751. Thus, the electronic device can perform display with extremely high definition.

The electronic device 700A and the electronic device 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A shown in FIG. 41C and an electronic device 800B shown in FIG. 41D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high definition. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 41C and the like show examples where the wearing portion has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A shown in FIG. 41A has a function of transmitting information to the earphones 750 with the wireless communication function. As another example, the electronic device 800A in FIG. 41C has a function of transmitting information to the earphones 750 with the wireless communication function.

The electronic device may include an earphone portion. The electronic device 700B in FIG. 41B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B shown in FIG. 41D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

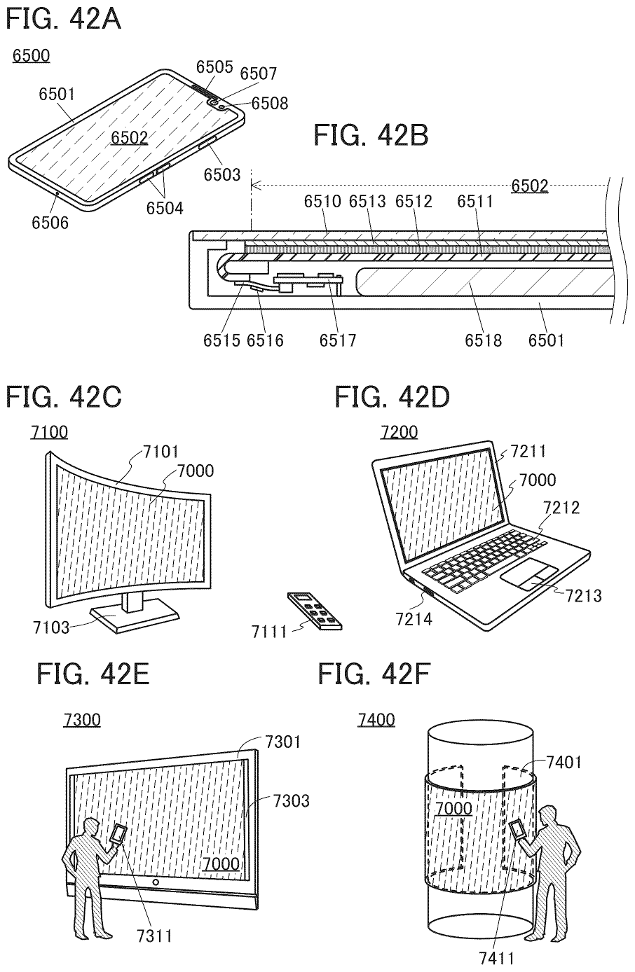

An electronic device 6500 shown in FIG. 42A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 42B is a schematic cross-sectional view including the end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 42C shows an example of a television device. In a television device 7100, a display portion 7000 is incorporated in a housing 7101. Here, a structure in which the housing 7101 is supported by a stand 7103 is shown.

The display apparatus of one embodiment of the present invention can be used for the display portion 7000.

Operation of the television device 7100 shown in FIG. 42C can be performed with an operation switch provided in the housing 7101 and a separate remote control 7111. Alternatively, the display portion 7000 may include a touch sensor, and the television device 7100 may be operated by touch on the display portion 7000 with a finger. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. Furthermore, when the television device is connected to a communication network with or without wires via the modem, one-way (from a transmitter to a receiver) or two-way (between a transmitter and a receiver or between receivers, for example) data communication can be performed.

FIG. 42D shows an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 42E and FIG. 42F show examples of digital signage.

Digital signage 7300 shown in FIG. 42E includes a housing 7301, the display portion 7000, a speaker 7303, and the like. Furthermore, an LED lamp, operation keys (including a power switch or an operation switch), a connection terminal, a variety of sensors, a microphone, and the like can be included.

FIG. 42F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 42E and FIG. 42F.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Alternatively, in the case where the display apparatus of one embodiment of the present invention is used for providing information such as route information or traffic information, usability can be enhanced by intuitive operation.

As shown in FIG. 42E and FIG. 42F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

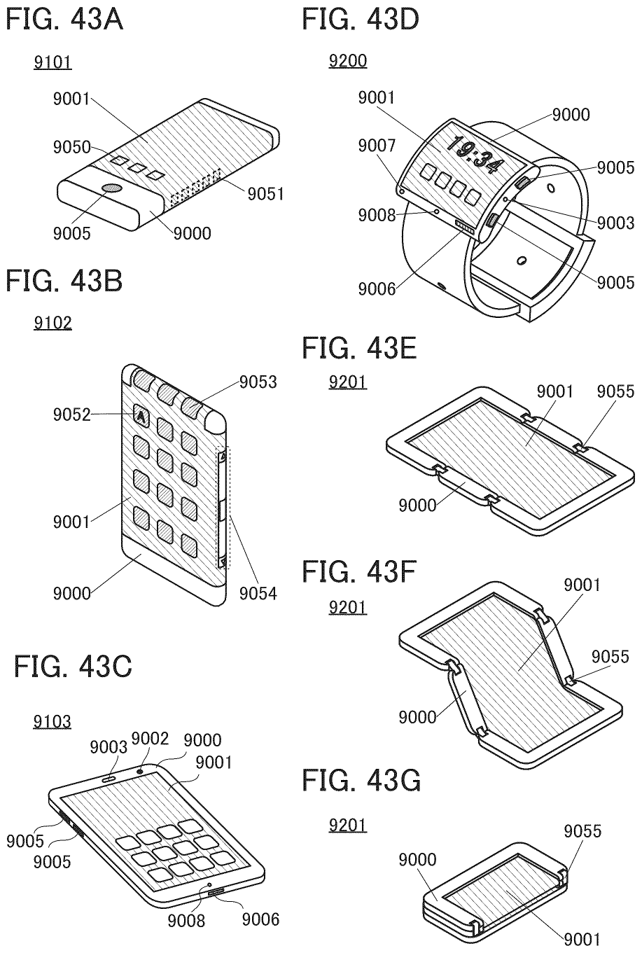

Electronic devices shown in FIG. 43A to FIG. 43G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 43A to FIG. 43G.

The electronic devices shown in FIG. 43A to FIG. 43G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. The functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices shown in FIG. 43A to FIG. 43G are described in detail below.

FIG. 43A is a perspective view showing a portable information terminal 9101. The portable information terminal 9101 can be used as a smartphone, for example. Note that the portable information terminal 9101 may be provided with the speaker 9003, the connection terminal 9006, the sensor 9007, and the like. The portable information terminal 9101 can display characters and image information on its plurality of surfaces. FIG. 43A shows an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, and the date. Other examples include the time, remaining battery, the radio field intensity, and the like. Alternatively, the icon 9050 or the like may be displayed at the position where the information 9051 is displayed.

FIG. 43B is a perspective view showing a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed such that it can be seen from above the portable information terminal 9102, with the portable information terminal 9102 put in a breast pocket of his/her clothes. For example, the user can see the display without taking out the portable information terminal 9102 from the pocket and decide whether to answer the call.

FIG. 43C is a perspective view showing a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 43D is a perspective view showing a watch-type portable information terminal 9200. The portable information terminal 9200 can be used as a Smartwatch (registered trademark), for example. The display surface of the display portion 9001 is curved, and an image can be displayed on the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 43E to FIG. 43G are perspective views showing a foldable portable information terminal 9201. Note that FIG. 43E is a perspective view of an opened state of the portable information terminal 9201, FIG. 43G is a perspective view of a folded state thereof, and FIG. 43F is a perspective view of a state in the middle of change from one of FIG. 43E and FIG. 43G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The structures and the like described in this embodiment can be used in appropriate combination with any of the structures and the like described in the other embodiments and the like.

### Supplementary Notes on Description in this Specification and the Like

The following are supplementary notes on the description of the above embodiments and structures in the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

Here, the expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0 Ω can be used, for example. Accordingly, in this specification and the like, examples of the “resistor” include a wiring having a resistance value, a diode, a coil, and a transistor in which current flows from its drain to source. Thus, the term “resistor” can be replaced with the terms “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. For another example, the resistance value may be higher than or equal to 1 Ω and lower than or equal to 1×10⁹ Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping a semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. For another example, the electrostatic capacitance value may be higher than or equal to 1 pF and lower than or equal to 10 μ.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, current can flow through the channel formation region between the source and the drain. The channel formation region refers to a region through which current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, functions of the source and the drain are replaced with each other when the direction of current flow is changed in circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In this case, in this specification and the like, one of the gate and the back gate of the transistor may be referred to as a first gate, and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

In this specification and the like, a transistor with a multi-gate structure having two or more gate electrodes can be used as the transistor. In a transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, drain-source current does not change very much even if drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having high characteristics.

In this specification and the like, the case where a single circuit element is shown in a circuit diagram may indicate a case where the circuit element includes a plurality of circuit elements. For example, the case where a single resistor is shown in a circuit diagram may indicate a case where two or more resistors are electrically connected to each other in series. As another example, the case where a single capacitor is shown in a circuit diagram may indicate a case where two or more capacitors are electrically connected to each other in parallel. As another example, the case where a single transistor is shown in a circuit diagram may indicate a case where two or more transistors are electrically connected to each other in series and their gates are electrically connected to each other. Similarly, as another example, the case where a single switch is shown in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, “current” means a charge transfer (electrical conduction). For example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanying carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A” and the like, for example. The description “current is input to element A” and the like can be rephrased as “current is output from element A” and the like, for example.

Ordinal numbers such as “first”, “second”, and “third” in this specification and the like are used to avoid confusion among components. Thus, the ordinal numbers do not limit the number of components. In addition, the terms do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°. Moreover, the expression “an insulator located over (on) a top surface of a conductor” can be replaced with the expression “an insulator located on a left surface (or a right surface) of a conductor” when the direction of a drawing showing these components is rotated by 90 degrees.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the diagram is rotated by 90 degrees.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a wiring in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the term such as “wiring”, “signal line”, or “power supply line” can be replaced with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether current flows therethrough or not. Alternatively, a switch has a function of selecting and changing a current path. For example, an electrical switch or a mechanical switch can be used as the switch. That is, a switch can be any element capable of controlling current, and is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction state with the movement of the electrode.

In this specification and the like, the “channel length” of the transistor sometimes refers to, for example, the distance between a source and a drain in a region where a semiconductor (or a portion where current flows in a semiconductor when a transistor is in an on state) and a gate overlap with each other or the distance between the source and the drain of a region where a channel is formed in a top view of the transistor.

In this specification and the like, the “channel width” of the transistor sometimes refers to, for example, the length of a portion where a source and a drain face each other in a region where a semiconductor (or a portion where current flows in a semiconductor when a transistor is in an on state) and a gate overlap with each other or the length of a portion where a source and a drain face each other in a region where a channel is formed in a top view of the transistor.

In this specification and the like, for example, the term such as “substrate”, “wafer”, or “die” does not functionally limit these components. For example, the term such as “substrate,” “wafer,” or “die,” can be interchanged with each other depending on the situation in some cases.

In this specification and the like, the term “parallel” does not necessarily mean a state of being exactly parallel. Hence, for example, the term “parallel” can be replaced with the term such as “approximately parallel”, “substantially parallel”, or “practically parallel” as appropriate. The term “parallel”, “approximately parallel”, “substantially parallel”, or “practically parallel” may include the case where the angle between two straight lines or planes is greater than or equal to −5°and less than or equal to 5°. Alternatively, the term can include the state where the angle between two straight lines or planes is greater than or equal to −10°and less than or equal to 10°. Alternatively, the term sometimes includes the state where the angle between two straight lines or planes is greater than or equal to −30°and less than or equal to 30°. Accordingly, “parallel” sometimes means “parallel or substantially parallel,” for example. Moreover, the term “perpendicular” does not necessarily mean a state of being exactly perpendicular. Hence, for example, the term “perpendicular” can be replaced with the term such as “approximately perpendicular”, “substantially perpendicular”, or “practically perpendicular” as appropriate. The term “perpendicular”, “approximately perpendicular”, “substantially perpendicular”, or “practically perpendicular” may include the state where the angle between two straight lines or planes is greater than or equal to 85°and less than or equal to 95°. Alternatively, the term can include the state where the angle between two straight lines or planes is greater than or equal to 80°and less than or equal to 100°. Alternatively, the term sometimes includes the state where the angle between two straight lines or planes is greater than or equal to 60°and less than or equal to 120°. Accordingly, the term “perpendicular” sometimes means “perpendicular or substantially perpendicular”, for example.

Note that in this specification and the like, the expression “level or substantially level” indicates having the same level from a reference surface (e.g., a flat surface such as a substrate surface) in a cross-sectional view. For example, in a manufacturing process of a semiconductor device, planarization treatment is performed, whereby the surface(s) of a single layer or a plurality of layers are exposed in some cases. In this case, the surfaces on which the planarization treatment is performed are at the same level from a reference surface. Note that the surfaces of a plurality of layers on which the planarization treatment is performed are not exactly level with each other in some cases, depending on a treatment apparatus, a treatment method, or a material of the treated surfaces on which the planarization treatment is performed. This case is also described with the expression “level or substantially level” in this specification and the like. For example, the expression “level or substantially level” also includes the case where two layers (here, given as a first layer and a second layer) whose levels with respect to the reference surface are different from each other are provided to have a difference between the top-surface level of the first layer and the top-surface level of the second layer of less than or equal to 20 nm.

Note that in this specification and the like, the expression “end portions are aligned or substantially aligned” means that at least outlines of stacked layers partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is located inward from the outline of the lower layer or the outline of the upper layer is located outward from the outline of the lower layer. This case is also described with the expression “end portions are aligned or substantially aligned” in this specification and the like.

Note that in this specification and the like, for example, the terms “identical”, “the same”, “equal”, “uniform”, and the like (including synonyms of these words) used in describing calculation values and measurement values or in describing objects, methods, events, and the like that can be converted into calculation values or measurement values, allow for a margin of error of ±20 % unless otherwise specified.

In this specification and the like, an impurity in a semiconductor refers to a component other than a main component of the semiconductor, for example. For example, an element with a concentration of lower than 0.1 atomic % is an impurity. When an impurity is included in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. For example, when an impurity enters an oxide semiconductor, oxygen vacancies are formed in the oxide semiconductor in some cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used for a semiconductor including a channel formation region of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor including a metal oxide or an oxide semiconductor.

In this specification and the like, a metal oxide including nitrogen is also referred to as a metal oxide in some cases. A metal oxide including nitrogen may be referred to as a metal oxynitride.

In the drawings and the like related to this specification, arrows indicating the X direction, the Y direction, and the Z direction are shown in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with one another. The X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

### REFERENCE NUMERALS

60: semiconductor device, 61: transmission portion, 62: input portion, 63: output portion, 64: generation portion, 64a: generation portion, 65: buffer portion, 65a: buffer portion, M11: transistor, M12: transistor, M13: transistor, M14: transistor, M15: transistor, M16: transistor, M17: transistor, M18: transistor, M19: transistor, C11: capacitor, IN11: wiring, OUT11: wiring, SW11: wiring, SW12: wiring, SW13: wiring, SW14: wiring, SW15: wiring, VL11: wiring, VL12: wiring, VL13: wiring, VL14: wiring, VL15: wiring, VL16: wiring, VL17: wiring, VL18: wiring, T61: period, T62: period, T63: period, Vin: potential, H: potential, L: potential, Vsfd: potential, Vsfs: potential, Vsfb: potential, Vpre: potential, Vth: voltage, 60a: semiconductor device, 62a: input portion, M1A: transistor, M1B: transistor, C1A: capacitor, SW1A: wiring, SW1B: wiring, 64b: generation portion, 64c: generation portion, 64d: generation portion, 64e: generation portion, 65b: buffer portion, 65c: buffer portion, 66: comparator portion, 67: AND arithmetic unit, 68: operational amplifier portion, M61: transistor, M1C: transistor, VL61: wiring, VL62: wiring, SW61: wiring, SW1C: wiring, 40: display apparatus, 41: pixel, 42: display portion, 43: first driver circuit portion, 44: second driver circuit portion, 45: wiring, 46: wiring, 40A: display apparatus, 40B: display apparatus, 43L: first driver circuit portion, 43R: first driver circuit portion, 45L: wiring, 45R: wiring, 40C: display apparatus, 40D: display apparatus, 20A: semiconductor device, 31A: pixel circuit, 32: light-emitting element, M1: transistor, M2: transistor, M3: transistor, M4: transistor, M5: transistor, M6: transistor, C1: capacitor, C2: capacitor, GLa: wiring, GLb: wiring, GLc: wiring, DL: wiring, 21: wiring, 22: wiring, 23: wiring, 24: wiring, ND1:node, ND2:node, ND3: node, T11: period, T12: period, T13: period, T14: period, T15: period, T16: period, Vdata: data potential, Va: potential, Vc: potential, V0: potential, V1: potential, Ve0: potential, Vel: potential, Vb: correction voltage, Ie: current, 20B: semiconductor device, 31B: pixel circuit, 20C: semiconductor device, 31C: pixel circuit, 20D: semiconductor device, 31D: pixel circuit, 20E: semiconductor device, 31E: pixel circuit, 20F: semiconductor device, 31F: pixel circuit, 20G: semiconductor device, 31G: pixel circuit, 20H: semiconductor device, 31H: pixel circuit, 201: semiconductor device, 31I: pixel circuit, 33: liquid crystal element, M7: transistor, M8: transistor, M9: transistor, C3: capacitor, C4: capacitor, C5: capacitor, 25: wiring, 26: wiring, 27: wiring, ND4:node, ND5:node, ND6:node, 70A: semiconductor device, 71: register portion, 72: buffer portion, SR: wiring, M21: transistor, M22: transistor, M23: transistor, M24: transistor, M25: transistor, M26: transistor, M31: transistor, M32: transistor, M33: transistor, M34: transistor, IN21: wiring, IN22: wiring, IN23: wiring, IN31: wiring, IN32: wiring, OUT21: wiring, OUT31: wiring, OUT32: wiring, VLD: wiring, VLS: wiring, NL21: wiring, NL22: wiring, T71: period, T72: period, T73: period, 71a: register portion, 72 a: buffer portion, M27: transistor, M35: transistor, M36: transistor, C21: capacitor, C31: capacitor, C32: capacitor, 70B: semiconductor device, 73: inverter portion, M41: transistor, M42: transistor, M43: transistor, M44: transistor, IN41: wiring, IN42: wiring, OUT41: wiring, NL41: wiring, T74: period, T75: period, T76: period, 73a: inverter portion, M45: transistor, C41: capacitor, 80: semiconductor device, 81: selector portion, SMP1: wiring, SMP2: wiring, SL: wiring, M51: transistor, M52: transistor, IN51: wiring, SW51: wiring, SW52: wiring, OUT51: wiring, OUT52: wiring, 90: semiconductor device, 90A: shift register portion, 90B: latch portion, 90C: latch portion, 90D: source follower portion, CLK: wiring, PWC: wiring, SP: wiring, SMP: wiring, DAT: wiring, LAT1: wiring, LAT2: wiring, SW1: wiring, SW2: wiring, SW3: wiring, SW4: wiring, SW5: wiring, SW6: wiring, 91: register portion, M71: transistor, M72: transistor, M73: transistor, M74: transistor, M75: transistor, M76: transistor, M7A: transistor, M7B: transistor, IN71: wiring, IN72: wiring, IN73: wiring, IN7A: wiring, OUT71: wiring, OUT7A: wiring, NL71: wiring, NL72: wiring, T91: period, T92: period, T93: period, 91a: register portion, M77: transistor, M7C: transistor, C71: capacitor, C7A: capacitor, 92: latch unit portion, 93: latch unit portion, 94: source follower unit portion, M81: transistor, M82: transistor, M83: transistor, M84: transistor, M85: transistor, M86: transistor, M87: transistor, M88: transistor, M8A: transistor, M8B: transistor, C81: capacitor, C82: capacitor, C83: capacitor, IN81: wiring, IN82: wiring, IN83: wiring, OUT81: wiring, OUT82: wiring, OUT83: wiring, SW81: wiring, SW82: wiring, SW83: wiring, SW84: wiring, SW85: wiring, SW86: wiring, SW87: wiring, VL81: wiring, VL82: wiring, VL83: wiring, VL84: wiring, VL85: wiring, VL8A: wiring, VL8B: wiring, NL81: wiring, NL82: wiring, T9A: period, T9B: period, Vd: data potential, TrA: transistor, TrB: transistor, TrC: transistor, Tr1: transistor, Tr2: transistor, Tr3: transistor, Tr4: transistor, Tr5: transistor, Tr6: transistor, 10: semiconductor device, 50A: display apparatus, 50B: display apparatus, 50E: display apparatus, 50F: display apparatus, 162: display portion, 163: circuit portion, 164: circuit portion, 210: pixel, 230: pixel, 230R: pixel, 230G: pixel, 230B: pixel, 100: transistor, 100A: transistor, 100B1: transistor, 100B2: transistor, 100C: transistor, 100D: transistor, 200: transistor, 205R: transistor, 205G: transistor, 205B: transistor, 205D: transistor, 207G: transistor, 207B: transistor, 130: light-emitting element, 130R: light-emitting element, 130G: light-emitting element, 130B: light-emitting element, 820: display portion, 6502: display portion, 7000: display portion, 9001: display portion

1. A semiconductor device comprising:
a transmission portion, an input portion, an output portion, a generation portion, a first wiring and a second wiring,
wherein the transmission portion comprises a first transistor,
wherein a gate of the first transistor is electrically connected to the first wiring through the input portion,
wherein one of a source and a drain of the first transistor is electrically connected to the second wiring through the output portion,
wherein the first wiring is electrically connected to the second wiring through the generation portion and the output portion,
wherein the transmission portion is configured to be a source follower outputting a first potential to the one of the source and the drain of the first transistor in accordance with a potential input to the gate of the first transistor,
wherein the generation portion is configured to generate a second potential corresponding to a potential of the first wiring,
wherein the input portion has a function of retaining is configured:
to retain a voltage corresponding to a threshold voltage of the first transistor; and
to transmit a potential corresponding to the potential of the first wiring to the gate of the first transistor, and wherein the output portion is configured:
to transmit the first potential to the second wiring; and
to transmit the second potential to the second wiring.

2. A semiconductor device comprising:
a transmission portion, an input portion, an output portion, a generation portion, a first wiring, a second wiring, a third wiring, a fourth wiring, a fifth wiring, a sixth wiring, a seventh wiring, an eighth wiring, a ninth wiring, a tenth wiring, an eleventh wiring, a twelfth wiring, a thirteenth wiring and a fourteenth wiring,
wherein the transmission portion comprises a first transistor and a second transistor,
wherein the input portion comprises a third transistor, a fourth transistor, a fifth transistor and a first capacitor,
wherein the output portion comprises a sixth transistor and a seventh transistor,
wherein the generation portion comprises an eighth transistor and a ninth transistor,
wherein a gate of the first transistor is electrically connected to one of a source and a drain of the fifth transistor and one terminal of the first capacitor,
wherein one of a source and a drain of the first transistor is electrically connected to one of a source and a drain of the second transistor, one of a source and a drain of the fourth transistor, and one of a source and a drain of the sixth transistor,
wherein the other of the source and the drain of the first transistor is electrically connected to the third wiring,
wherein a gate of the second transistor is electrically connected to the fourth wiring,
wherein the other of the source and the drain of the second transistor is electrically connected to the fifth wiring,
wherein a gate of the third transistor is electrically connected to the sixth wiring,
wherein one of a source and a drain of the third transistor is electrically connected to the other of the source and the drain of the fourth transistor and the other terminal of the first capacitor,
wherein the other of the source and the drain of the third transistor is electrically connected to a gate of the eighth transistor and the first wiring,
wherein a gate of the fourth transistor is electrically connected to the seventh wiring,
wherein a gate of the fifth transistor is electrically connected to the eighth wiring,
wherein the other of the source and the drain of the fifth transistor is electrically connected to the ninth wiring,
wherein a gate of the sixth transistor is electrically connected to the tenth wiring,
wherein the other of the source and the drain of the sixth transistor is electrically connected to one of a source and a drain of the seventh transistor and the second wiring,
wherein a gate of the seventh transistor is electrically connected to the eleventh wiring,
wherein the other of the source and the drain of the seventh transistor is electrically connected to one of a source and a drain of the eighth transistor and one of a source and a drain of the ninth transistor,
wherein the other of the source and the drain of the eighth transistor is electrically connected to the twelfth wiring,
wherein a gate of the ninth transistor is electrically connected to the thirteenth wiring, and
wherein the other of the source and the drain of the ninth transistor is electrically connected to the fourteenth wiring.

3. The semiconductor device according to claim 2,
wherein the first capacitor is configured to retain a voltage corresponding to a threshold voltage of the first transistor.

4. The semiconductor device according to claim 3, wherein, in a first state of the semiconductor device, each of the fourth transistor, the fifth transistor and the seventh transistor is in a conduction state, and each of the third transistor and the sixth transistor is in a non-conduction state.

5. The semiconductor device according to claim 1,
wherein the first transistor comprises a semiconductor layer, and
wherein the semiconductor layer comprises an oxide semiconductor.

6. The semiconductor device according to claim 5,
wherein at least part of the semiconductor layer is provided inside an opening formed in an insulating layer.

7. The semiconductor device according to claim 6,
wherein each transistor in the transmission portion, the input portion, the output portion and the generation portion is formed in the same step as the first transistor.

8. A display apparatus comprising:
the semiconductor device according to claim 1; and
a pixel,
wherein the pixel comprises a second transistor, and
wherein one of a source and a drain of the second transistor is electrically connected to the second wiring.

9. The display apparatus according to claim 8,
wherein the first transistor comprises a semiconductor layer, and
wherein the semiconductor layer comprises an oxide semiconductor.

10. The display apparatus according to claim 9, wherein at least part of the semiconductor layer is provided inside an opening formed in an insulating layer.

11. (canceled)

12. The semiconductor device according to claim 2,
wherein the first transistor comprises a semiconductor layer, and
wherein the semiconductor layer comprises an oxide semiconductor.

13. The semiconductor device according to claim 12, wherein at least part of the semiconductor layer is provided inside an opening formed in an insulating layer.

14. The semiconductor device according to claim 13, wherein each of the second to ninth transistors is formed in the same step as the first transistor.

15. A display apparatus comprising:
the semiconductor device according to claim 2; and
a pixel,
wherein the pixel comprises a tenth transistor, and
wherein one of a source and a drain of the tenth transistor is electrically connected to the second wiring.

16. The display apparatus according to claim 15,
wherein the first transistor comprises a semiconductor layer, and
wherein the semiconductor layer comprises an oxide semiconductor.

17. The display apparatus according to claim 16, wherein at least part of the semiconductor layer is provided inside an opening formed in an insulating layer.
